(19) United States
(12) Patent Application Publication
(10) Pub. No.: US 2025/0221144 A1
(43) Pub. Date: Jul. 3, 2025

(54) STRETCHABLE LIGHT-EMITTING POLYMERS

(71) Applicant: The University of Chicago, Chicago, IL (US)

(72) Inventors: Sihong Wang, Chicago, IL (US); Cheng Zhang, Chicago, IL (US); Wei Liu, Chicago, IL (US); Juan de Pablo, Chicago, IL (US)

(21) Appl. No.: 18/846,591

(22) PCT Filed: Mar. 15, 2023
(86) PCT No.: PCT/US2023/064376

§ 371 Date: Sep. 12, 2024

Related U.S. Application Data
(60) Provisional application No. 63/320,465, filed on Mar. 16, 2022.

(51) Int. Cl. H10K 50/11; C08F 26/06; C09K 11/06; H10K 50/15; H10K 50/17; H10K 85/10; H10K 102/00

(52) U.S. Cl. CPC H10K 50/11; C08F 26/06; C09K 11/06; H10K 50/15; H10K 50/171; H10K 85/1135; C09K 2211/1466; H10K 2102/311

(57) ABSTRACT

Stretchable light-emitting polymers are provided. Stretchable organic light-emitting diodes including the stretchable light-emitting polymers are further provided.

### TECHNICAL FIELD

The present disclosure relates to compositions. More particularly, the disclosure relates to mechanically stretchable electroluminescent polymers.

### BACKGROUND

Electroluminescent (“EL”) devices have been one of the major developments of modern technology in applications from visualizing information to wirelessly transmitting signal to medical therapy. Following decades of developments, organic light-emitting diodes (“OLEDs”) have been incorporated into the most advanced EL technology, especially for the display industry, owing to the many advantages of OLEDs, including high efficiency, high brightness, low-voltage operation, low cost, large-area scalability, and mechanical bendability.

The recently emerging desire to intimately integrate electronics with human bodies as wearable and implantable devices has spurred a new development need for EL devices; specifically, there is a growing need to incorporate skin-like softness and stretchability. However, relative to the development of other types of stretchable devices, such as sensors or transistors, the development of stretchable EL devices having high stretchability and high electroluminescence efficiency has lagged.

Initial efforts for imparting stretchability to EL devices and displays began from strain engineering designs on non-stretchable, inorganic light-emitting diodes (“LEDs”) and OLEDs, which sacrifice resolution and visualization and achieve only limited skin and/or tissue-like mechanical properties. Up until now, stretchability has been achieved by sacrificing performance characteristics, including, but not limited to, EL efficiency, brightness, low driving voltage, and fast switching speed. Particularly, for emissive materials that may operate under 20 V, the stretchability has only been realized on polymers that emit only through fluorescence (“FL”) with inherently low efficiency, such as poly(p-phenylene vinylene), with the commercial name of Super Yellow (SY). Fluorescence results from the rapid decay of singlet excitons. According to spin statistics, singlet excitons constitute only 25% of all excitons formed from the recombination of electrons and holes; the remaining 75% of excitons are triplet excitons. Therefore, FL emissive materials, which have been considered first-generation organic emitters, can only achieve a maximum internal quantum efficiency (“IQE”) of 25%, and a maximum external quantum efficiency (“EQE”) of 5%. Currently, further improvement of EL performance of stretchable OLEDs is limited by a lack of stretchable emissive materials with high-efficiency electroluminescence.

Successful commercialization of OLED technology has been enabled by innovations that achieved effective harnessing of triplet excitons for light emission, so as to reach near unity IQE. Two types of organic emitters have harnessed triplet excitons and reached near unity IQE: (1) phosphorescent (“PH”) emitters, regarded as second-generation emitters, and which incorporate heavy metal ions to exert strong spin-orbit coupling, so as to facilitate direct triplet emissions; and (2) thermally activated delayed fluorescence (“TADF”) emitters, regarded as third-generation emitters, and which have significantly reduced energy-level splitting (ΔE_{ST}) between singlet (S₁) and triplet (T₁) excited states for enabling the efficient reverse intersystem crossing (“RISC”) process from T₁ to S₁. Compared to PH emitters, heavy-metal-free TADF emitters have lower biological and environmental toxicity and are less expensive, which are desirable characteristics for human-integrated applications. Most of the TADF emitters yet reported are small molecules, which cannot offer stretchability. Of those TADF polymers that have been developed, stretchability has not yet been reported.

Thus, there is a need for stretchable light-emitting polymers that maintain EQE as high as 10%. Further, there is a need for stretchable EL devices with high efficiency, high switching speed, increased brightness, and low driving voltage.

### SUMMARY

In an example, the present disclosure provides a stretchable light-emitting polymer of formula (I), (II), (III), (IV), or (V):

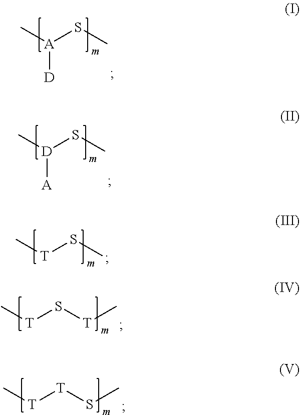

wherein D is a donor chemical moiety capable of donating electrons; A is an acceptor chemical moiety capable of accepting electrons; T is a chemical moiety including D bonded to A; S is a stretchable section, including a stretchable chemical moiety selected from the group consisting of

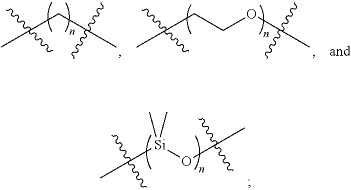

m is an integer from 1 to 100; n is an integer from 1 to 50; and a dihedral angle of a bond between D and A is from about 75.0° to about 90.0°.

In another example, the present disclosure provides a stretchable organic light-emitting diode, including: a cathode layer; an anode layer; a film including a stretchable light-emitting polymer of formula (I), (II), (III), (IV), or (V); a stretchable electron injection layer between the cathode layer and the film; and a stretchable hole transporting layer between the anode layer and the film.

In yet another example, the present disclosure provides a stretchable light-emitting polymer of formula (VI):

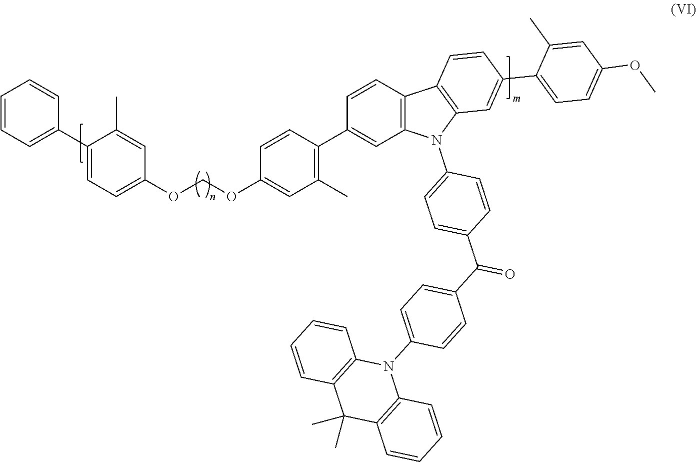

wherein m is an integer from 1 to 100; and n is an integer from 1 to 50.

Further areas of applicability will become apparent from the description provided herein. It should be understood that the description and specific examples are intended for purposes of illustration only and are not intended to limit the scope of the present disclosure.

### DRAWINGS

In order that the present disclosure may be well understood, there will now be described various forms thereof, given by way of example, reference being made to the accompanying drawings. The components in the figures are not necessarily to scale.

FIG. 1 illustrates a ¹H nuclear magnetic resonance (“NMR”) spectrum of (4-(9,9-dimethylacridin-10(9H)-yl)phenyl)(4-fluorophenyl)methanone (Compound 1);

FIG. 2 illustrates a ¹H NMR spectrum of (4-(2,7-dibromo-9H-carbazol-9-yl)phenyl)(4-(9,9-dimethylacridin-10(9H)-yl)phenyl)methanone (Compound 2);

FIG. 3 illustrates a ¹H NMR spectrum of (4-(2,7-bis(4,4,5,5-tetramethyl-1,3,2-dioxaborolan-2-yl)-9H-carbazol-9-yl)phenyl)-(4-(9,9-dimethylacridin-10(9H)-yl)phenyl)methanone (Compound 3);

FIG. 4 illustrates a ¹H NMR spectrum of bis(4-bromo-3-methylphenoxy)methane (Compound 4);

FIG. 5 illustrates a ¹H NMR spectrum of 1,3-bis(4-bromo-3-methylphenoxy)propane (Compound 5);

FIG. 6 illustrates a ¹H NMR spectrum of 1,6-bis(4-bromo-3-methylphenoxy)hexane (Compound 6);

FIG. 7 illustrates a ¹H NMR spectrum of 1,10-bis(4-bromo-3-methylphenoxy)decane (Compound 7);

FIG. 8 illustrates a ¹H NMR spectrum of (4-(2,7-bis(4-methoxy-2-methylphenyl)-9H-carbazol-9-yl)phenyl)-(4-(9,9-dimethylacridin-10(9H)-yl)phenyl)methanone (DKC, Compound 8);

FIG. 9 illustrates a ¹H NMR spectrum of stretchable light-emitting polymer PDKCM;

FIG. 10 illustrates a ¹H NMR spectrum of stretchable light-emitting polymer PDKCP;

FIG. 11 illustrates a ¹H NMR spectrum of stretchable light-emitting polymer PDKCH;

FIG. 12 illustrates a ¹H NMR spectrum of stretchable light-emitting polymer PDKCD;

FIG. 13 illustrates a density functional theory (“DFT”) simulation of the repeating unit of stretchable light-emitting polymer PDKCD (arrow indicating a dihedral angle between donor and acceptor moiety planes of 87.5°);

FIG. 14 illustrates optical microscope images of PDKCM, PDKCP, PDKCH, and PDKCD at approximately the on-set strain for crack formation, stretched in the horizontal direction (scale bar has a length of 20 μm);

FIG. 15 illustrates the glass-transition temperatures (T_{g}) obtained from differential scanning calorimetry (“DSC”) thermal analysis of each of PDKCM, PDKCP, PDKCH, and PDKCD;

FIG. 16 illustrates glass-transition temperatures and crack on-set strains of stretchable light-emitting polymers (error bars of crack on-set strains represent the range of measurement error);

FIG. 17 illustrates images of a stretchable organic light-emitting diode including a stretchable light-emitting polymer of the present disclosure;

FIG. 18 illustrates absorption spectra and room temperature emission spectra of films of stretchable light-emitting polymers of the present disclosure, and DKC for comparison;

FIGS. 19A and 19B illustrate fluorescent/phosphorescent (“FL/PH”) spectra at low temperature (77 K) of PDKCM, PDKCP, PDKCH, PDKCH, and DKC in 2-methyltetrahydrofuran (“2-Me-THF,” 10⁻⁵ M) solutions (19A), and of films of PDKCM, PDKCP, PDKCH, PDKCH, and DKC (19B);

FIG. 20 illustrates the intramolecular dihedral angles of D-A pairs of stretchable light-emitting polymers with molecular dynamics (“MD”) simulation;

FIGS. 21A, 21B, 21C, 21D, and 21E illustrate transient PL characteristics of films including each of DKC (21A), PDKCM (21B), PDKCP (21C), PDKCH (21D), and PDKCD (21E), under different strains (0%, 25%, 50%, 75%, and 100%) in 50 nanosecond time-scale windows;

FIGS. 22A, 22B, 22C, 22D, and 22E illustrate transient PL characteristics of films including each of DKC (22A), PDKCM (22B), PDKCP (22C), PDKCH (22D), and PDKCD (22E), under different strains (0%, 25%, 50%, 75%, and 100%) in 5 microsecond time-scale windows;

FIG. 23 illustrates the prompt component (Φₚ) and the delayed component (Φ_{TADF}) PL quantum yields (“PLQYs”) of DKC, PDKCM, PDKCP, PDKCH, and PDKCD;

FIG. 24 illustrates a schematic representation of an organic light-emitting diode device structure (TmPyPB=1,3,5-tri(m-pyridin-3-ylphenyl)benzene; LiF=lithium fluoride; Al=aluminum; ITO=indium tin oxide);

FIG. 25 illustrates a representative current density (J)-luminance (L)-voltage (V) traces of OLEDs according to FIG. 24 with DKC, PDKCM, PDKCP, PDKCH, and PDKCD as the “TADF Emitters” layer;

FIG. 26 illustrates the maximum external quantum efficiency (EQEₘₐₓ) and EL spectra of the OLEDs according to FIG. 24 with DKC, PDKCM, PDKCP, PDKCH, and PDKCD as the TADF Emitters” layer;

FIG. 27 illustrates optical microscope images of PDKCM and PDKCD under 100% strain, with an atomic force microscopy (“AFM”) height image;

FIG. 28 illustrates optical microscope images of PDKCM, PDKCP, PDKCH, and PDKCD films under horizontal stretching to the strains of 50%, 75%, and 100%, transferred from PDMS substrates to polystyrene-block-poly(ethylene-ranbutylene-block-polystyrene-coated “SEBS-coated”) Si substrates;

FIG. 29 illustrates normalized PLQYs of PDKCM and PDKCD under different strains;

FIG. 30 illustrates a x-ray photoelectron spectroscopy (“XPS”) spectrum obtained at different depths of the SEBS_mCP film for the C 1s is peak;

FIG. 31 illustrates a XPS spectrum obtained at different depths of the SEBS_mCP film for the N is peak;

FIG. 32 illustrates ratios between the N is peak area and C 1s is peak area (N/C ratio) from XPS spectra obtained at different etching times (etching step of 5 s results in about 5 nm depth change; thickness of SEBS_mCP film is about 30 nm);

FIG. 33 illustrates PL transient decays of PDKCM and PDKCD under different strains;

FIG. 34 illustrates the structure of the organic light-emitting diode device for characterizing the EL performance of the stretchable light-emitting polymers of the present disclosure as emitting layers upon stretching;

FIG. 35 illustrates representative J-V and L-V traces of an OLED device of FIG. 34 including PDKCD as emitting layer under different strains;

FIG. 36 illustrates representative J-V and L-V traces of an OLED device of FIG. 34 including PDKCM as emitting layer under different strains;

FIG. 37 illustrates normalized maximum external quantum efficiency of OLED devices of FIG. 34 including PDKCD and PDKCM under different strains;

FIG. 38 illustrates normalized maximum external quantum efficiency of OLED devices of FIG. 34 including PDKCD and PDKCM as a function of 100%-strain stretching cycles;

FIG. 39 illustrates maximum external quantum efficiency and stretchability for PDKCD and reported stretchable composite emitters based on a FL emitter;

FIG. 40 illustrates snapshots taken from an MD simulation of PDKCD at 0% and 100% strain, with one chain highlighted, the backbone rendered in grey, the donor units in blue, and the acceptor units in red;

FIG. 41A illustrates the straight-line distance changes (d/d₀) between the terminal atoms for TADF and alkyl chain units for PDKCM and PDKCD based on the distances indicated in FIG. 41B;

FIG. 42 illustrates time-averaged donor-to-donor (“D-D”) configurational statistics extracted from the MD simulations for PDKCM, PDKCP, PDKCH, and PDKCD under different strains (0%, 50%, and 100%) during continuous stretching;

FIG. 43 illustrates time-averaged acceptor-to-acceptor (“A-A”) configurational statistics extracted from the MD simulations for PDKCM, PDKCP, PDKCH, and PDKCD under different strains (0%, 50%, and 100%) during continuous stretching;

FIG. 44 illustrates time-averaged inter-TADF-unit donor-to-acceptor (“D-A”) configurational statistics extracted from the MD simulations for PDKCM, PDKCP, PDKCH, and PDKCD under different strains (0%, 50%, and 100%) during continuous stretching;

FIGS. 45A, 45B, 45C, and 45D illustrates radial distribution functions (“RDFs”) for the centers of mass of donor groups (“g(r_{DD})”) of PDKCM (45A), PDKCP (45B), PDKCH (45C), and PDKCD (45D) extracted from MD simulations under different strains (0%, 50%, and 100%);

FIGS. 46A, 46B, 46C, and 46D illustrate radial distribution functions (RDFs) for the centers of mass of acceptor groups (“g(r_{AA})”) of PDKCM (46A), PDKCP (46B), PDKCH (46C), and PDKCD (46D) extracted from MD simulations under different strains (0%, 50%, and 100%);

FIG. 47 illustrates a schematic device structure of a stretchable organic light-emitting diode including PDKCD;

FIG. 48 illustrates an energy level diagram of the device of FIG. 47;

FIG. 49 illustrates a flow diagram of the fabrication process for the AgNW/TPU/PDMS stretchable semi-transparent electrode;

FIG. 50 illustrates a transmittance curve for the AgNW/TPU/PDMS stretchable semi-transparent electrode, including a photo of the electrode as an inset;

FIG. 51 illustrates stretching-induced resistance changes for the original AgNW/TPU/PDMS stretchable semi-transparent electrode and the annealed electrode (140° C. for 1 h);

FIG. 52 illustrates a UPS test result for the AgNW/TPU/PDMS stretchable semi-transparent electrode;

FIG. 53 illustrates an optical microscope image of the AgNW/TPU/PDMS stretchable semi-transparent electrode under different strains (60%, 80%, and 100%) from horizontal stretching (error bars of the resistance represent the variations from 5 samples);

FIG. 54 illustrates a UPS test result of PEIE_PFN-Br composite film;

FIG. 55 illustrates a UV-vis absorption spectrum of PEIE_PFN-Br composite film;

FIG. 56 illustrates optical microscope images of PEIE_PFN-Br composite films of 50%, 60%, 70%, and 100% strains under horizontal stretching;

FIG. 57 illustrates an optical microscope image of PFI;

FIG. 58 illustrates an optical microscope image of PEDOT:PSS_PFI composite film;

FIG. 59 illustrates Raman spectra of PEDOT:PSS and PEDOT:PSS_PFI film under 632.8 nm laser excitation;

FIG. 60 illustrates a flow diagram of the device fabrication process for the stretchable OLED device of FIG. 47;

FIG. 61 illustrates a photograph of the stretchable OLED device of FIG. 47 powered by a 9 volt battery;

FIG. 62 illustrates J-V-L curves of the stretchable OLED device of FIG. 47;

FIG. 63 illustrates EQE-J traces measured from both anode- and cathode-sides and the calculated total of the stretchable OLED device of FIG. 47;

FIG. 64 illustrates EL spectra and a CIE chromaticity diagram marked with an emission coordinate insert of the stretchable OLED device of FIG. 47 working at 9 volts with different strains;

FIG. 65 illustrates normalized luminance intensity (L/L₀) and external quantum efficiency (EQE/EQE₀) of the stretchable OLED device of FIG. 47 at different strains (the error bars of L/L₀ and EQE/EQE₀ represent the variations with different samples;

FIG. 66 illustrates optical images of the stretchable OLED device of FIG. 47 working at 9 volts with different strains;

FIG. 67 illustrates a ¹H NMR spectrum of 2,4-bis(4-bromo-3-methylphenyl)-6-(4-fluoro-3-methylphenyl)-1,3,5-triazine (Compound 9);

FIG. 68 illustrates a ¹H NMR spectrum of 9-(4-(4,6-bis(4-bromo-3-methylphenyl)-1,3,5-triazin-2-yl)-2-methylphenyl)-3,6-di-tert-butyl-9H-carbazole (Compound 10);

FIG. 69 illustrates a ¹H NMR spectrum of 1,10-bis(4-(4,4,5,5-tetramethyl-1,3,2-dioxa-borolan-2-yl)phenoxy)decane (Compound 11);

FIG. 70 illustrates a ¹H NMR spectrum of 9-(4-(4,6-bis(4′-methoxy-2-methyl-[1,1′-biphenyl]-4-yl)-1,3,5-triazin-2-yl)-2-methylphenyl)-3,6-di-tert-butyl-9H-carbazole (Compound 12);

FIG. 71 illustrates a ¹H NMR spectrum of 2-(4-(diphenylamino)phenyl)anthracene-9,10-dione (Compound 13);

FIG. 72 illustrates a ¹H NMR spectrum of PTrz-tBuCz in CDCl₃;

FIG. 73 illustrates a representative blue-light EL spectrum of an OLED with PTrz-tBuCz as the emitting layer;

FIG. 74 illustrates a representative red-light EL spectrum of an OLED with PTrz-tBuCz as the emitting layer;

FIG. 75 illustrates an EQE-current density plot of an OLED with a PTrz-tBuCz emitting layer compared to an OLED with the small molecule emitter Trz-tBuCz (Compound 10); and

FIG. 76 illustrates an EQE-current density plot of an OLED with PTrz-tBuCz_30% TPA-AQ emitting layer, compared to an OLED with mCP_30% TPA-AQ emitting layer.

The drawings described herein are for illustration purposes only and are not intended to limit the scope of the present disclosure in any way.

### DETAILED DESCRIPTION

The following description is merely exemplary in nature and is not intended to limit the present disclosure, application, or uses.

In describing elements of the present disclosure, the terms “1l”,” “_{2nd},” “first,” “second,” “A,” “B,” “(a),” “(b),” and the like may be used herein. These terms are only used to distinguish one element from another element, but do not limit the corresponding elements irrespective of the nature or order of the corresponding elements.

Numerical values, including endpoints of ranges, can be expressed herein as approximations preceded by the term “about,” “approximately,” or the like. In such cases, other embodiments include the particular numerical values. Regardless of whether a numerical value is expressed as an approximation, two embodiments are included in this disclosure: one expressed as an approximation, and another not expressed as an approximation. It will be further understood that an endpoint of each range is significant both in relation to another endpoint, and independently of another endpoint.

The uses of the terms “a” and “an” and “the” and similar referents in the context of describing the present disclosure (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein may be performed in any suitable order unless otherwise indicated herein or otherwise clearly contradicted by context.

As used herein, the terms “comprise(s),” “include(s),” “having,” “has,” “can,” “contain(s),” and variants thereof, are intended to be open-ended transitional phrases, terms, or words that do not preclude the possibility of additional acts, structures, elements, or components. The present description also contemplates other embodiments “comprising,” “consisting of,” and “consisting essentially of” the examples or elements presented herein, whether explicitly set forth or not.

As used herein, the term “about,” when used in the context of a numerical value or range set forth means a variation of ±15%, or less, of the numerical value. For example, a value differing by ±15%, ±14%, ±10%, or ±5%, among others, would satisfy the definition of “about,” unless more narrowly defined in particular instances.

As used herein, unless otherwise stated, the term “dihedral angle,” refers to the angle between two intersecting planes or half-planes. In chemistry, a dihedral angle refers to the clockwise angle between half-planes through two sets of three atoms, having two atoms in common. For example, in (4-(9,9-dimethylacridin-10(9H)-yl)phenyl)(phenyl)methanone, shown below, there is a dihedral angle of 87.5° (indicated by the curved arrow) between the plane including the 4-(9,9-dimethylacridin-10(9H)-yl) substituent (except for the 9,9-dimethyl groups) and the plane including the phenyl(phenyl)methanone groups:

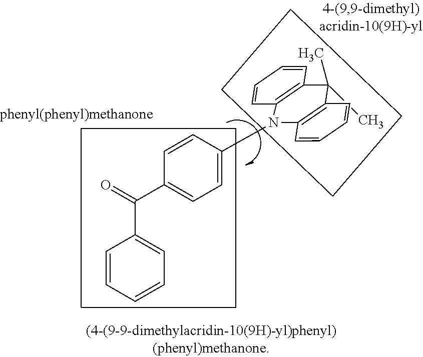 [SMILES: CC1(C)c2ccccc2N(c2ccc(C(=O)c3ccccc3)cc2)c2ccccc21]

As used herein, unless otherwise stated, the term “donor” (“D”) refers to a chemical species that can donate electrons to another chemical species.

In examples of stretchable light-emitting polymers of the present disclosure, examples of donors or donor chemical moieties may include the following chemical species, wherein an atom selected from carbon and nitrogen is bonded to the acceptor:

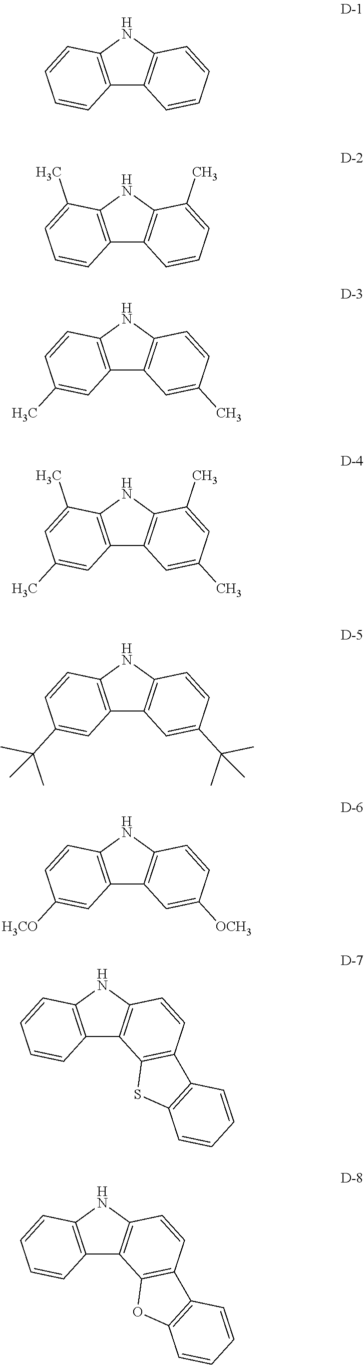

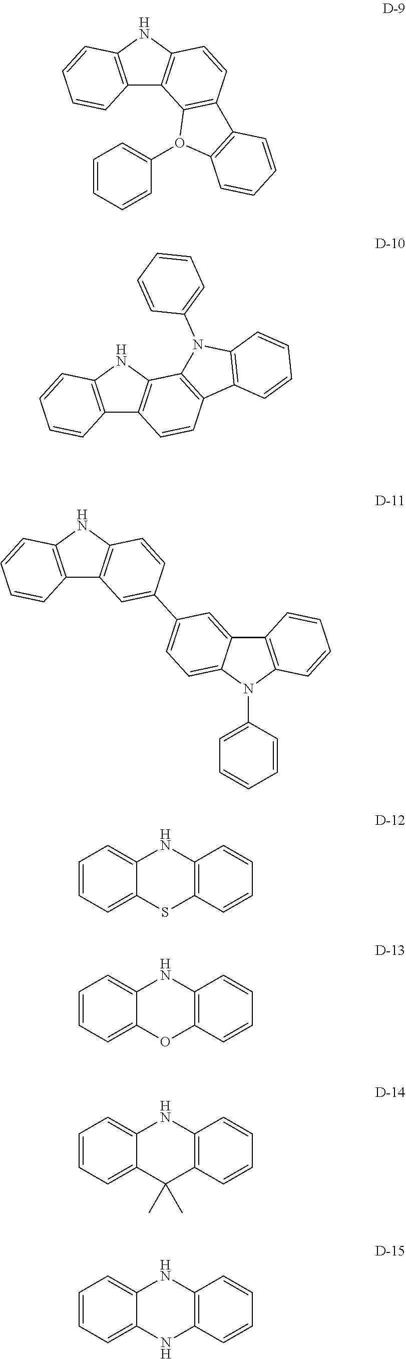

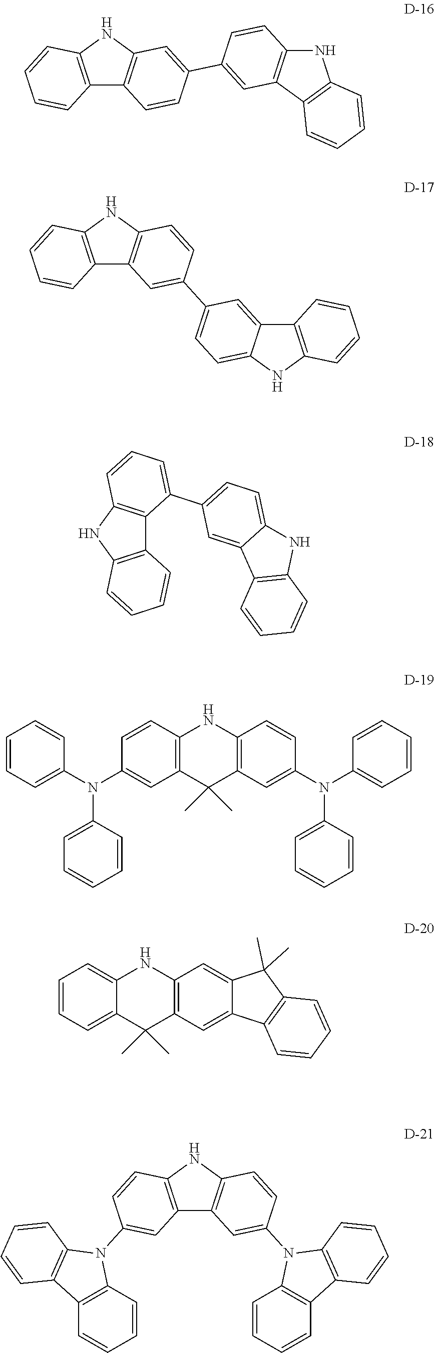 [SMILES: c1ccc2c(c1)[nH]c1cc(-c3ccc4[nH]c5ccccc5c4c3)ccc12 ; c1ccc2c(c1)[nH]c1ccc(-c3ccc4[nH]c5ccccc5c4c3)cc12 ; c1ccc2c(c1)[nH]c1ccc(-c3cccc4[nH]c5ccccc5c34)cc12 ; CC1(C)c2cc(N(c3ccccc3)c3ccccc3)ccc2Nc2ccc(N(c3ccccc3)c3ccccc3)cc21 ; CC1(C)c2ccccc2Nc2cc3c(cc21)-c1ccccc1C3(C)C ; c1ccc2c(c1)c1ccccc1n2-c1ccc2[nH]c3ccc(-n4c5ccccc5c5ccccc54)cc3c2c1]

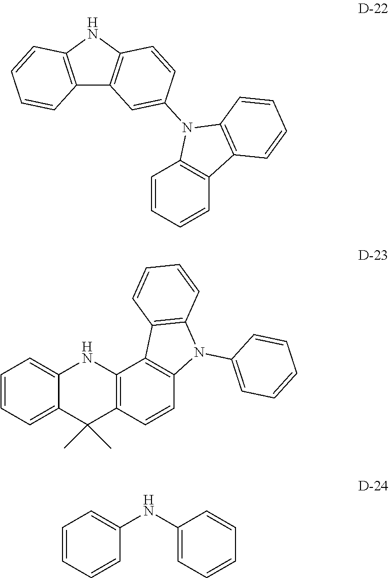

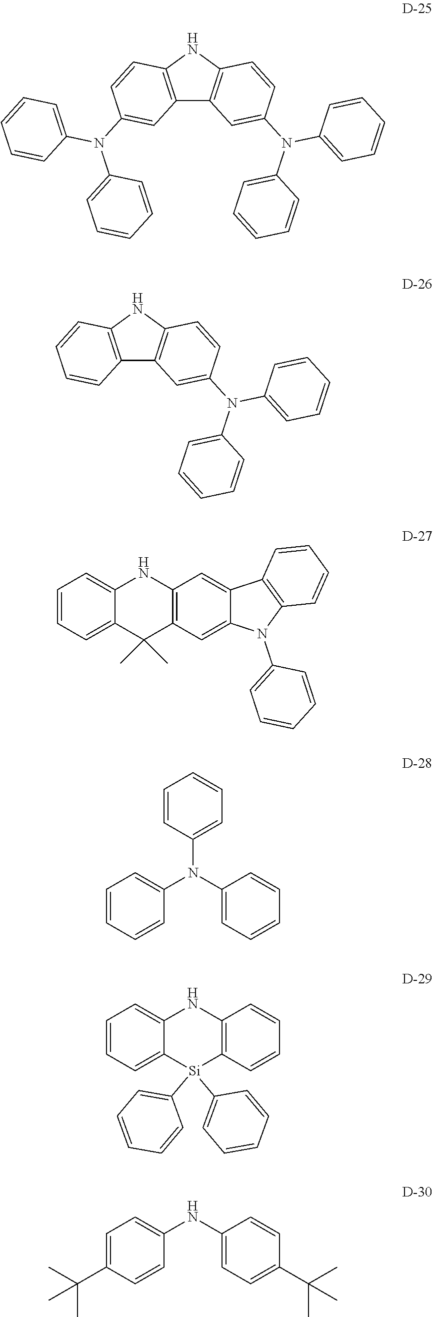 [SMILES: c1ccc(N(c2ccccc2)c2ccc3[nH]c4ccc(N(c5ccccc5)c5ccccc5)cc4c3c2)cc1 ; c1ccc(N(c2ccccc2)c2ccc3[nH]c4ccccc4c3c2)cc1 ; CC1(C)c2ccccc2Nc2cc3c4ccccc4n(-c4ccccc4)c3cc21 ; c1ccc(N(c2ccccc2)c2ccccc2)cc1 ; c1ccc([Si]2(c3ccccc3)c3ccccc3Nc3ccccc32)cc1 ; CC(C)(C)c1ccc(Nc2ccc(C(C)(C)C)cc2)cc1]

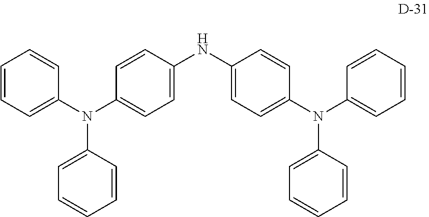 [SMILES: c1ccc(N(c2ccccc2)c2ccc(Nc3ccc(N(c4ccccc4)c4ccccc4)cc3)cc2)cc1]

As used herein, unless otherwise stated, the term “acceptor” (“A”) refers to a chemical species that can accept electrons transferred to the chemical species from another chemical species.

In examples of stretchable light-emitting polymers of the present disclosure, examples of acceptors or acceptor chemical moieties may include the following chemical species, wherein a first atom selected from carbon, nitrogen, boron, and sulfur is bonded to the donor, and a second atom and a third atom each selected from carbon, nitrogen, boron, and sulfur are each bonded to the stretchable section:

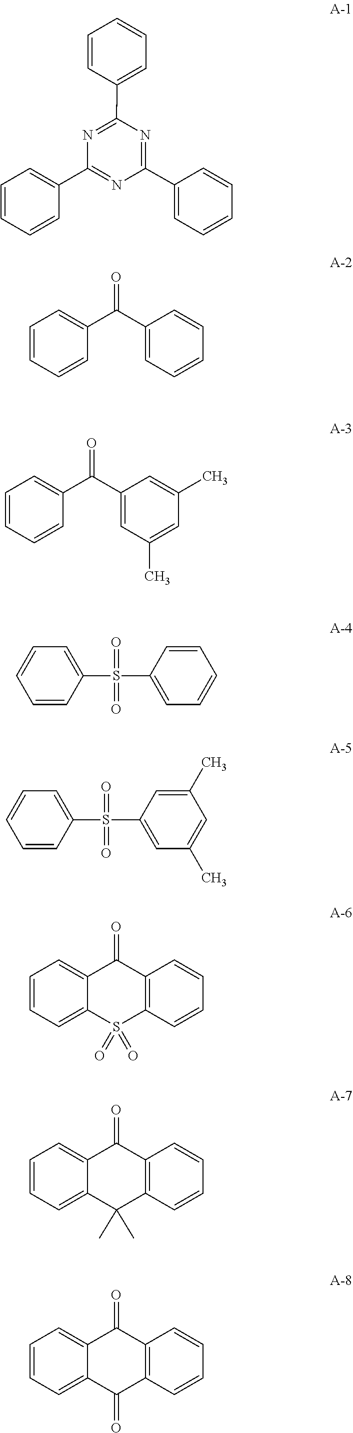

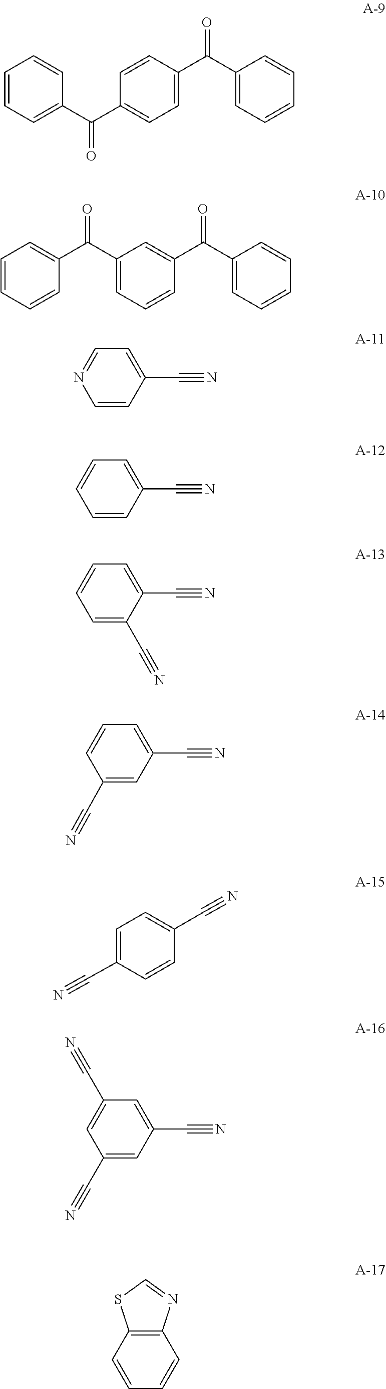

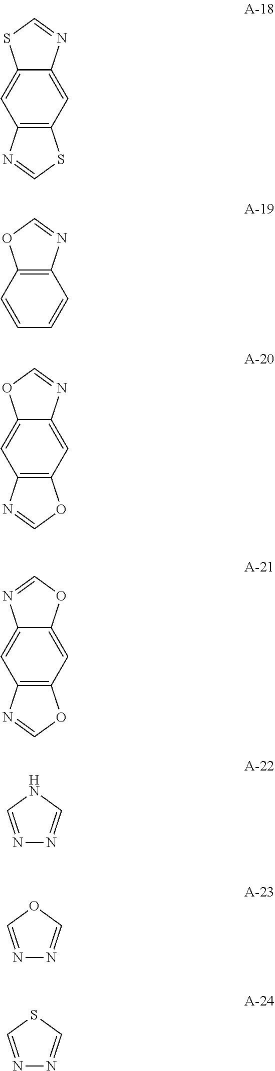

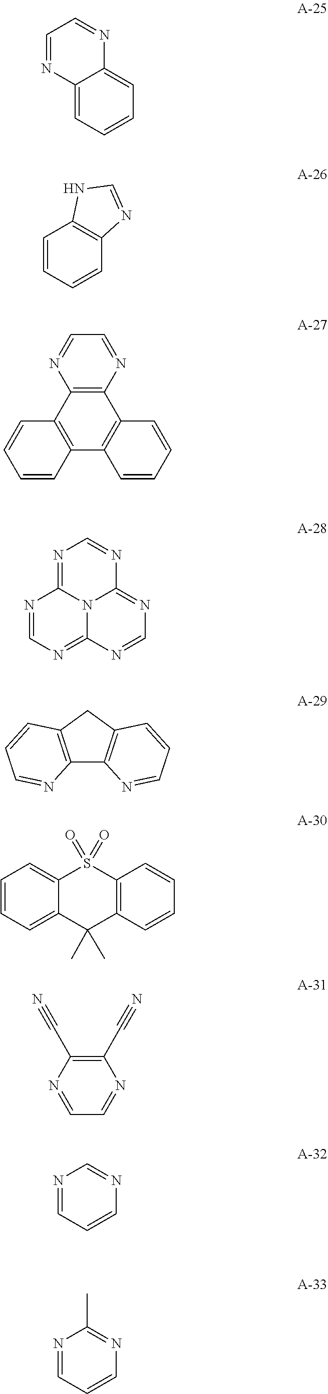

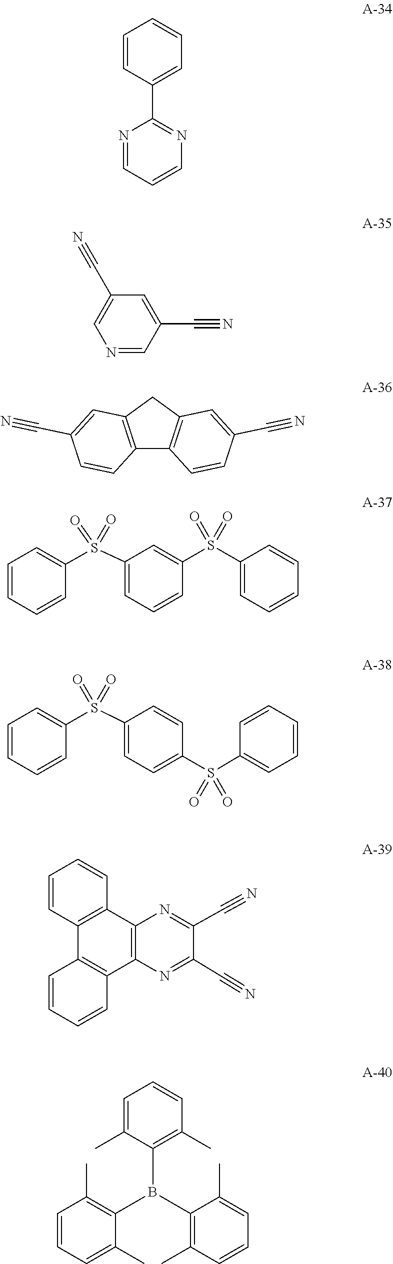

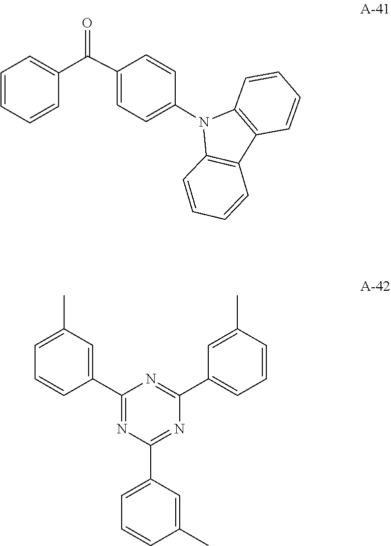 [SMILES: O=C(c1ccccc1)c1ccc(-n2c3ccccc3c3ccccc32)cc1 ; Cc1cccc(-c2nc(-c3cccc(C)c3)nc(-c3cccc(C)c3)n2)c1]

As used herein, unless otherwise stated, the term “donor-acceptor pair” (“D-A” or “T”) refers to a chemical species produced by donation of elections from a donor to an acceptor. In examples of stretchable light-emitting polymers of the present disclosure, examples of donor-acceptor pairs may include a chemical species made up of any atom of one of the above examples of donors chemically bonded to any atom of any one of the above examples of acceptors.

In examples of the stretchable light-emitting polymers of the present disclosure, a dihedral angle along the bond between the chemically bonded donor and acceptor of a donor-acceptor pair may be an angle of from about 75.0°, or from about 75.5°, or from about 76.0°, or from about 76.5°, or from about 77.0°, or from about 77.5°, or from about 78.0°, or from about 78.5°, or from about 79.0°, or from about 79.5°, or from about 80.0°, or from about 80.5°, or from about 81.0°, or from about 81.5°, or from about 82.0°, or from about 82.5°, or from about 83.0°, or from about 83.5°, or from about 84.0°, or from about 84.5°, or from about 85.0°, or from about 85.5°, or from about 86.0°, or from about 86.5°, or from about 87.0°, or from about 87.5°, or from about 88.0°, or from about 88.5°, or from about 89.0°, or from about 89.5° to about 90.0°; or a dihedral angle along the bond between the chemically bonded donor and acceptor of a donor-acceptor pair may be an angle of from about 75.0° to about 89.5°, or to about 89.0°, or to about 88.5°, or to about 88.0°, or to about 87.5°, or to about 87.0°, or to about 86.5°, or to about 86.0°, or to about 85.5°, or to about 85.0°, or to about 84.5°, or to about 84.0°, or to about 83.5°, or to about 83.0°, or to about 82.5°, or to about 82.0°, or to about 81.5°, or to about 81.0°, or to about 80.5°, or to about 80.0°, or to about 79.5°, or to about 79.0°, or to about 78.5°, or to about 78.0°, or to about 77.5°, or to about 77.0°, or to about 76.5°, or to about 76.0°, or to about 75.5°; or any other range of from about one of the above minima to about one of the above maxima.

In examples of the stretchable light-emitting polymers of the present disclosure, the stretchable light-emitting polymers include a stretchable section. Examples of the stretchable section may include a repeating molecular substructure having a formula (S-1), (S-2), or (S-3) shown below:

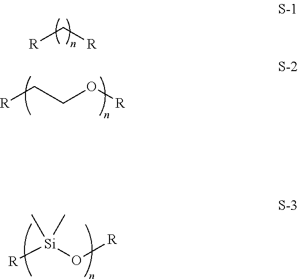

In examples of the stretchable section above, n is an integer that may have a value of 1, 2, 3, 4, 5, 6, 7, 8, 9, 10, or from 1 to 50, or to 49, or to 48, or to 47, or to 46, or to 45, or to 44, or to 43, or to 42, or to 41, or to 40, or to 39, or to 38, or to 37, or to 36, or to 35, or to 34, or to 33, or to 32, or to 31, or to 30, or to 29, or to 28, or to 27, or to 26, or to 25, or to 24, or to 23, or to 22, or to 21, or to 20, or to 19, or to 18, or to 17, or to 16, or to 15, or to 14, or to 13, or to 12, or to 11, or to 10.

In examples of the stretchable section above, each R is independently a molecular substructure or moiety. Examples of R may include molecular substructures or moieties, bonded in either direction, having a formula shown below:

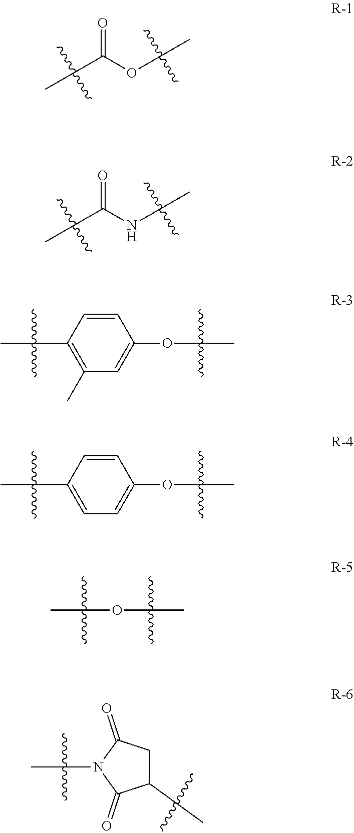

The term “alkylene,” by itself or as part of another substituent, means, unless otherwise stated, a straight, branched, or cyclic chain bivalent saturated aliphatic radical having the number of carbon atoms designated (for example, “C₁-C₃₀” means one to thirty carbons) such as methylene (“C₁alkylene,” or “—CH₂—”) or that may be derived from an alkane by opening of a double bond or from an alkane by removal of two hydrogen atoms from different carbon atoms. Examples include methylene, methylmethylene, ethylene, propylene, ethylmethylene, dimethylmethylene, methylethylene, butylene, cyclopropylmethylene, dimethylethylene, and propylmethylene.

Examples of stretchable light-emitting polymers of the present disclosure may include stretchable light-emitting polymers of formula (I), (II), (III), (IV), and/or (V):

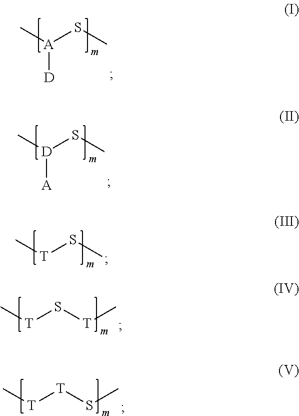

wherein D is a donor chemical moiety, capable of donating electrons;
A is an acceptor chemical moiety, capable of accepting electrons;
T is a chemical moiety including D bonded to A;
the dihedral angle of a bond between D and A is from about 75.0° to about 90.0°;
S is a stretchable section, including a chemical moiety that may repeat that is capable of stretching, examples of which may include alkylene chains and polyethylene glycol chains; and
m is an integer that may have a value of from 1 to 100, or to 95, or to 90, or to 85, or to 80, or to 75, or to 70, or to 65, or to 60, or to 55, or to 50, or to 45, or to 40, or to 35, or to 30, or to 25, or to 20, or to 15, or to 10; or a value of from 2, or from 3, or from 4, or from 5, or from 6, or from 7, or from 8, or from 9, or from 10, or from 11, or from 12, or from 13 or from 14, or from 15, or from 16, or from 17, or from 18, or from 19, or from 20, or from 25, or from 30, or from 35, or from 40, or from 45, or from 50, or from 55, or from 60, or from 65, or from 70, or from 75, or from 80, or from 85, or from 90, or from 95 to 100, or from any one of the above minima to any one of the above maxima.

In an example, a stretchable organic light-emitting diode according to the present disclosure includes: a cathode layer; an anode layer; a film including a stretchable light-emitting polymer of formula (I), (II), (III), (IV), and/or (V); a stretchable electron injection layer between the cathode layer and the film; and a stretchable hole transporting layer between the anode layer and the film. The cathode layer and the anode layer may include thermoplastic polyurethane including transparent silver nanowire. The electron injection layer may include poly[(9,9-bis(3′-((N,N-dimethyl)-N-ethylammonium)-propyl)-2,7-fluorene)-alt-2,7-(9,9-dioctylfluorene)](PFN-Br) and polyethyleneimine ethoxylated (PEIE) in a weight ratio of from about 2:1 to about 1:4. The hole transporting layer may include poly(3,4-ethylenedioxythiophene) poly(styrenesulfonate) (PEDOT:PSS) with perfluorinated ionomers (PFA) in a weight ratio of from about 3:1 to about 1:50.

In some examples, the weight ratio of poly[(9,9)-bis(3′-((N,N-dimethyl)-N-ethylammonium)-propyl)-2,7-fluorene)-alt-2,7-(9,9-dioctylfluorene)](PFN-Br) to polyethyleneimine ethoxylated (PEIE) may be in the range from about 2:1, or from about 1.9:1, or from about 1.8:1, or from about 1.7:1, or from about 1.6:1, or from about 1.5:1, or from about 1.4:1, or from about 1.3:1, or from about 1.2:1, or from about 1.1:1, or from about 1:1, or from about 1:1.1, or from about 1:1.2, or from about 1:1.3, or from about 1:1.4, or from about 1:1.5, or from about 1:1.6, or from about 1:1.7, or from about 1:1.8, or from about 1:1.9, or from about 1:2, or from about 1:2.1, or from about 1:2.2, or from about 1:2.3, or from about 1:2.4, or from about 1:2.5, or from about 1:2.6, or from about 1:2.7, or from about 1:2.8, or from about 1:2.9, or from about 1:3, or from about 1:3.1, or from about 1:3.2, or from about 1:3.3, or from about 1:3.4, or from about 1:3.5, or from about 1:3.6, or from about 1:3.7, or from about 1:3.8, or from about 1:3.9 to about 1:4; or from about 2:1 to about 1.9:1, or to about 1.8:1, or to about 1.7:1, or to about 1.6:1, or to about 1.5:1, or to about 1.4:1, or to about 1.3:1, or to about 1.2:1, or to about 1.1:1, or to about 1:1, or to about 1:1.1, or to about 1:1.2, or to about 1:1.3, or to about 1:1.4, or to about 1:1.5, or to about 1:1.6, or to about 1:1.7, or to about 1:1.8, or to about 1:1.9, or to about 1:2, or to about 1:2.1, or to about 1:2.2, or to about 1:2.3, or to about 1:2.4, or to about 1:2.5, or to about 1:2.6, or to about 1:2.7, or to about 1:2.8, or to about 1:2.9, or to about 1:3, or to about 1:3.1, or to about 1:3.2, or to about 1:3.3, or to about 1:3.4, or to about 1:3.5, or to about 1:3.6, or to about 1:3.7, or to about 1:3.8, or to about 1:3.9, or to about 1:4; or all ranges and sub-ranges therebetween. In other examples, the weight ratio of poly[(9,9)-bis(3′-((N,N-dimethyl)-N-ethylammonium)-propyl)-2,7-fluorene)-alt-2.7-(9,9-dioctylfluorene)](PFN-Br) to polyethyleneimine ethoxylated (PEIE) may be 2:1, or 1.9:1, or 1.8:1, or 1.7:1, or 1.6:1, or 1.5:1, or 1.4:1, or 1.3:1, or 1.2:1, or 1.1:1, or 1:1, or 1:1.1, or 1:1.2, or 1:1.3, or 1:1.4, or 1:1.5, or 1:1.6, or 1:1.7, or 1:1.8, or 1:1.9, or 1:2, or 1:2.1, or 1:2.2, or 1:2.3, or 1:2.4, or 1:2.5, or 1:2.6, or 1:2.7, or 1:2.8, or 1:2.9, or 1:3, or 1:3.1, or 1:3.2, or 1:3.3, or 1:3.4, or 1:3.5, or 1:3.6, or 1:3.7, or 1:3.8, or 1:3.9, or 1:4.

In some examples, the weight ratio of poly(3,4-ethylenedioxythiophene) poly(styrenesulfonate) (PEDOT:PSS) to perfluorinated ionomers (PFI) may be in the range from about 3:1, or from about 2.9:1, or from about 2.8:1, or from about 2.7:1, or from about 2.6:1, or from about 2.5:1, or from about 2.4:1, or from about 2.3:1, or from about 2.2:1, or from about 2.1:1, or from about 2:1, or from about 1.9:1, or from about 1.8:1, or from about 1.7:1, or from about 1.6:1, or from about 1.5:1, or from about 1.4:1, or from about 1.3:1, or from about 1.2:1, or from about 1.1:1, or from about 1:1, or from about 1:1.1, or from about 1:1.2, or from about 1:1.3, or from about 1:1.4, or from about 1:1.5, or from about 1:1.6, or from about 1:1.7, or from about 1:1.8, or from about 1:1.9, or from about 1:2, or from about 1:2.1, or from about 1:2.2, or from about 1:2.3, or from about 1:2.4, or from about 1:2.5, or from about 1:2.6, or from about 1:2.7, or from about 1:2.8, or from about 1:2.9, or from about 1:3, or from about 1:3.1, or from about 1:3.2, or from about 1:3.3, or from about 1:3.4, or from about 1:3.5, or from about 1:3.6, or from about 1:3.7, or from about 1:3.8, or from about 1:3.9, or from about 1:4, or from about 1:4.1, or from about 1:4.2, or from about 1:4.3, or from about 1:4.4, or from about 1:4.5, or from about 1:4.6, or from about 1:4.7, or from about 1:4.8, or from about 1:4.9, or from about 1:5, or from about 1:6, or from about 1:7, or from about 1:8, or from about 1:9, or from about 1:10, or from about 1:11, or from about 1:12, or from about 1:13, or from about 1:14, or from about 1:15, or from about 1:16, or from about 1:17, or from about 1:18, or from about 1:19, or from about 1:20, or from about 1:21, or from about 1:22, or from about 1:23, or from about 1:24, or from about 1:25, or from about 1:26, or from about 1:27, or from about 1:28, or from about 1:29, or from about 1:30, or from about 1:31, or from about 1:32, or from about 1:33, or from about 1:34, or from about 1:35, or from about 1:36, or from about 1:37, or from about 1:38, or from about 1:39, or from about 1:40, or from about 1:41, or from about 1:42, or from about 1:43, or from about 1:44, or from about 1:45, or from about 1:46, or from about 1:47, or from about 1:48, or from about 1:49 to about 1:50; or from about 3:1 to about 2.9:1, or to about 2.8:1, or to about 2.7:1, or to about 2.6:1, or to about 2.5:1, or to about 2.4:1, or to about 2.3:1, or to about 2.2:1, or to about 2.1:1, or to about 2:1, or to about 1.9:1, or to about 1.8:1, or to about 1.7:1, or to about 1.6:1, or to about 1.5:1, or to about 1.4:1, or to about 1.3:1, or to about 1.2:1, or to about 1.1:1, or to about 1:1, or to about 1:1.1, or to about 1:1.2, or to about 1:1.3, or to about 1:1.4, or to about 1:1.5, or to about 1:1.6, or to about 1:1.7, or to about 1:1.8, or to about 1:1.9, or to about 1:2, or to about 1:2.1, or to about 1:2.2, or to about 1:2.3, or to about 1:2.4, or to about 1:2.5, or to about 1:2.6, or to about 1:2.7, or to about 1:2.8, or to about 1:2.9, or to about 1:3, or to about 1:3.1, or to about 1:3.2, or to about 1:3.3, or to about 1:3.4, or to about 1:3.5, or to about 1:3.6, or to about 1:3.7, or to about 1:3.8, or to about 1:3.9, or to about 1:4, or to about 1:4.1, or to about 1:4.2, or to about 1:4.3, or to about 1:4.4, or to about 1:4.5, or to about 1:4.6, or to about 1:4.7, or to about 1:4.8, or to about 1:4.9, or to about 1:5, or to about 1:6, or to about 1:7, or to about 1:8, or to about 1:9, or to about 1:10, or to about 1:11, or to about 1:12, or to about 1:13, or to about 1:14, or to about 1:15, or to about 1:16, or to about 1:17, or to about 1:18, or to about 1:19, or to about 1:20, or to about 1:21, or to about 1:22, or to about 1:23, or to about 1:24, or to about 1:25, or to about 1:26, or to about 1:27, or to about 1:28, or to about 1:29, or to about 1:30, or to about 1:31, or to about 1:32, or to about 1:33, or to about 1:34, or to about 1:35, or to about 1:36, or to about 1:37, or to about 1:38, or to about 1:39, or to about 1:40, or to about 1:41, or to about 1:42, or to about 1:43, or to about 1:44, or to about 1:45, or to about 1:46, or to about 1:47, or to about 1:48, or to about 1:49, or to about 1:50; or all ranges and sub-ranges therebetween. In other examples, the weight ratio of poly(3,4-ethylenedioxythiophene) poly(styrenesulfonate) (PEDOT:PSS) to perfluorinated ionomers (PFI) may be 3:1, or 2.9:1, or 2.8:1, or 2.7:1, or 2.6:1, or 2.5:1, or 2.4:1, or 2.3:1, or 2.2:1, or 2.1:1, or 2:1, or 1.9:1, or 1.8:1, or 1.7:1, or 1.6:1, or 1.5:1, or 1.4:1, or 1.3:1, or 1.2:1, or 1.1:1, or 1:1, or 1:1.1, or 1:1.2, or 1:1.3, or 1:1.4, or 1:1.5, or 1:1.6, or 1:1.7, or 1:1.8, or 1:1.9, or 1:2, or 1:2.1, or 1:2.2, or 1:2.3, or 1:2.4, or 1:2.5, or 1:2.6, or 1:2.7, or 1:2.8, or 1:2.9, or 1:3, or 1:3.1, or 1:3.2, or 1:3.3, or 1:3.4, or 1:3.5, or 1:3.6, or 1:3.7, or 1:3.8, or 1:3.9, or 1:4, or 1:4.1, or 1:4.2, or 1:4.3, or 1:4.4, or 1:4.5, or 1:4.6, or 1:4.7, or 1:4.8, or 1:4.9, or 1:5, or 1:6, or 1:7, or 1:8, or 1:9, or 1:10, or 1:11, or 1:12, or 1:13, or 1:14, or 1:15, or 1:16, or 1:17, or 1:18, or 1:19, or 1:20, or 1:21, or 1:22, or 1:23, or 1:24, or 1:25, or 1:26, or 1:27, or 1:28, or 1:29, or 1:30, or 1:31, or 1:32, or 1:33, or 1:34, or 1:35, or 1:36, or 1:37, or 1:38, or 1:39, or 1:40, or 1:41, or 1:42, or 1:43, or 1:44, or 1:45, or 1:46, or 1:47, or 1:48, or 1:49, or 1:50.

The compositions and processes described above may be better understood in connection with the following Examples. In addition, the following non-limiting examples are an illustration. The illustrated methods are applicable to other examples of stretchable light-emitting polymers of the present disclosure. The procedures described as general methods describe what is believed will be typically effective to prepare the compositions indicated.

However, the person skilled in the art will appreciate that it may be necessary to vary the procedures for any given example of the present disclosure, e.g., vary the order or steps and/or the chemical reagents used.

### Examples

### General Information.

Number average molecular weight (Mₙ), weight average molecular weight (M_{w}), and polydispersity index (“PDI”) were evaluated by Wyatt Dawn HELEOS II multi-angle light scattering (“MALS”) instrument. Absorption was measured using Shimadzu UV-3600 Plus UV-VIS-NIR spectrophotometer. The photoluminescence (“PL”) spectra were measured with Horiba Spectrofluorometer-Fluorolog 3. The fluorescence and phosphorescence spectra were measured at 77 K using a Hitachi F-4600 fluorescence spectrometer. The measurement of the phosphorescence spectra was delayed by a chopper with a chopping speed of 40 Hz, corresponding to a delayed time of −6.25 ms. The transient photoluminescence (PL) decay was measured using a streak camera system at Argonne National Laboratory. The TA Instruments Discovery 2500 Differential Scanning Calorimeter (“DSC”) was used to measure the glass transition temperature (T_{g}). Cyclic voltammetry was performed on a Multi PalmSens4 electrochemical analyzer with 0.1 M tetra-n-butylammonium hexafluorophosphate (Bu₄NPF₆) as a supporting electrolyte, a saturated calomel electrode (“SCE”) as a reference electrode, a Pt disk as a working electrode, and a scan rate of 50 mV/s. The oxidation potential of SCE relative to the vacuum level was calibrated to be 4.662 V in dimethylformamide (“DMF”). The CV for small molecular thermally activated delayed fluorescence (“TADF”) emitter (4-(2,7-bis(4-methoxy-2-methylphenyl)-9H-carbazol-9-yl)phenyl)(4-(9,9-dimethylacridin-10(9H)-yl)phenyl)methanone (“DKC”) was measured in DMF solution, and CV for stretchable light-emitting polymers are measured as the films, deposited on the glassy carbon electrode, in the DMF solution. The PL quantum yield (“PLQY”) was measured using a LSM Series High-Power LED (310 nm, Ocean Optics) as the light source and a fiber integration sphere (FOIS-1) coupled with a QE Pro Spectrometer (Ocean Optics) as the spectrometer, the samples were held on a home-made stage to enable the light source excited on the samples, and the emitted light was collected with the integration sphere. Raman spectra were measured on the Microscope—LabRAM HR Evo Raman Confocal equipment. Transparency of AgNWs-based electrode was measured using standard Visible-NIR light source (HL-3P-INT-CAL plus, Ocean Optics) as the light source and a fiber integration sphere (FOIS-1) coupled with a QE Pro Spectrometer (Ocean Optics) as the spectrometer. All XPS and UPS measurements were conducted in a Thermo Scientific K-Alpha XPS with built-in automated calibration system and with an average base pressure of 10⁻⁸ Torr at NUNACE, Northwestern University. XPS data were collected with monochromatic Al (Kα) radiation. He I (21.22 eV) radiation line from a discharge lamp was used for UPS measurements. All of the UPS measurements were done using standard procedures with a −5 V bias applied to the sample. Gaussian09 software with the functional and basis of B3LYP/6-31G(d,p) was used to perform the Density Functional Theory (“DFT”) calculation.

### Functionalized Substrate (Si-Wafer, Glass, or Quartz) Preparation.

Ocadecyltrimethoxysilane (“OTS”) functionalized substrate was prepared according to literature procedure. See A. Chortos, et al., Highly stretchable transistors using a microcracked organic semiconductor, 26 ADVANCED MATERIALS 4253 (2014), incorporated herein by reference in its entirety. Briefly, the pre-cleaned substrate was treated by O₂ plasma for 2 minutes, the OTS solution (1 μL,/mL in trichloroethylene) was spin-coated in the ammonium hydroxide vapor overnight to form a single layer of OTS on the substrate, then sonicated in toluene for 5 minutes. Finally, the substrate was cleaned and dried for use. The 3-(trimethoxysilyl)propyl methacrylate (“MPTS”) functionalized substrate was prepared similarly to the OTS functionalized substrate, but with an additional step of cross-linking of MPTS at 150° C. for 30 minutes before use. For SEBS modified substrate, the SEBS solution (10 mg/mL in toluene) was spin-coated at 3000 rpm for 30 seconds on substrate, followed by annealing at 80° C. for 10 minutes.

### Characterization of Stretchable Thin Films.

The stretchable light-emitting polymers solution (8 mg/mL in chlorobenzene (“CB”)) was spin-coated on MPTS-modified Si substrate (“MPTS-S₁”) at 1000 rpm followed by annealing at 120° C. for 20 minutes to form a film of a thickness of around 50 nanometers. The films were transferred to pre-cured polydimethylsiloxane (“PDMS”) stamps to apply different strains and then transferred to SEBS-modified Si substrate for characterization. For PLQY measurement, the films were transferred to SEBS-modified quartz substrates. Young's modulus was measured with a previously reported buckling methodology. Stretchable light-emitting polymer films were transferred to a 10% pre-stained PDMS (base/crosslinker ratio of 10:1). When the pre-strain was released, the thin films formed periodic buckles form which the Young's modulus could be estimated. Characterization of other stretchable functional layers are similar but use OTS-modified Si substrate (“OTS-Si”) as the spin-coating substrate, with spin-coating conditions that are the same as the films used in the fully stretchable OLEDs. The poly(3,4-ethylenedioxythiophene) polystyrene sulfonate perfluorinated ionomer (“PEDOT:PSS_PFI”) composite film was measured on both OTS-Si substrate for the top side measurement and transferred onto PDMS substrate for the bottom side for XPS measurement.

### Conventional, Rigid OLEDs Fabrication and Testing.

Indium tin oxide (“ITO”) coated glasses were first cleaned with 1 vol. % Hellmanex solution, isopropyl alcohol (“IPA”), and deionized (“DI”) water, then dried, and treated with plasma. Poly(3,4-ethylenedioxythiophene) polystyrene sulfonate (“PEDOT:PSS”) was spin-coated on ITO substrates at 4500 rpm for 1 minute as hole injection layer/hole transporting layer (“HIL/HTL”), followed by annealing at 150° C. for 30 minutes. Then, the device was transferred into the glovebox for spin-coating stretchable light-emitting polymers (8 mg/mL in CB) or small-molecule TADF emitters (DKC, 10 mg/mL in chloroform) at 2000 rpm for 30 seconds as emitting layers (“EMLs”), followed by annealing at 120° C. for 30 minutes. Then, the devices were transferred to a deposition system with a base pressure of about 4·10⁻⁴ Pa. 1,3,5-Tris(3-pyridyl-3-phenyl)benzene (“TmPyPB”) was deposited at a rate of 1 Å·s⁻¹, and the rates were 0.1 and 10 Å·s⁻¹ for LiF and Al, respectively. Current density-voltage-luminance (J-V-L) measurements were carried out at room temperature in an N₂ filled glovebox. A Keithley 2450 source meter and a fiber integration sphere FOIS-1) coupled with a QE Pro Spectrometer Ocean Optics) were used for the measurements. The OLED devices are tested on top of the integrating sphere, and only forward light emission can be collected, consistent with the standard OLEDs characterization method. The absolute OLED emission was calibrated by a standard Visible-NIR light source (HL-3P-INT-CAL Plus, Ocean Optics).

### OLEDs Fabrication for Studying the Strain Influence on Stretchable Light-Emitting Polymers.

The fabrication and measurement are similar to conventional rigid OLEDs fabrication, except the HIL/HTL and emission layer (“EML”) are different. For HIL/HTL, a mixture solution of PEDOT:PSS solution, perfluorinated ionomer (“PFI”) solution, and isopropyl alcohol (“IPA”) with a volume ratio of 1:1:5 was stirred with a vortex mixture for 30 minutes before spin-coating, after which the device was transferred into a glovebox for the following processes. Between HIL/HTL and EML, an additional layer of SEBS_mCP composite was inserted by spin-coating (carefully controlled due to poor wettability of solution on PEDOT:PSS_PFI surface). The total concentration of the mixture solution was 10 mg/mL in CB with a weight ratio of 1:1. The mixture was spin-coated with a speed of 3000 rpm for 30 seconds, followed by annealing at 80° C. for 15 minutes. The EML was not directly spin-coated on the seeding layer but instead on MPTS-Si. The stretchable light-emitting polymer solution (8 mg/mL in CB) was spin-coated on MPTS-Si at 2000 rpm for 30 seconds, followed by annealing at 120° C. for 30 minutes. Then the stretchable light-emitting polymer film was transferred onto the PDMS stamp and the PDMS stamp was tightly mounted onto a stretcher. After applying different strains on the stretchable light-emitting polymer film, the film was turned face down to SEBS_mCP with a gentle press to make two films well contacted, followed by baking at 85° C. for 5 minutes before releasing the PDMS stamp, resulting in printing the stretchable light-emitting polymer film on the device under different strains.

### Fabrication of Stretchable Transparent Electrode.

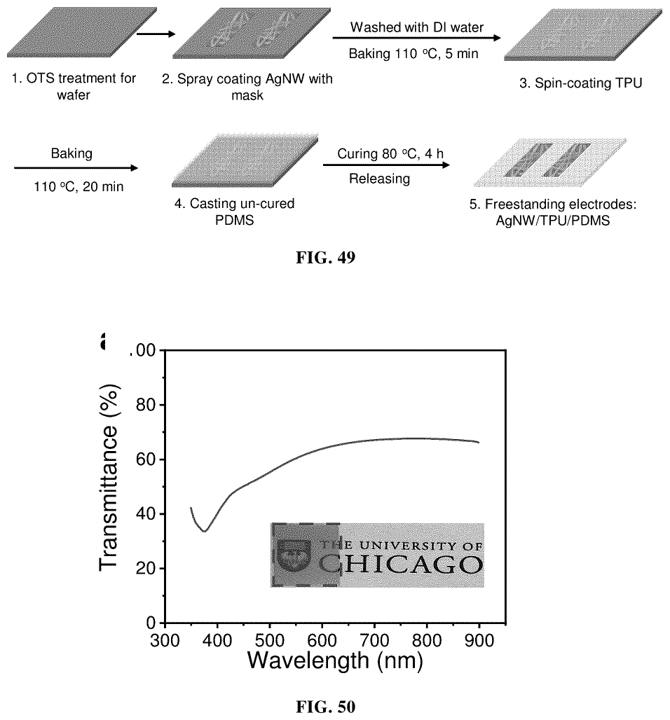

The fabrication process was schematically described in FIG. 49. Silver nanowire (“AgNWs”) solution (AW045, 1 wt % in water) was first vortexed for 10 minutes to remove big aggregations and then diluted in IPA (1:19 (v:v), AW045:IPA), followed by 10 seconds of bath sonication. The solution was spray-coated on a cleaned OTS-Si with substrate heating at 100° C. until it reached target sheet resistance. The pattern was made with Kapton-tape masks. After removing masks, the AgNWs on OTS were washed with DI water to remove the surfactant and dried at 110° C. for 5 minutes. Then, thermoplastic polyurethane (“TPU”) solution (20 mg/mL in THF) was spin-coated onto the AgNWs at 3000 rpm for 30 seconds. After drying at 110° C. for 20 minutes, the AgNWs covered by TPU were O₂-plasma treated for 1 minute. Then the PDMS mixture (base/crosslinker ratio of 15:1) was drop-casted on the TPU. After the bubble in PDMS was fully released, the PDMS was cured at 80° C. for 4 hours. The AgNWs_TPU/PDMS electrode was then ready to be used after the delamination from OTS-Si.

### Fabrication of Fully Stretchable OLEDs.

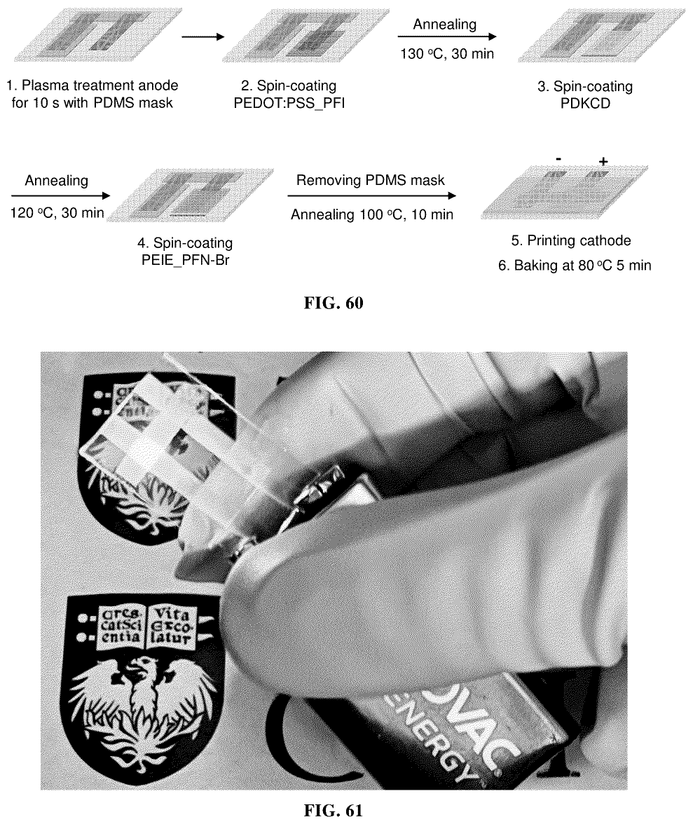

The fabrication process was schematically described in FIG. 60. The AgNWs_TPU/PDMS electrode was supported on OTS-glass and masked by pre-cured PDMS (base/crosslinker ratio of 20:1). For better electrical connection between AgNWs with Keithley input circuit, stretchable Ag/AgCl paste was cast on the tail of the AgNWs stripes, followed by curing at 80° C. for 20 minutes. Before spin-coating functional materials, the electrode was O₂-plasma treated for 10 seconds. PEDOT:PSS_PFI mixture solution was diluted with IPA (PEDOT:PSS_PFI_IPA=1:1:3 (solution V:V:V)), and spin-coated at 3000 rpm for 1 minute, then annealed at 130° C. for 30 minutes, resulting in a film with the thickness of 110 nm. Then the samples were transferred into the N₂-filled glovebox. PDKCD solution (8 mg/mL in CB) was spin-coated at 1000 rpm for 30 seconds, then annealed at 120° C. for 30 minutes. Then polyethyleneimine ethoxylated poly[(9,9-bis(3′-((N,N-dimethyl)-N-ethylammonium)-propyl)-2,7-fluorene)-alt-2.7-(9,9-dioctylfluorene)](“PEIE:PFN-Br”) solution (total 0.25 wt. % in methanol with a weight ratio of 1:1) was spin-coated 3000 rpm for 30 seconds and annealed at 100° C. for 10 minutes, resulting in a 20-nanometer film. Afterward, the PDMS masks were removed, and the samples were released from OTS-glass. The cathode electrode was gently laminated on top to finish the device fabrication. Finally, the device was heated at 80° C. for 5 minutes to enhance adhesion between the layers. The measurement conditions are the same as the rigid devices.

### Synthesis of Stretchable Light-Emitting Polymers.

All starting materials for the synthesis of examples of stretchable light-emitting polymers of the present disclosure were purchased from commercial sources and used as received.

### A. Synthetic Preparation of Light-Emitting Monomers

The TADF monomer was synthesized according to the following Scheme A:

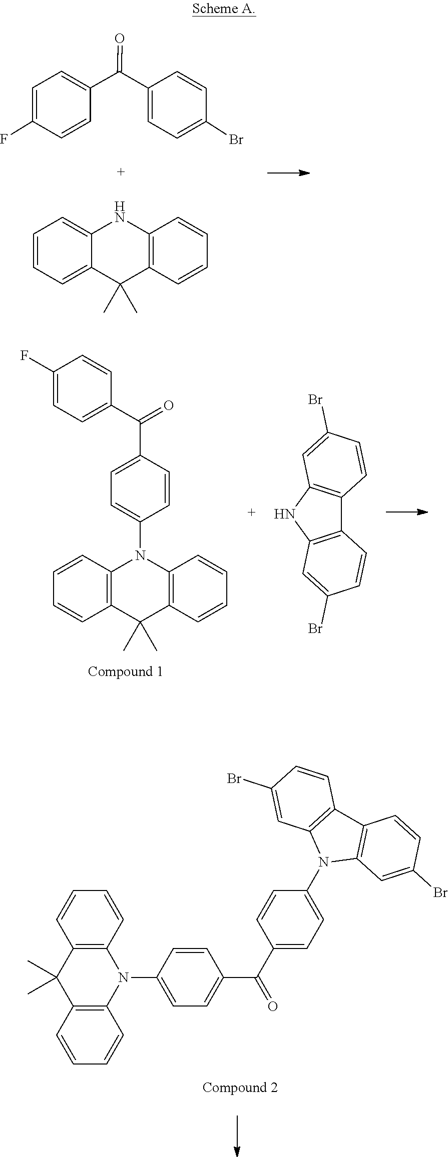 [SMILES: O=C(c1ccc(F)cc1)c1ccc(Br)cc1 ; CC1(C)c2ccccc2Nc2ccccc21 ; CC1(C)c2ccccc2N(c2ccc(C(=O)c3ccc(F)cc3)cc2)c2ccccc21 ; Brc1ccc2c(c1)[nH]c1cc(Br)ccc12 ; CC1(C)c2ccccc2N(c2ccc(C(=O)c3ccc(-n4c5cc(Br)ccc5c5ccc(Br)cc54)cc3)cc2)c2ccccc21]

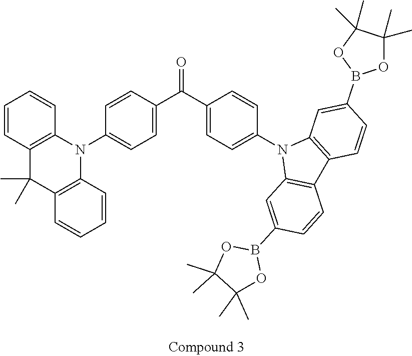

### 1. Preparation of (4-(9,9-dimethylacridin-10(9H)-yl)phenyl)(4-fluorphenyl)methanone (Compound 1)

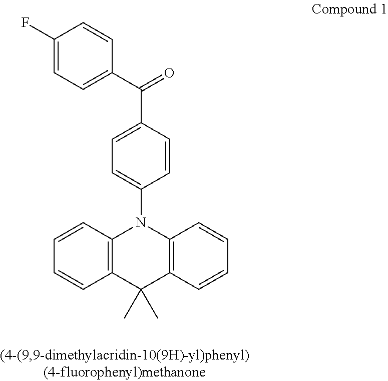 [SMILES: CC1(C)c2ccccc2N(c2ccc(C(=O)c3ccc(F)cc3)cc2)c2ccccc21]

In a double-necked 150-milliliter round-bottom flask with a magnetic stir bar, reflux condenser, and N₂ atmosphere, toluene (20 mL) was added to a mixture of (4-bromophenyl)(4-fluorophenyl)methanone (1.1 g, 4 mmol), 9,9-dimethyl-9,10-dihydroacridine (0.81 g, 4 mmol), bis(dibenzylideneacetone)dipalladium (“Pd(dba)₂”) (0.115 g, 0.2 mmol), NaOtBu (0.96 g, 10.0 mmol), and dicyclohexylphosphino-2′,4′,6-tri-i-propyl-1,1′-biphenyl (“Xphos”) (0.28 g, 0.6 mmol). The mixture was refluxed for 12 hours under a N₂ atmosphere. After the mixture was cooled to room temperature, the reaction mixture was extracted using dichloromethane and distilled water. The dichloromethane (“DCM”) phase was dried over Na₂SO₄ and then filtered.

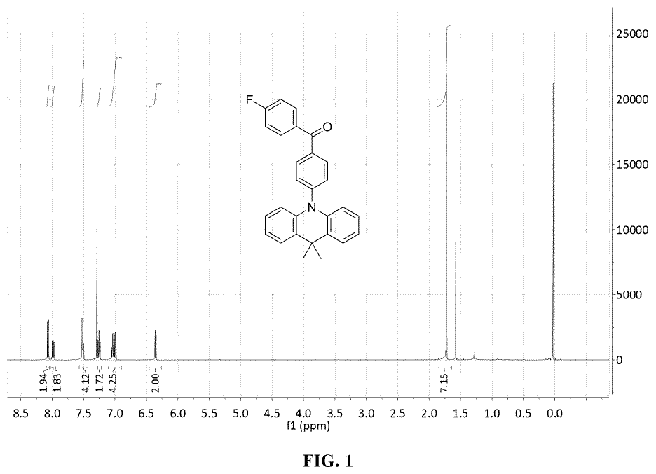

After the solvent was removed under reduced pressure, the residue was purified by column chromatography on silica gel using hexane/DCM (v/v=4:1) as eluent to give the product, after removal of solvent under reduced pressure, as a yellow powder (Compound 1, 1.28 g, yield 81%). ¹H NMR (400 MHz, CDCl₃) δ 8.07-8.01 (m, 2H), 8.00-7.92 (m, 2H), 7.54-7.44 (m, 4H), 7.25-7.19 (m, 2H), 7.05-6.92 (m, 4H), 6.33 (dd, J=8.0, 1.4 Hz, 2H), 1.70 (s, 6H). The ¹H NMR spectrum of Compound 1 is illustrated in FIG. 1.

### 2. Preparation of (4-(2,7-dibromo-9H-carbazol-9-yl)phenyl)(4-(9,9-dimethylacridin-10(9H)-yl)phenyl)methanone (Compound 2)

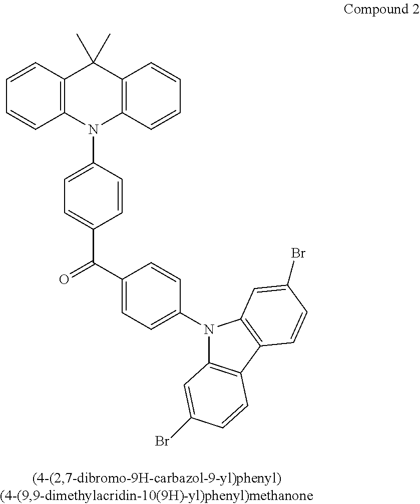 [SMILES: CC1(C)c2ccccc2N(c2ccc(C(=O)c3ccc(-n4c5cc(Br)ccc5c5ccc(Br)cc54)cc3)cc2)c2ccccc21]

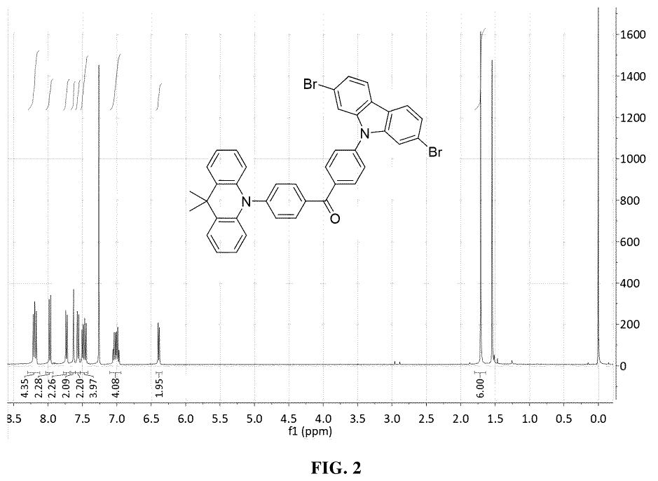

A mixture of Compound 1 (1.22 g, 3 mmol) and 2,7-dibromo-9H-carbazole (1.03 g, 3.2 mmol) in N,N-dimethylformamide (15 mL) was stirred for 15 minutes under argon atmosphere at room temperature, and then the reaction mixture was heated up to 110° C. and potassium tert-butoxide (0.35 g, 3.1 mmol) was added, followed by stirring for 12 hours. The reaction was quenched with water (20 mL), and precipitated in methanol, filtered by vacuum, and washed with methanol three times to obtain the crude product as a yellow powder (Compound 2, 2.01 g, yield 90%). ¹H NMR (400 MHz, CDCl₃) δ 8.19 (dd, J=12.4, 8.3 Hz, 4H), 7.97 (d, J=8.3 Hz, 2H), 7.73 (d, J=8.3 Hz, 2H), 7.63 (d, J=1.6 Hz, 2H), 7.56 (d, J=8.2 Hz, 2H), 7.50 (dd, J=7.7, 1.6 Hz, 2H), 7.45 (dd, J=8.3, 1.6 Hz, 2H), 7.02 (tdd, J=14.9, 10.5, 4.6 Hz, 4H), 6.39 (d, J=8.0 Hz, 2H), 1.71 (s, 6H). The ¹H NMR spectrum of Compound 2 is illustrated in FIG. 2.

### 3. Preparation of (4-(2,7-bis(4,4,5,5-tetramethyl-1,3,2-dioxaborolan-2-yl)-9H-carbazol-9-yl)phenyl)(4(9,9-dimethylacridin-10(9H)-yl)phenyl)methanone (Compound 3)

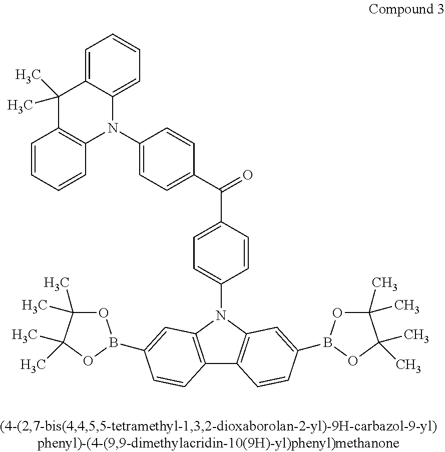

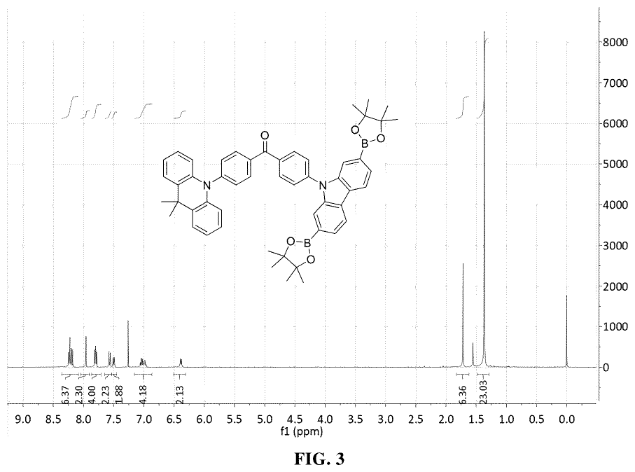

Compound 2 (1.42 g, 2 mmol), bis(pinacolato)diboron (1.52 g, 6 mmol), [1,1′-Bis(diphenylphosphino)ferrocene]dichloropalladium(II) (73 mg, 0.1 mmol), and potassium acetate (0.59 g, 6 mmol) were mixed in a flask that was vacuumed and filled with a nitrogen atmosphere three times. Degassed DMF (15 mL) was added and the system was heated to 100° C. and stirred for 12 hours. When the temperature cooled down to room temperature, the mixture was precipitated into 100 mL saturated sodium chloride solution, filtered by vacuum to obtain the crude product, and purified by column chromatography on silica gel (short ˜15 cm) using first Hexane/DCM in a 1:3 v/v ratio, and then DCM, as eluent, to give the product, after removal of solvent under reduced pressure, as a yellow powder (Compound 3, 0.81 g, yield 50.1%). ¹H NMR (400 MHz, CDCl₃) δ 8.29-8.13 (m, 6H), 7.95 (s, 2H), 7.80 (t, J=7.8 Hz, 4H), 7.56 (d, J=8.4 Hz, 2H), 7.49 (d, J=7.7 Hz, 2H), 7.01 (dt, J=13.7, 7.3 Hz, 4H), 6.38 (d, J=7.0 Hz, 2H), 1.72 (s, 6H), 1.36 (s, 24H). The ¹H NMR spectrum of Compound 3 is illustrated in FIG. 3.

The Trz-tBuCz monomer was synthesized according to the following Scheme Al:

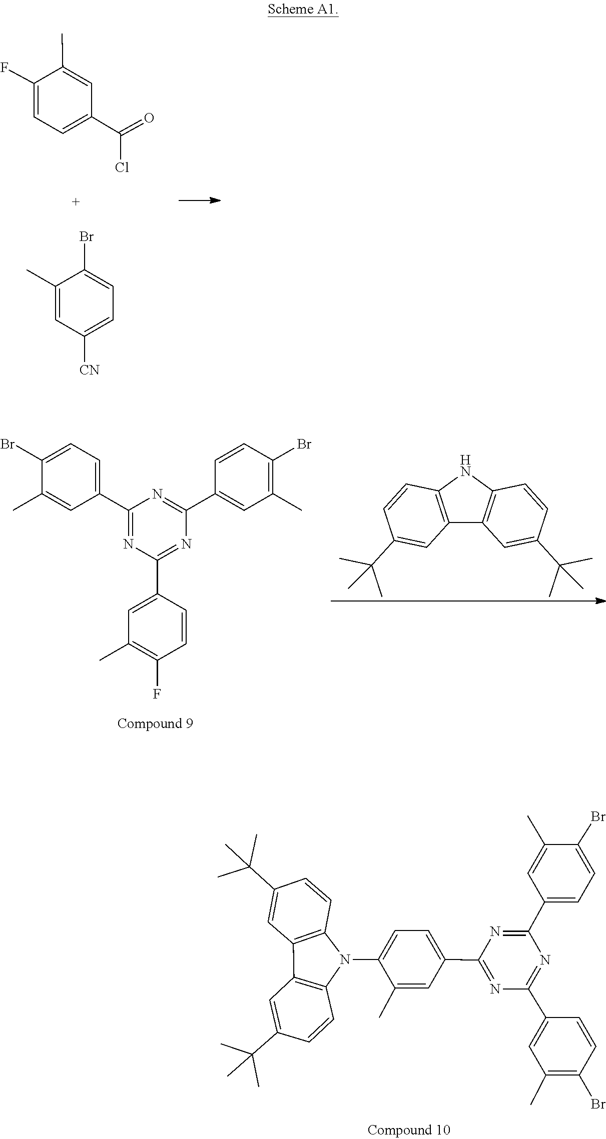

### 4. Preparation of 2,4-bis(4-bromo-3-methylphenyl)-6-(4-fluoro-3-methylphenyl)-1,3,5-triazine (Compound 9)

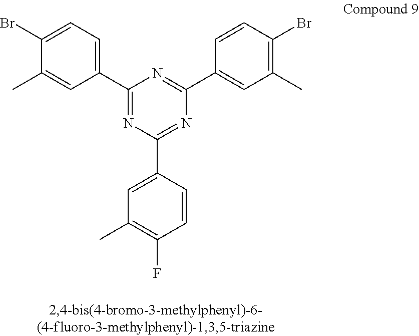 [SMILES: Cc1cc(-c2nc(-c3ccc(Br)c(C)c3)nc(-c3ccc(Br)c(C)c3)n2)ccc1F]

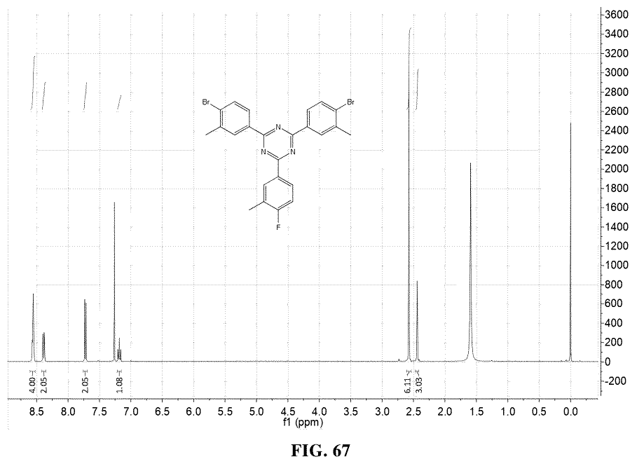

4-fluoro-3-methylbenzoyl chloride (1.72 g, 10 mmol) and 4-bromo-3-methylbenzonitrile (3.92 g, 20 mmol) were added to chlorobenzene (30 mL) and the solution was cooled to 0° C. To the solution, antimony(V) chloride (3.00 g, 10 mmol) was added drop-wise. The mixture was stirred for 20 minutes and warmed to room temperature, then heated at 100° C. for 2 hours. The resulting orange slurry of the oxadiazinium salt was cooled to 0° C. With vigorous stirring, 28% NH₃ aqueous solution (40 mL) was added to the slurry, and a white precipitate of Compound 9 was immediately formed as a white slurry. The precipitate was collected by filtration and washed with a mixture of water and methanol. The product was purified by column chromatography on silica gel using hexane/dichloromethane (“DCM”) (v/v=4:1) as eluent to give a white solid product after removal of solvent under reduced pressure (Compound 9, 2.9 g, yield 55.0%). ¹H NMR (400 MHz, CDCl₃) δ 8.65-8.45 (m, 4H), 8.39 (dd, J=8.3, 2.1 Hz, 2H), 7.72 (d, J=8.3 Hz, 2H), 7.23-7.13 (m, 1H), 2.57 (s, 6H), 2.43 (t, J=6.5 Hz, 3H). The ¹H NMR spectrum of Compound 9 is illustrated in FIG. 67.

### 5. Preparation of 9-(4-(4,6-bis(4-bromo-3-methylphenyl)-1,3,5-triazin-2-yl)-2-methylphenyl)-3,6-di-tert-butyl-9H-carbazole (Compound 10)

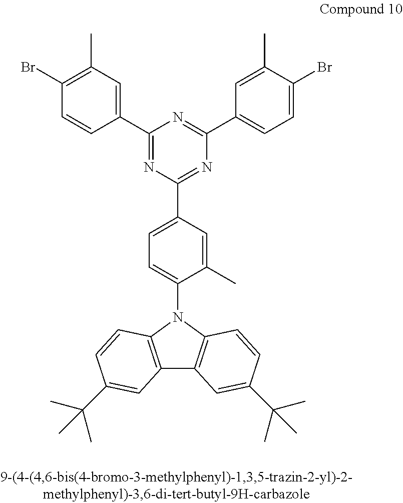 [SMILES: Cc1cc(-c2nc(-c3ccc(Br)c(C)c3)nc(-c3ccc(-n4c5ccc(C(C)(C)C)cc5c5cc(C(C)(C)C)ccc54)c(C)c3)n2)ccc1Br]

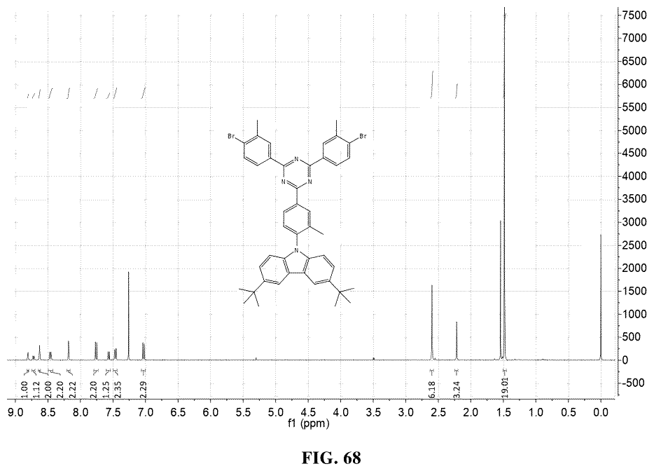

A solution of Compound 9 (0.58 g, 1 mmol), 3,6-di-tert-butylcarbazole (0.28 g, 1 mmol), and cesium carbonate (1.63 g, 5 mmol) in N,N-dimethylformamide (DMF) was stirred for 30 minutes under nitrogen atmosphere, and then stirred for 12 hours at 105° C. After the mixture was cooled to room temperature, the reaction mixture was extracted using dichloromethane and distilled water. The DCM phase was dried over sodium sulfate and filtered. After the solvent was removed under reduced pressure, purification was carried out with column chromatography on silica gel using hexane/DCM (v/v=5:1) as eluent to give the product as a white powder (Compound 10, 0.65 g, yield 83.1%). ¹H NMR (400 MHz, CDCl₃) δ 8.81 (s, 1H), 8.72 (dd, J=8.1, 1.8 Hz, 1H), 8.63 (d, J=1.7 Hz, 2H), 8.46 (dd, J=8.4, 2.0 Hz, 2H), 8.18 (d. J=1.7 Hz, 2H), 7.76 (d, J=8.4 Hz, 2H), 7.57 (d, J=8.2 Hz, 1H), 7.46 (dd, J=8.6, 1.9 Hz, 2H), 7.03 (d, J=8.6 Hz, 2H), 2.60 (s, 6H), 2.22 (s, 3H), 1.48 (s, 18H). The ¹H NMR spectrum of Compound 10 is illustrated in FIG. 68.

### 6. Preparation of 2-(4-(diphenylamino)phenyl)anthracene-9,10-dione (“TPA-AQ.” Compound 13)

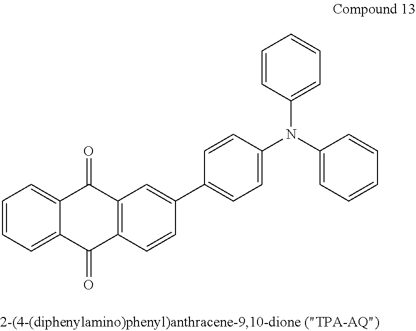 [SMILES: O=C1c2ccccc2C(=O)c2cc(-c3ccc(N(c4ccccc4)c4ccccc4)cc3)ccc21]

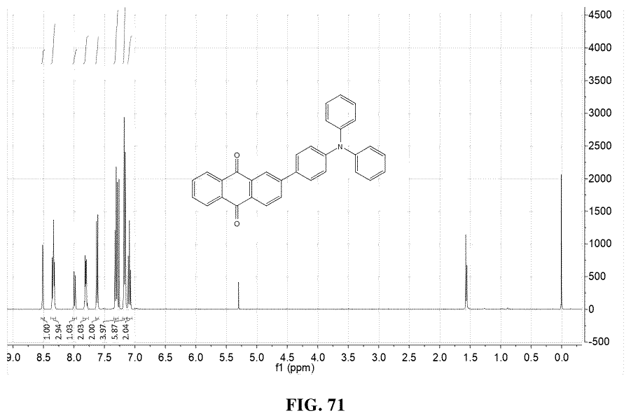

2-bromoanthraquinone (0.33 g, 1.2 mmol), [4-(diphenylamino)phenyl]boronic acid (0.69 g, 2.4 mmol), Pd(PPh₃)₄(50 mg), and K₂CO₃ (2.2 g, 16 mmol) in THF (20 mL) and deionized water (8 mL) were stirred under nitrogen at 65° C. for 12 h. After the mixture was cooled to room temperature, the reaction mixture was extracted using dichloromethane and distilled water. The DCM phase was dried over sodium sulfate and filtered. After the solvent was removed under reduced pressure, purification was carried out with column chromatography on silica gel using hexane/DCM (v/v=4:1) as eluent to give the product as a white powder (Compound 13, 0.48 g, yield 89.3%). ¹H NMR (400 MHz, CDCl₃) δ 8.51 (d, J=1.9 Hz, 1H), 8.38-8.30 (m, 3H), 7.99 (dd, J=8.2, 2.0 Hz, 1H), 7.85-7.76 (m, 2H), 7.65-7.59 (m, 2H), 7.35-7.27 (m, 4H), 7.20-7.14 (m, 6H), 7.12-7.04 (m, 2H). The ¹H NMR spectrum of Compound 13 is illustrated in FIG. 71.

### B. General Procedure B: Synthetic Preparation of Alkyl Chain Monomers

The alkyl chain monomers (Compounds 4-7) were synthesized according to the following Scheme B:

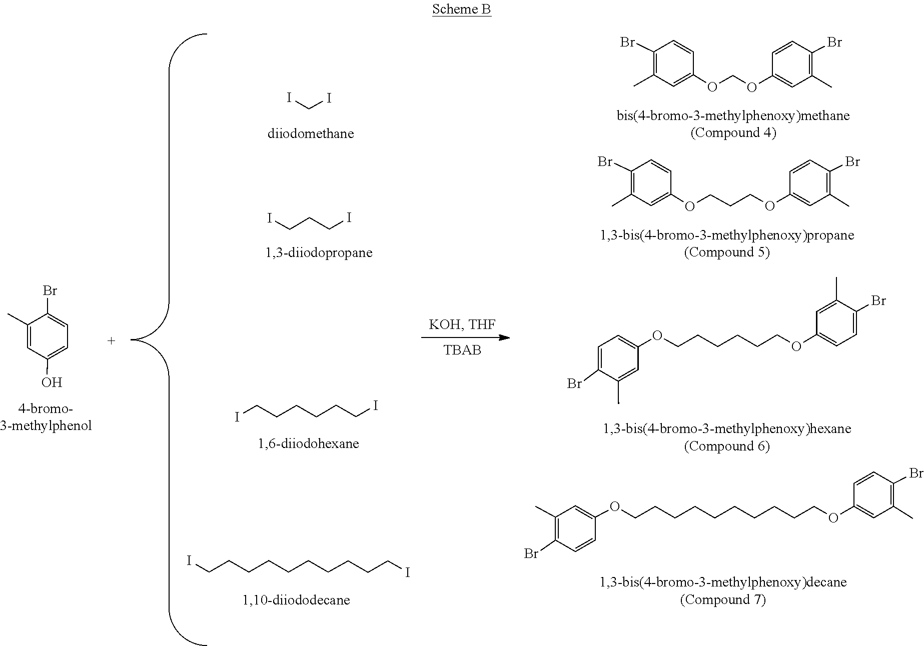

A solution of 4-bromo-3-methylphenol (15 mmol), diiodoalkane (6 mmol), and tetrabutylammonium bromide (TBAB, 4 mg, 0.15 mmol) in 12 mL THF was stirred for 30 minutes under nitrogen at 65° C., and then sodium hydroxide (NaOH, 0.6 g, 15 mmol) in 3 mL THF was added and stirred for 12 hours. After cooling to room temperature, the solution was poured into methanol. The precipitate was collected by filtration and washed with water/methanol. Finally, the precipitate was purified by column chromatography on silica gel using hexane:DCM in a 4:1 v/v ratio as eluent to give a white solid product.

### 1. Preparation of bis(4-bromo-3-methylphenoxy)methane (Compound 4)

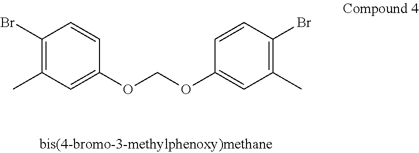 [SMILES: Cc1cc(OCOc2ccc(Br)c(C)c2)ccc1Br]

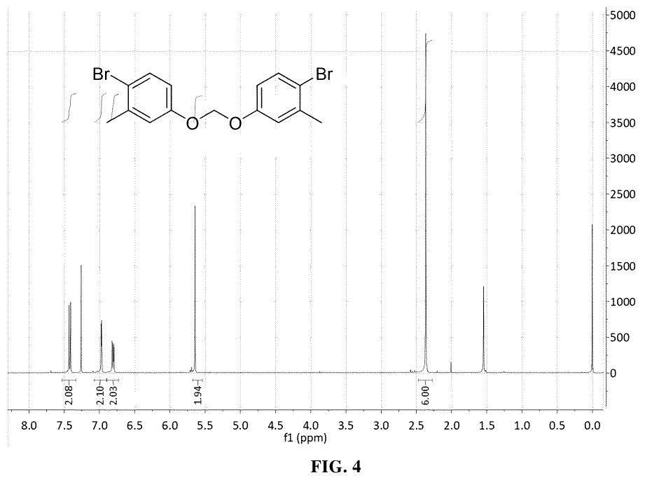

Synthesized by general procedure B to give the product as a white solid (Compound 4, 0.90 g, yield 39.0%). ¹H NMR (400 MHz, CDCl₃) δ 7.42 (d, J=8.7 Hz, 2H), 6.97 (d, J=2.7 Hz, 2H), 6.81 (dd, J=8.7, 2.8 Hz, 2H), 5.64 (s, 2H), 2.37 (s, 6H). The ¹H NMR spectrum of Compound 4 is illustrated in FIG. 4.

### 2. Preparation of 1,3-bis(4-bromo-3-methylphenoxy)propane (Compound 5)

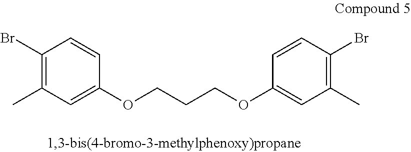 [SMILES: Cc1cc(OCCCOc2ccc(Br)c(C)c2)ccc1Br]

Synthesized by general procedure B to give the product as a white solid (Compound 5, 0.7 g, yield 28.3%). ¹H NMR (400 MHz, CDCl₃) δ 7.38 (d, J=8.7 Hz, 2H), 6.79 (d, J=3.0 Hz, 2H), 6.61 (dd, J=8.7, 3.0 Hz, 2H), 4.10 (t, J=6.1 Hz, 4H), 2.35 (s, 6H), 2.29-2.14 (m, 2H). The ¹H NMR spectrum of Compound 5 is illustrated in FIG. 5.

### 3. Preparation of 1,6-bis(4-bromo-3-methylphenoxy)hexane (Compound 6)

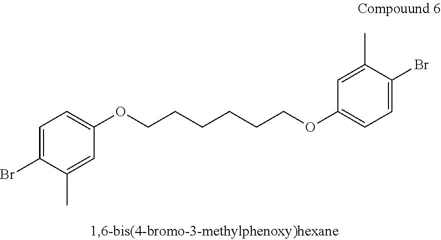 [SMILES: Cc1cc(OCCCCCCOc2ccc(Br)c(C)c2)ccc1Br]

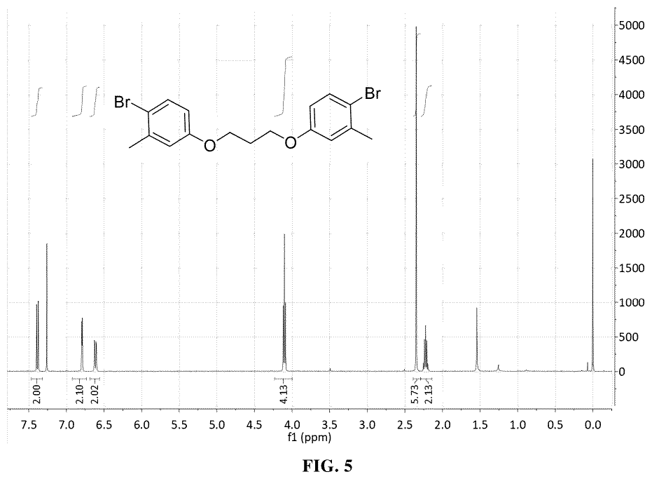

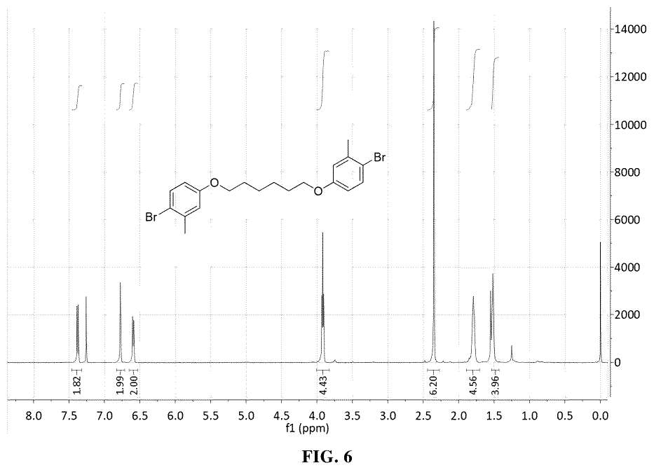

Synthesized by general procedure B to give the product as a white solid (Compound 6, 1.9 g, yield 69.8%). ¹H NMR (400 MHz, CDCl₃) δ 7.38 (dd, J=8.7, 1.9 Hz, 2H), 6.78 (s, 2H), 6.60 (dd, J=8.7, 2.3 Hz, 2H), 3.92 (td, J=6.4, 1.9 Hz, 4H), 2.35 (d, J=1.5 Hz, 6H), 1.82 (dd, J=32.3, 3.9 Hz, 4H), 1.52 (d, J=1.9 Hz, 4H). The ¹H NMR spectrum of Compound 6 is illustrated in FIG. 6.

### 4. Preparation of 1,10-bis(4-bromo-3-methylphenoxy)decane (Compound 7)

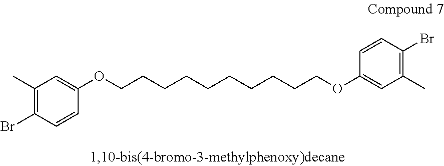 [SMILES: Cc1cc(OCCCCCCCCCCOc2ccc(Br)c(C)c2)ccc1Br]

Synthesized by general procedure B to give the product as a white solid (Compound 7, 1.0 g, yield 32.7%). ¹H NMR (400 MHz, CDCl₃) δ 7.38 (d, J=8.7 Hz, 2H), 6.78 (d, J=2.9 Hz, 2H), 6.60 (dd, J=8.7, 3.0 Hz, 2H), 3.90 (t, J=6.5 Hz, 4H), 2.35 (s, 6H), 1.84-1.67 (m, 4H), 1.43 (dd, J=14.4, 6.9 Hz, 4H), 1.3 (s, 8H). The ¹H NMR spectrum of Compound 7 is illustrated in FIG. 7.

### 5. Preparation alkyl chain monomer 1,1-bis(4-(4,4,5,5-tetramethyl-1,3,2-dioxaborolan-2-yl)phenoxy)decane (Compound 11)

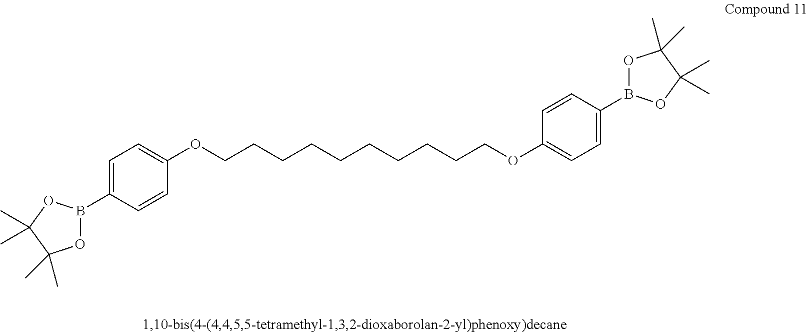

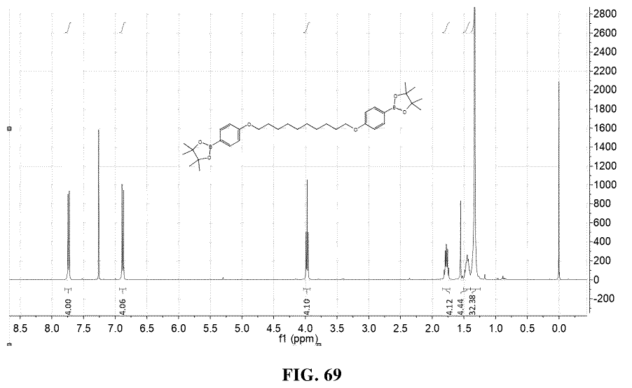

A solution of 1,10-dibromodecane (0.9 g, 3 mmol), 4-(4,4,5,5-tetramethyl-1,3,2-dioxaborolan-2-yl)phenol (2.64 g, 12 mmol), and potassium carbonate (K₂CO₃, 1.65 g, 12 mmol) in 40 mL of acetone were stirred under nitrogen at 60° C. for 40 h. After the mixture was cooled to room temperature, the reaction mixture was extracted using DCM and distilled water. The DCM phase was dried over sodium sulfate and then filtered. After the solvent was removed under reduced pressure, purification was carried out with column chromatography on silica gel using hexane/ethyl acetate (v/v=10:1) as eluent to give Compound 11 as a white powder (1.15 g, yield 66.3%). ¹H NMR (400 MHz, CDCl₃) δ 7.79-7.69 (m, 4H), 6.93-6.83 (m, 4H), 3.97 (t, J=6.6 Hz, 4H), 1.84-1.72 (m, 4H), 1.51-1.40 (m, 4H), 1.33 (s, 32H). The ¹H NMR spectrum of Compound 11 is illustrated in FIG. 69.

### C. Synthetic Preparation of (4-(2,7-bis(4-methoxy-2-methylphenyl)-9H-carbazol-9-yl)phenyl)(4-(9,9-dimethylacridin-10(9H)-yl)phenyl)methanone (“DKC”) (Compound 8)

DKC (Compound 8) was synthesized according to the following Scheme C:

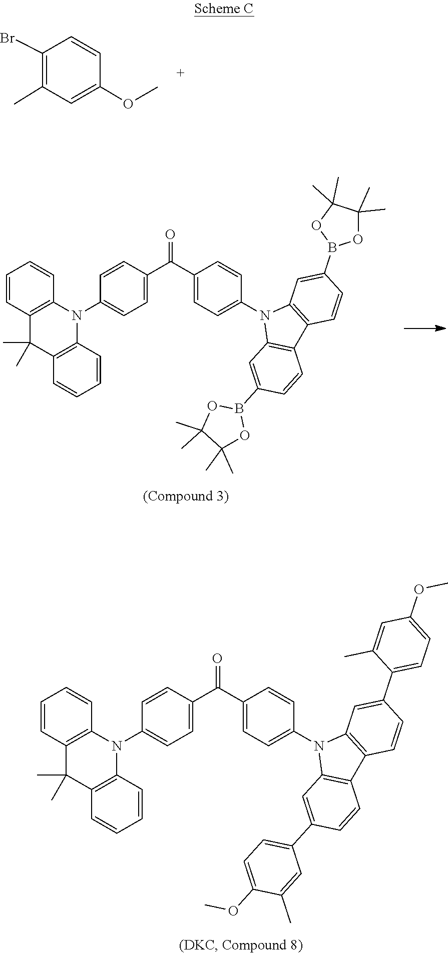

### 1. (4-(2,7-bis(4-methoxy-2-methylphenyl)-9H-carbazol-9-yl)phenyl)(4-(9,9-dimethylacridin-10(9H)-yl)phenyl)methanone (DKC, Compound 8)

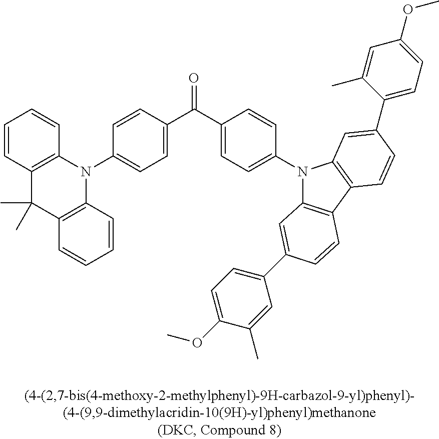

4-Bromo-3-methylanisole (0.3 g, 1.5 mmol), Compound 3 (0.48 g, 0.6 mmol), tris(dibenzylideneacetone)dipalladium (1.5 mg), and 2-dicyclohexylphosphino-2′,6′-dimethoxybiphenyl (“Sphos”) (7 mg) were charged into a flask that was then vacuumed and aerated with argon five times. Degassed toluene (20 mL) was added, and the mixture was heated to 80° C. under vigorous stirring. A potassium carbonate solution (8 mL, 2 mol/L in H₂O) with four drops of Aliquat 336 was added, and the temperature was raised to 95° C. After the mixture was cooled to room temperature, the reaction mixture was extracted using dichloromethane and distilled water. The dichloromethane phase was dried over Na₂SO₄ and then was filtered. After the solvent was removed under reduced pressure, the residue was purified by column chromatography on silica gel using hexane/DCM in a 2:1 v/v ratio as eluent to give the product (Compound 8, 0.41 g, yield 87%). ¹H NMR (400 MHz, CDCl₃) δ 8.26-8.01 (m, 6H), 7.81 (d, J=8.5 Hz, 2H), 7.61-7.39 (m, 6H), 7.35-7.19 (m, 4H), 6.99 (ddd, J=10.3, 7.5, 1.5 Hz, 4H), 6.89-6.76 (m, 4H), 6.36 (dd, J=7.9, 1.4 Hz, 2H), 3.83 (s, 6H), 2.31 9s, 6H), 1.7 (s, 6H). The ¹H NMR spectrum of Compound 8 is illustrated in FIG. 8.

### C1. Synthetic Preparation of 9-(4-(4,6-bis(4′-methoxy-2-methyl-[1.1′-biphenyl]-4-yl)-1,3,5-triazin-2-yl)-2-methylphenyl)-3,6-di-tert-butyl-9H-carbazole (“Trz-tBuCz”) (Compound 12)

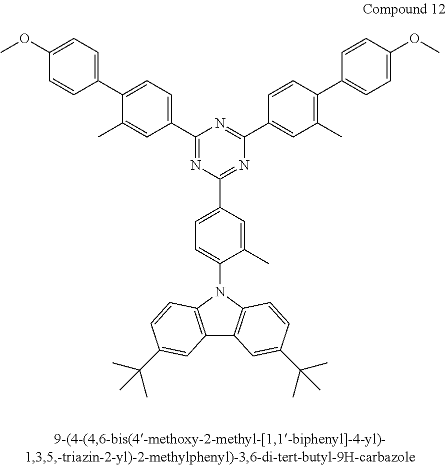

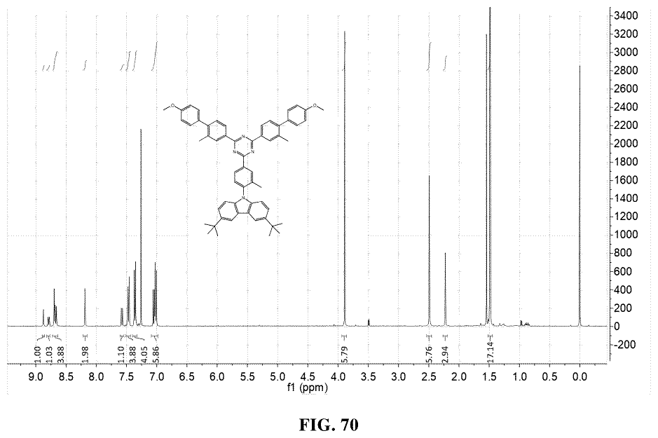

Compound 10 (0.78 g, 1 mmol), 4-methoxyphenylboronic acid pinacol ester (0.84 g, 3.6 mmol), Pd(PPh₃)₄(100 mg), and K₂CO₃ (2.2 g, 16 mmol) in tetrahydrofuran (“THF,” 20 mL) and deionized water (8 mL) were stirred under nitrogen at 65° C. for 12 h. After the mixture was cooled to room temperature, the reaction mixture was extracted using DCM and distilled water. The DCM phase was dried over sodium sulfate and then filtered. After the solvent was removed under reduced pressure, purification was carried out with column chromatography on silica gel using hexane/DCM (v/v=1:1) as eluent, to give the product as a white powder (Compound 12, 0.65 g, yield 89.2%). ¹H (400 MHz, CDCl₃) δ 8.87 (d, J=1.3 Hz, 1H), 8.79 (dd, J=8.2, 1.7 Hz, 1H), 8.67 (dd, J=11.6, 3.6 Hz, 4H), 8.19 (d, J=1.6 Hz, 2H), 7.57 (d, J=8.2 Hz, 1H), 7.47 (dd, J=8.2, 2.6 Hz, 4H), 7.40-7.33 (m, 4H), 7.09-6.98 (m, 6H), 3.89 (s, 6H), 2.49 (s, 6H), 2.23 (s, 3H), 1.48 (s, 18H). The ¹H spectrum of Compound 12 is illustrated in FIG. 70.

### D. Preparation of Stretchable Light-Emitting Polymer by Suzuki Poly-Condensation

Stretchable light-emitting polymers were synthesized according to the following Scheme D:

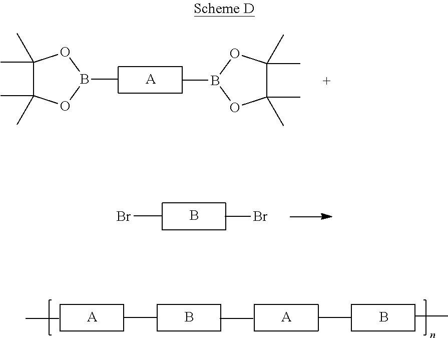

Compound 3 (0.6 mmol), alkyl chain monomer (0.6 mmol), tris(dibenzylideneacetone)dipalladium (1.5 mg), and 2-dicyclohexylphosphino-2′,6′-dimethoxybiphenyl (Sphos) (7 mg) was charged into a flask, which was then vacuumed and aerated with argon five times. Degassed toluene (20 mL) was added, and the mixture was heated to 80° C. under vigorous stirring. A degassed potassium carbonate solution (8 mL, 2 mol/L in H₂O) with four drops of Aliquat 336 was added, and the temperature was increased to 95° C. After 5 days of reaction, 4-bromo-3-methylanisole (50 mg in 3 mL toluene) was added. After 8 hours, phenylboronic acid (100 mg in 3 mL toluene) was added. After another 8 hours, the mixture was cooled down to 80° C., then sodium diethyldithiocarbamate trihydrate (10 mL, 1 g/mL in H₂O) was added. After 24 hours, the system was cooled down to room temperature. The mixture was poured into 100 mL DCM and washed with 100 mL saturated sodium chloride solution five times. The separated organic layer was dried over sodium sulfate, concentrated by rotary evaporation to 8 mL solution. The mixture was precipitated into 200 mL methanol and filtered by vacuum to obtain the crude fiber product. The product was further purified by bathing in boiling methanol, acetone, and chlorobenzene by Soxhlet's extractor. Then the chlorobenzene solution product was concentrated by rotary evaporation to 6 ml, precipitated into 200 mL methanol, filtered by vacuum to obtain pure yellow fiber (stretchable light-emitting polymer).

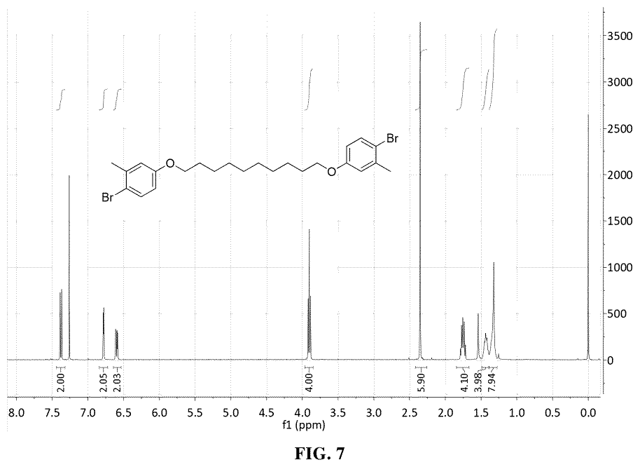

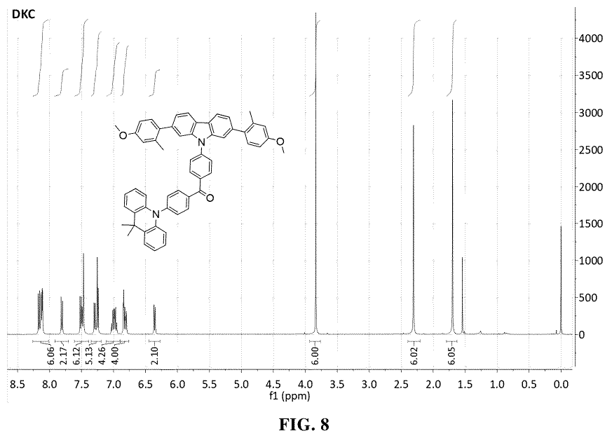

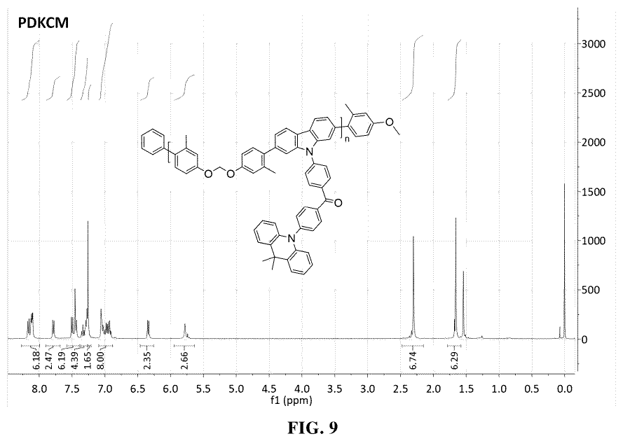

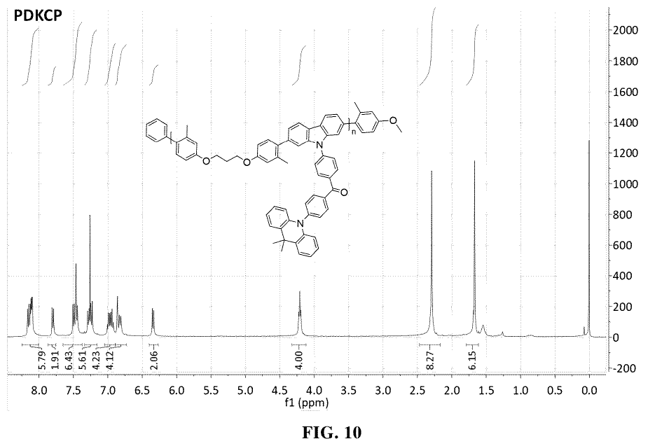

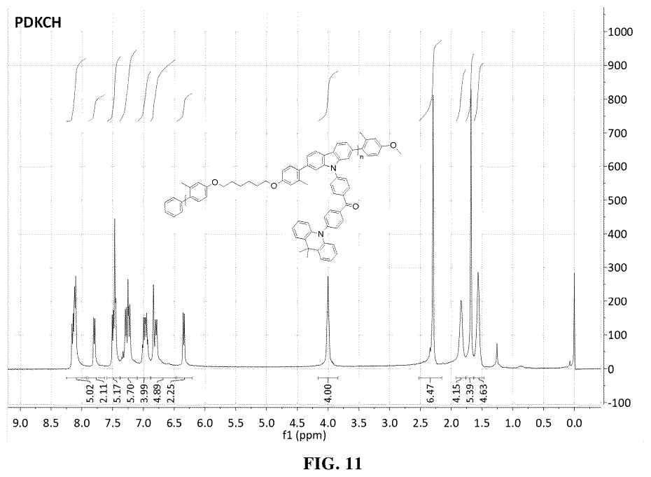

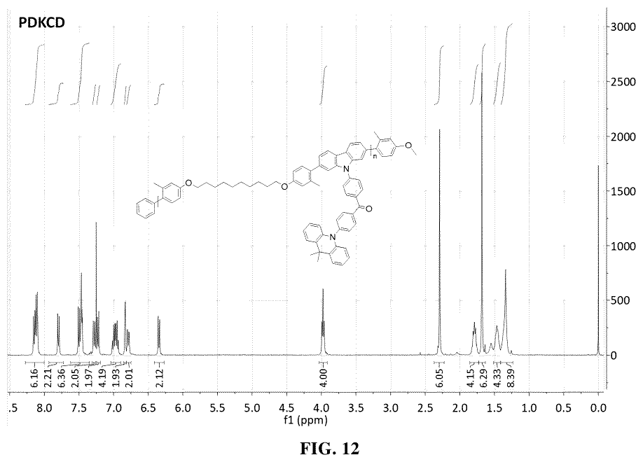

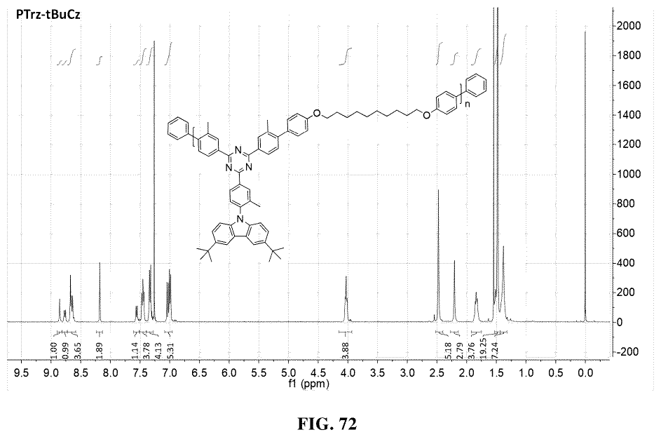

By the above process, the five example stretchable light-emitting polymers illustrated below in Scheme E were synthesized. The first four example polymers include the same TADF units, but differ in the length of the alkylene chain. The alkylene chain lengths include 1 carbon, 3 carbons, 6 carbons, and 10 carbons for each of PDKCM, PDKCP, PDKCH, and PDKCD, respectively. The ¹H spectra for each of PDKCM, PDKCP, PDKCH, and PDKCD are illustrated in FIGS. 9-12, respectively. The fifth example stretchable light-emitting polymer, PTrz-tBuCz, is prepared from Compounds 11 and 12, and a ¹H spectrum for PTrz-tBuCz is illustrated in FIG. 72.

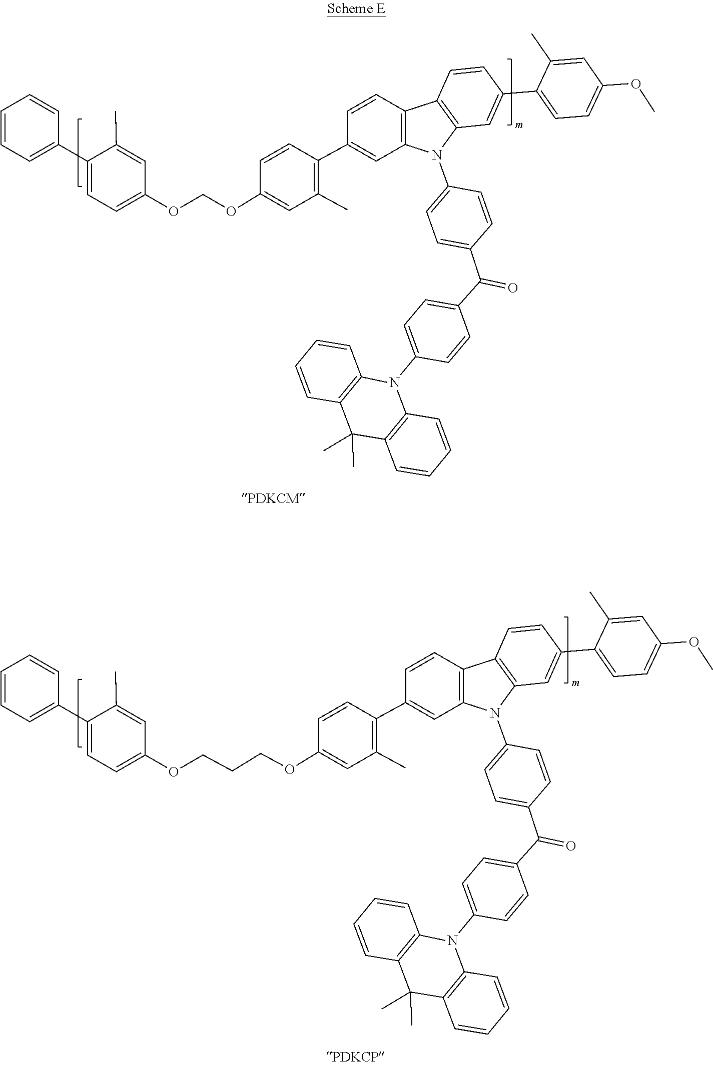

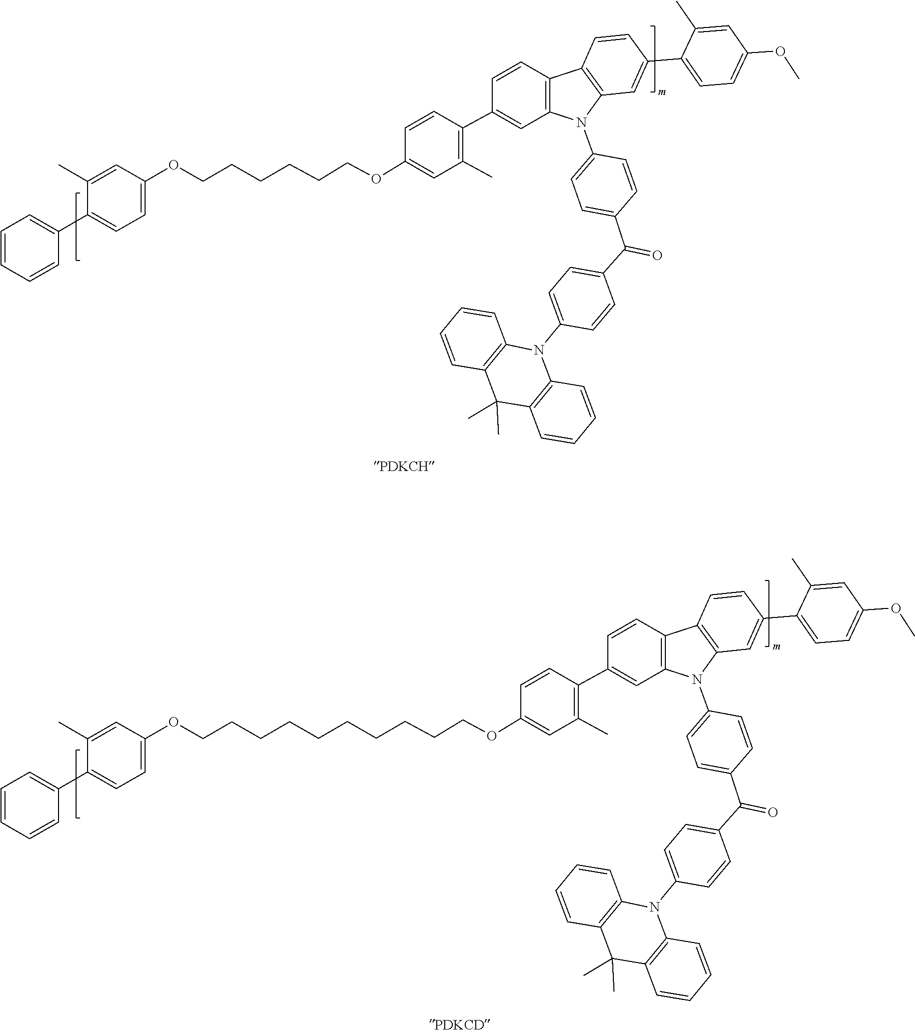

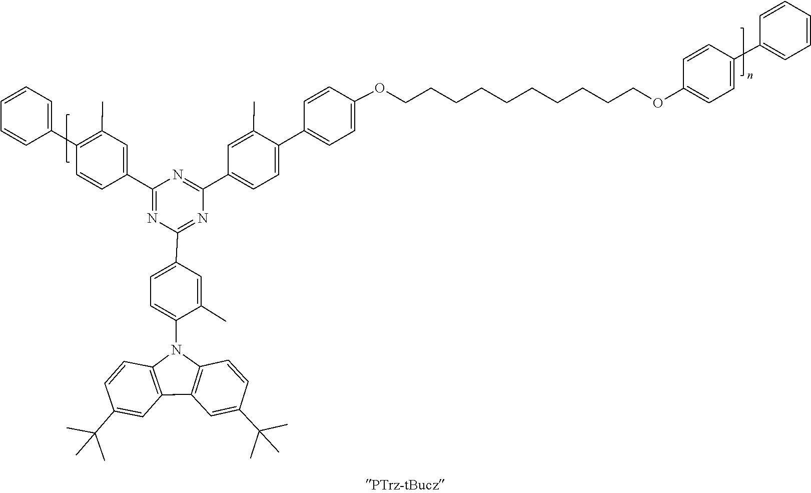

The number average molecular weights (Mₙ) and weight average molecular weights (M_{w}) in kilodaltons (kDa), and polydispersity indices (PDI), of PDKCM, PDKCP, PDKCH, PDKCM, and PTrz-tBuCz are provided below in Table 1.

TABLE 1
Molecular weights of stretchable light-emitting polymers.

| Stretchable light-emitting polymer | Mₙ (kDa) | M_{w} (kDa) | PDI |
|---|---|---|---|
| PDKCM | 33.4 | 70.8 | 2.12 |
| PDKCP | 39.3 | 67.6 | 1.72 |
| PDKCH | 30.9 | 51.3 | .166 |
| PDKCD | 29.0 | 55.4 | 1.91 |
| PTrz-tBu-Cz | 33.9 | 70.9 | 2.09 |

### E. Analysis of EL Efficiency

Without wishing to be bound by theory, it is believed that in the four example polymers, the acridine-benzophenone moiety, which is characterized by a close-to-perpendicular dihedral angle, serves as the electron donor-acceptor (“D-A”) pair and provides high EL efficiency.

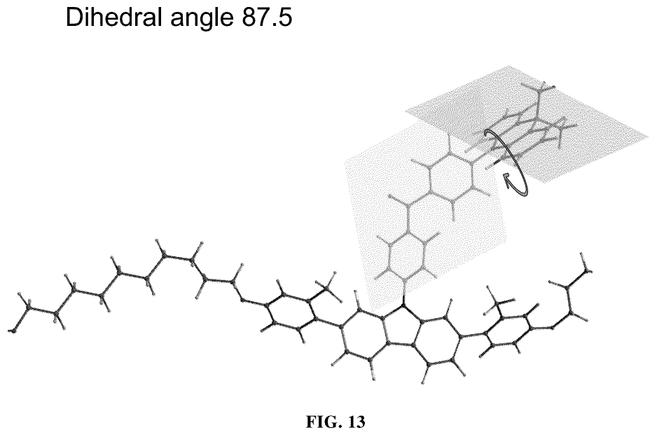

Taking example polymer PDKCD as a particular example, as illustrated in FIG. 13, the optimized conformational structure of PDKCD, as estimated by density functional theory (“DFT”), demonstrates that the dihedral angle of the D-A pair is close to 90 degrees. Based on the approximately perpendicular dihedral angle of the D-A pair of PDKCD, it is expected that PDKCD will have a small energy-level splitting between singlet (S₁) and triplet (T₁) excited states, and provide high EL efficiency.

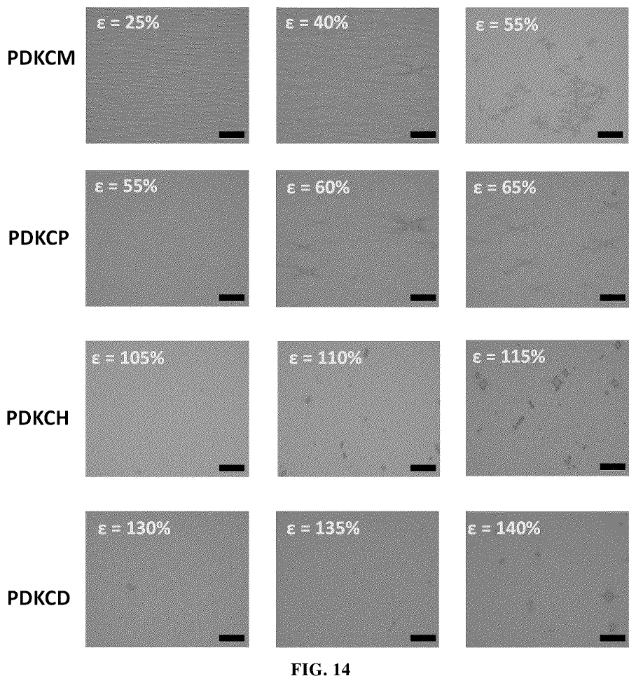

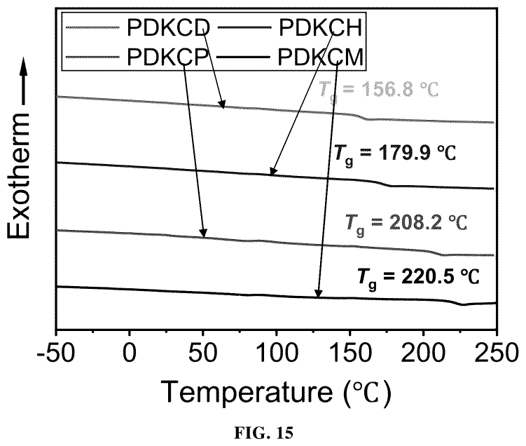

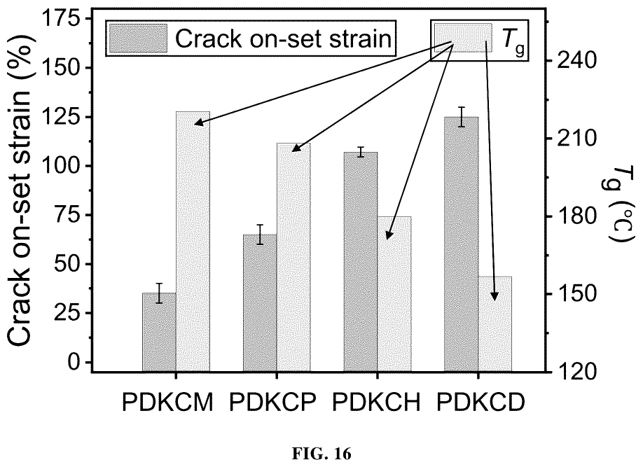

FIG. 14 illustrates optical microscope images of films of each of the four example stretchable light-emitting polymers shown in Scheme E, horizontally stretched, at approximately the on-set strains for crack formation. FIG. 15 illustrates the glass-transition temperatures of each of the four example stretchable light-emitting polymers shown in Scheme E, obtained from DSC thermal analysis of the four stretchable light-emitting polymers. FIG. 16 illustrates the trends in crack on-set strains and glass-transition temperatures of the four stretchable light-emitting polymers. The crack on-set strains and glass-transition temperatures illustrated in FIGS. 14 and 15, respectively, and the trends illustrated in FIG. 16, confirm that a longer alkylene chain of 10 carbons may more effectively enhance chain dynamics and may increase stretchability of the stretchable light-emitting polymer to greater than 125% strain.

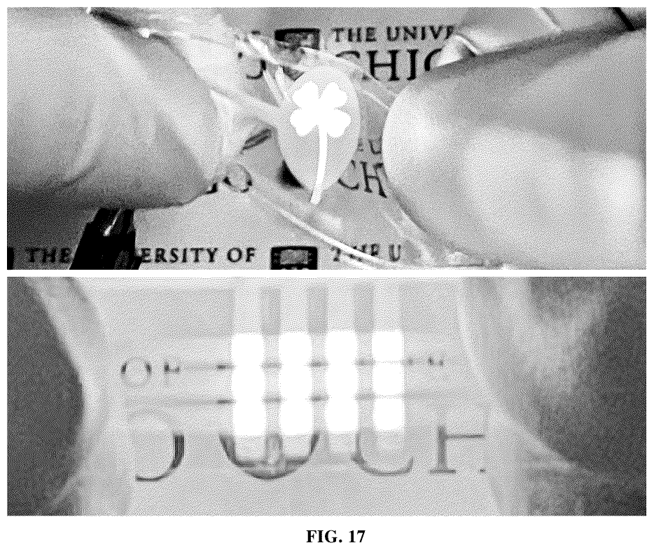

As illustrated in FIG. 17, the example stretchable light-emitting polymers, PDKCM, PDKCP, PDKCH, and/or PDKCD, may serve as an emitting layer, thereby combining high EL efficiency and brightness and high stretchability in novel, fully stretchable EL devices.

### F. Analysis of Effect of Alkylene Chain Length on Photophysical Properties of Exemplary Stretchable Light-Emitting Polymers

The influence of the alkylene chain length was analyzed by combining comprehensive experimental characterizations and theoretical simulations with DFT and molecular dynamics (“MID”). For comparison, small-molecule emitter DKC (Compound 8) was also synthesized.

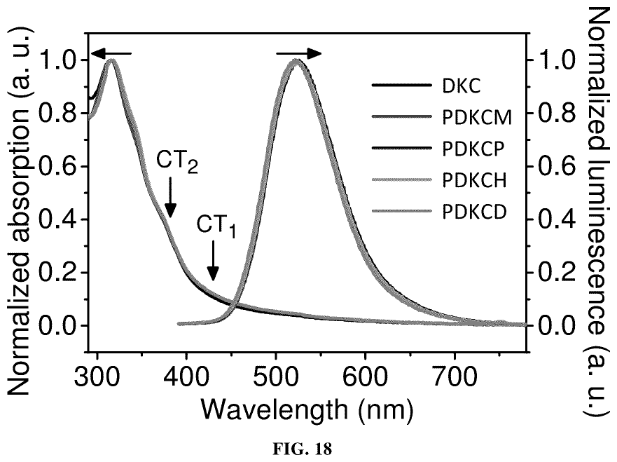

As illustrated in FIG. 18, each of PDKCM, PDKCP, PDKCH, PDKCD, and DKC exhibits two charge transfer (“CT”) absorptions: CT₂ at a wavelength of 350-400 nanometers, and CT₁ at a wavelength of 400-450 nanometers. Without being bound by theory, it is believed that CT₂ absorption corresponds to a carbazole-to-benzophenone charge transfer, and CT₁ absorption corresponds to an acridine-to-benzophenone transfer. Because one emission peak corresponding to CT₁ is exhibited by each of PDKCM, PDKCP, PDKCH, PDKCD, and DKC as illustrated by FIG. 18, minimal difference is observed in the PL emission spectra among PDKCM, PDKCP, PDKCH, PDKCD, and DKC.

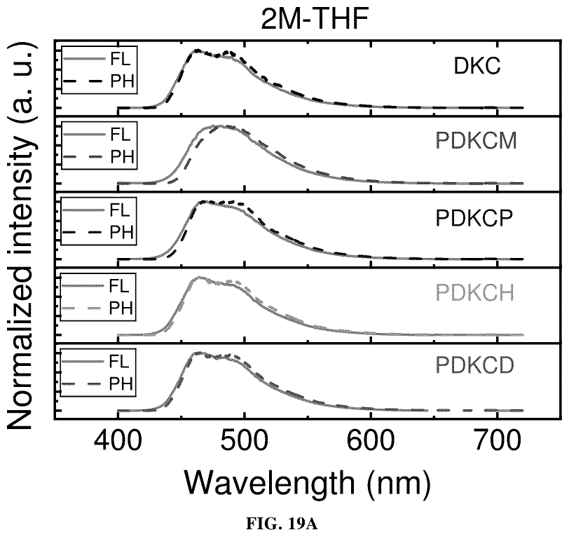

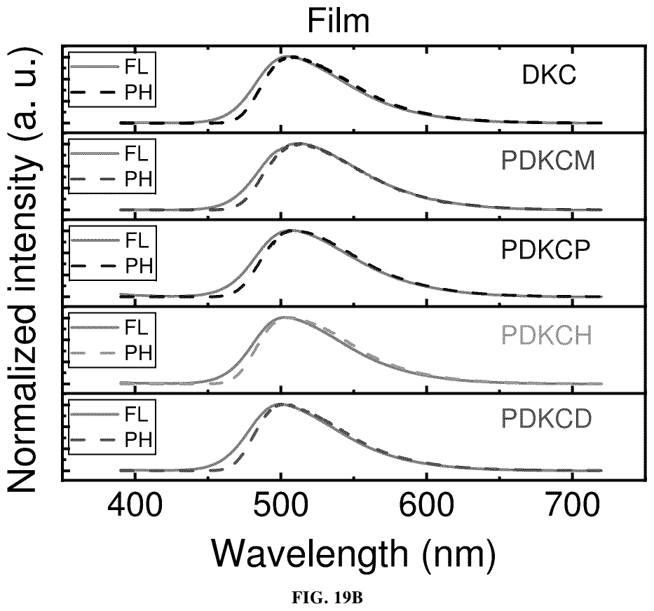

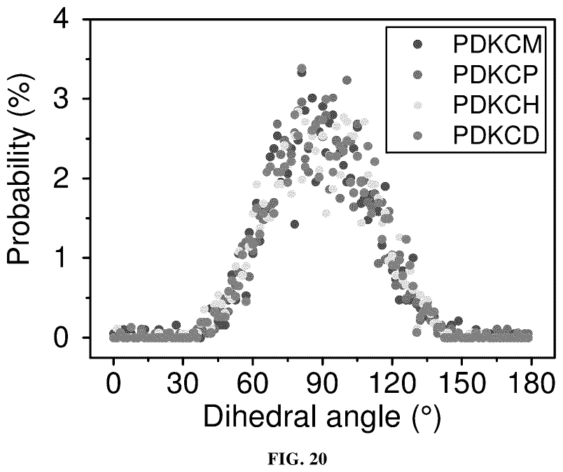

Low-temperature FL/PH spectroscopy was performed to study the energy-level splitting (ΔE_{ST}) of each of PDKCM, PDKCP, PDKCH, PDKCD, and DKC. FL/PH spectra of solutions of each of PDKCM, PDKCP, PDKCH, PDKCD, and DKC in 2-methyltetrahydrofuran (“2-Me-THF,” 10⁻⁵ M) at low temperature (77 K) are illustrated in FIG. 19A. FL/PH spectra of films of each of PDKCM, PDKCP, PDKCH, PDKCD, and DKC at low temperature are illustrated in FIG. 19B. In solution in 2-Me-THF, the ΔE_{ST}, which corresponds to the CT₂ emission, demonstrated a trend of gradually decreasing with increase of alkylene chain length for polymers PDKCM, PDKCP, PDKCH, and PDKCD. Without being bound by theory, it is believed that the gradual slight decrease in ΔE_{ST} with increasing alkylene chain length demonstrated in FIG. 19A as observed in 2-Me-THF solution may be due to the disappearance of conjugation coupling between adjacent carbazole moieties. By contrast, for each of PDKCM, PDKCP, PDKCH, PDKCD, and DKC in the film state, with complete energy transfer from CT₂ to CT₁ as illustrated in FIG. 19B, the ΔE_{ST} values are nearly identical, and the values are such as to provide efficient thermally activated delayed fluorescence. The D-A pair dihedral angle distributions for the four polymers PDKCM, PDKCP, PDKCH, and PDKCD in MD simulation, as illustrated in FIG. 20, further support the conclusions drawn from the ΔE_{ST} values.

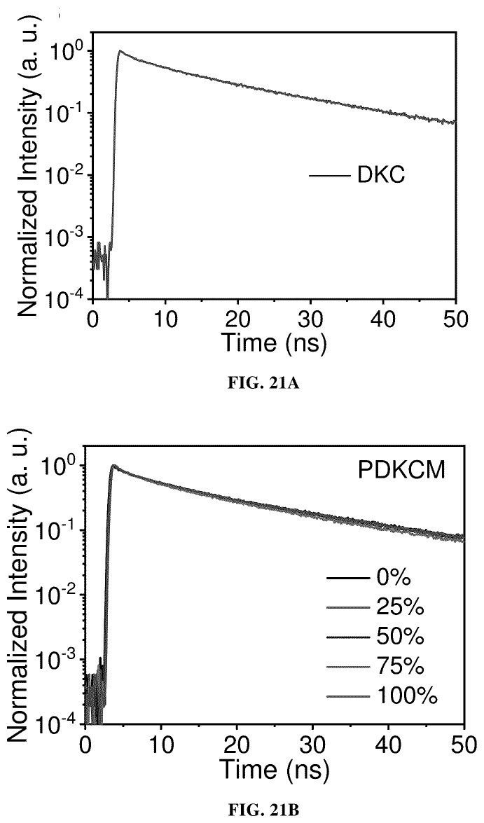

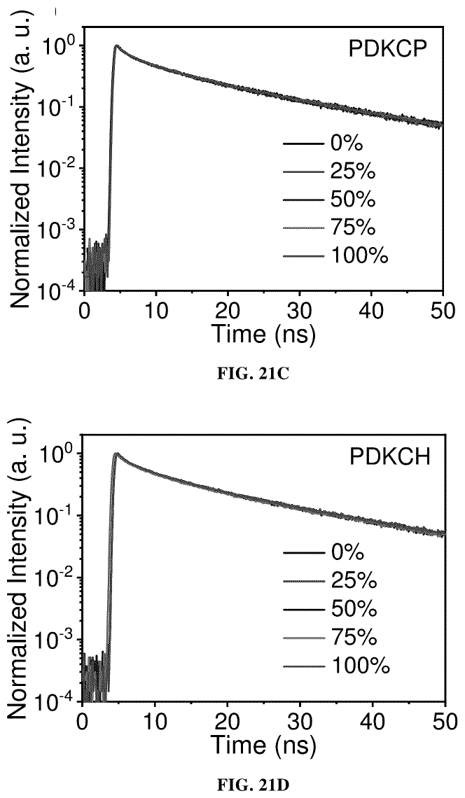

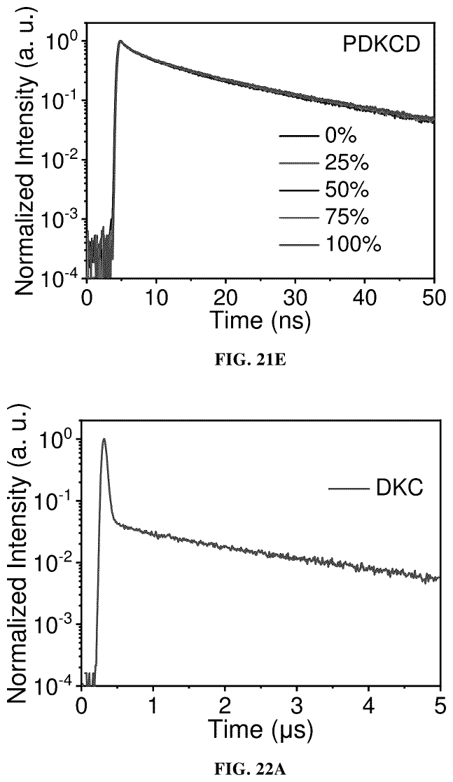

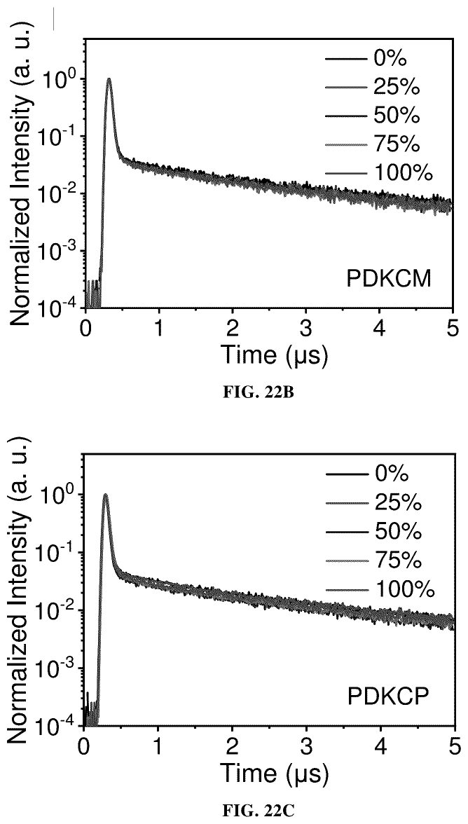

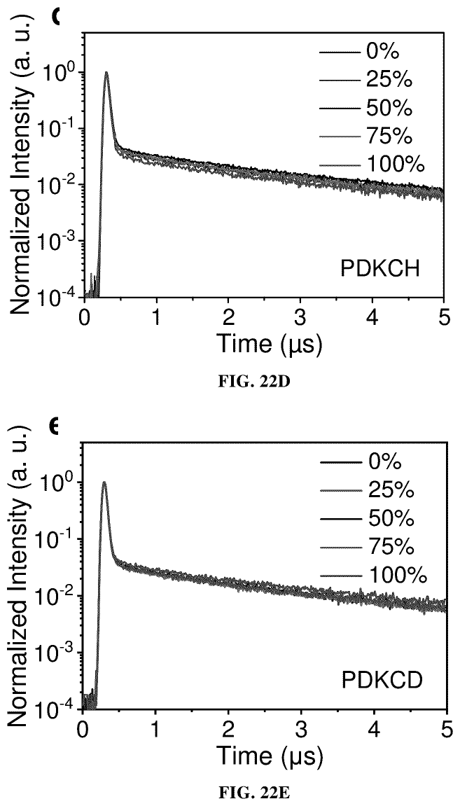

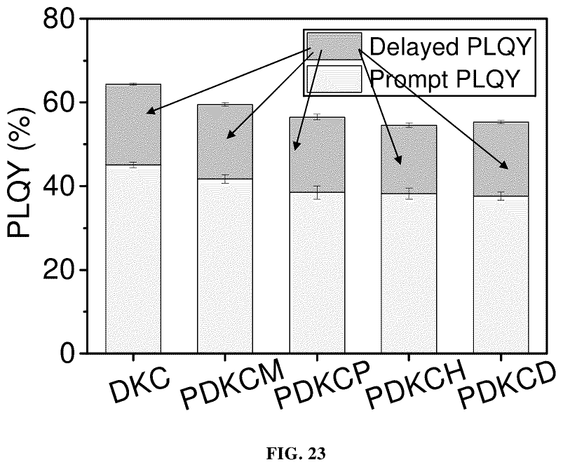

The PL quantum yield (“PLQY”) and transient PL decay were tested to further quantify the TADF of the four polymers PDKCM, PDKCP, PDKCH, and PDKCD. From the transient PL decay measurements, the four polymers PDKCM, PDKCP, PDKCH, and PDKCD, and DKC all demonstrate both prompt decay of approximately 10 nanoseconds, as illustrated in FIGS. 21A-21E, and delayed decay of approximately 3 microseconds, as illustrated in FIGS. 22A-22E. The prompt decay of approximately 10 nanoseconds and delayed decay of approximately 3 microseconds provide direct evidence for thermally activated delayed fluorescence. The PL quantum yields for the four polymers PDKCM, PDKCP, PDKCH, and PDKCD are similar to the PL quantum yield for DKC, as illustrated in FIG. 23.

The kinetic rate parameters for PDKCM, PDKCP, PDKCH, PDKCD, and DKC were estimated, and the parameters are summarized in Table 2 below. As the data in Table 2 demonstrates, the parameters for the polymers and DKC are highly similar, indicating that the alkylene chain length of the four polymers does not detract from the rates of the individual steps in the TADF process. In Table 2, τₚ and τ_{d} correspond, respectively, to the prompt and delayed decay times estimated from the transient PL decay data; kₚ and k_{d} correspond, respectively, to the prompt and delayed fluorescence decay rate constants; Φ_{F} and Φ_{TADF} correspond, respectively, to the prompt and delayed fluorescence quantum efficiencies; kᵣ^{S} corresponds to the radiative decay rate constant at singlet S₁ state; k_{ISC} and k_{RISC} correspond, respectively, to the rate constants for the intersystem crossing (“ISC”) process from singlet S₁ to triplet T₁ states, and the reverse ISC (“RISC”) process from triplet T₁ to singlet S₁ states; and kₙᵣ^{T} corresponds to the non-radiative decay rate constant at triplet state.

TABLE 2
Kinetic rate parameters of DKC and exemplary
stretchable light-emitting polymers

| | | | | | kₚ | k_{d} | kᵣ^{S} | k_{ISC} | k_{RISC} | kₙᵣ^{T} |
|---|---|---|---|---|---|---|---|---|---|---|
| | τₚ^{a} | τ_{d}^{b} | Φ_{F} | Φ_{TADF} | (10⁷ | (10⁵ | (10⁷ | (10⁷ | (10⁵ | (10⁵ |
| Emitters | (ns) | (μs) | (%) | (%) | s⁻¹) | s⁻¹) | s⁻¹) | s⁻¹) | s⁻¹) | s⁻¹) |
| DKC | 12 | 2.5 | 45.1 | 19.3 | 8.6 | 4.1 | 3.9 | 4.7 | 3.9 | 2.3 |
| PDKCM | 12 | 2.8 | 41.7 | 17.9 | 8.4 | 3.6 | 3.5 | 4.9 | 3.7 | 2.1 |
| PDKCP | 9.3 | 2.5 | 38.5 | 18.1 | 10.8 | 4.0 | 4.1 | 6.6 | 4.9 | 2.1 |
| PDKCH | 8.9 | 3.1 | 38.2 | 16.4 | 11.2 | 3.2 | 4.3 | 6.9 | 3.6 | 1.8 |
| PDKCD | 8.9 | 2.7 | 37.6 | 17.7 | 11.3 | 3.7 | 4.2 | 7.0 | 4.6 | 1.9 |

^{a}Calculated using single-exponential decay fitting for the prompt component in the range of 50 ns;
^{b}Calculated using double-exponential decay fitting for the delayed component in the range of 5 μs.

### G. Analysis of EL Properties of Exemplary Stretchable Light-Emitting Polymers as Host-Free Emitting Layers in Conventional OLED Structure

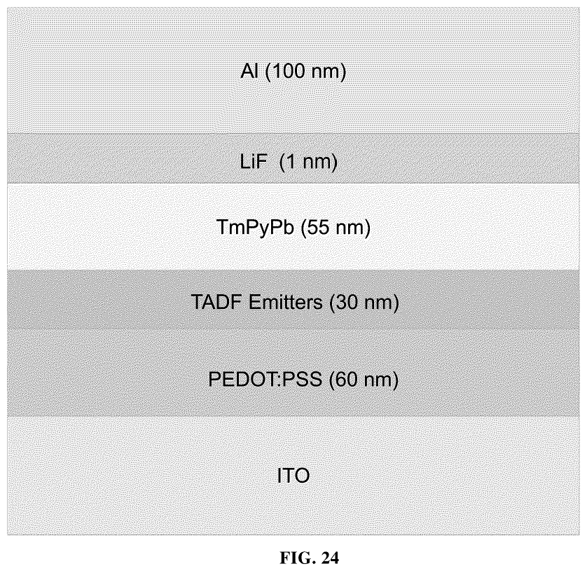

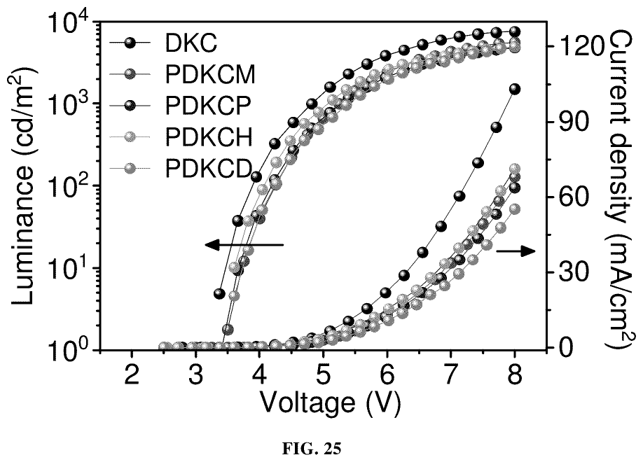

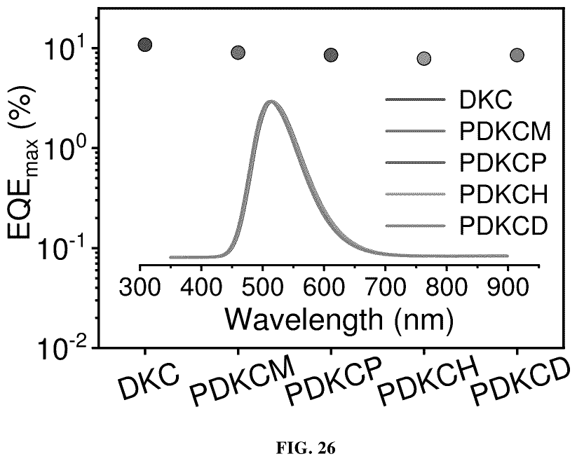

The EL properties of PDKCM, PDKCP, PDKCH, PDKCD, and DKC were separately included as the emitting layer in an OLED structure, a schematic of an example of which is illustrated in FIG. 24. As illustrated in FIG. 25, the four exemplary stretchable light-emitting polymers PDKCM, PDKCP, PDKCH, and PDKCD demonstrate very similar current density-voltage and luminance-voltage traces. Compared with an example of an OLED including DKC, the maximum luminance of examples of OLEDs including one of the four exemplary stretchable light-emitting polymers is slightly decreased. Without being bound by theory, it is believed that the slight decrease in maximum luminance of examples of OLEDS including an exemplary stretchable light-emitting polymer may be a result of the different packing structures of TADF units in polymer chains relative to the packing structure of small-molecule DKC. As illustrated in FIG. 26, the luminescence spectra of OLEDs including an exemplary stretchable light-emitting polymer and an OLED including DKC are also highly similar.

Similar EL performance between an OLED including DKC and OLEDs including an exemplary stretchable light-emitting polymer is also demonstrated by external quantum efficiency (EQE), which is illustrated by FIG. 26. As illustrated in FIG. 26, exemplary stretchable light-emitting polymers PDKCM, PDKCP, PDKCH, and PDKCD achieve a maximum EQE of approximately 10%. The maximum EQE values of OLEDs including an exemplary stretchable light-emitting polymer is similar to maximum EQE values for OLEDs including one of the reported non-stretchable TADF polymers as a host-free emitter, as demonstrated by Table 3.

TABLE 3
Molecular Weights and Maximum EQE Values of
Reported TADF Polymers and Exemplary Stretchable
Light-Emitting Polymers in OLEDs

| | | Mₙ | EQEₘₐₓ (%) at different strains | | |
|---|---|---|---|---|---|
| TADF polymer | | (kDa)/PDI | 0% | 50% | 100% |
| D-A | PDKCD | 29.0/1.91 | 9.6 ± 1.1 | 8.5 ± 0.9 | 8.0 ± 0.3 |
| TADF | LEP | —/—* | 10.0 | | |
| | poly(AcBPCz- | 13.8/2.8 | 7.2 | | |
| | TMP)^{b} | | | | |
| | poly(AcBPCz- | 13.8/2.8 | 15.3 | | |
| | TMP)^{c} | | | | |
| | poly(TMTPA- | 5.1/1.8 | 15.3 | | |
| | DCB)^{c} | | | | |
| Host- | P12 | 3.3/1.77 | 4.3 | | |
| TADF | PABPC5 | 7.8/2.66 | 18.1 | | |
| | PCzATD5 | 6.6/2.0 | 15.5 | | |
| | PAPTC, | 19.5/2.9 | 11.5 | | |
| | x = 50 | | | | |
| | PCzAPT10, | 7.9/2.27 | 16.9 | | |
| | x = 10 | | | | |
| | PBD-10 | 72/4.5 | 7.3 | | |
| | PAPCC | 16.2/2.38 | 1.34 | | |
| TSCT | P-Ac95-TRZ05 | 46.5/2.42 | 12.1 | | |
| TADF | PNB-TAc- | 31.7/1.31 | 18.8 | | |
| | TRZ-5 | | | | |

^{a}Data unavailable, but molecular weight is likely relatively low because the polymer was purified with a regular silica gel column.
^{b}Hole transporting layer is PEDOT:PSS.
^{c}Hole transporting layer is PEDOT:PSS_PFI composite.
TSCT = Through-space charge transfer.

As used in Table 3, the term “LEP” refers to the TADF polymer represented by the following chemical structure:

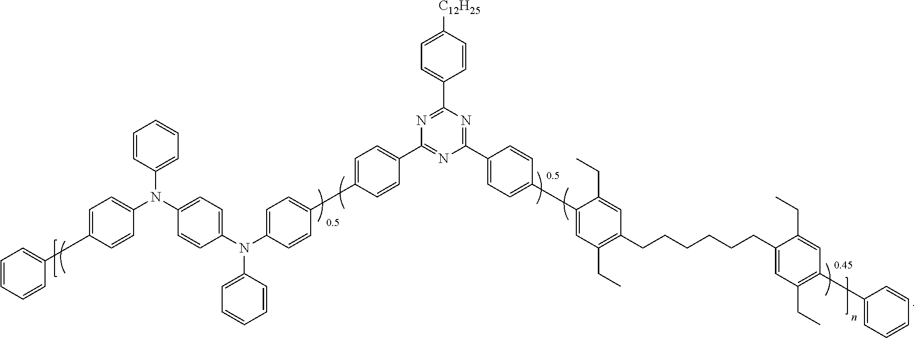

As used in Table 3, the term “poly(AcBPCz-TMP)” refers to the TADF polymer represented by the following chemical structure:

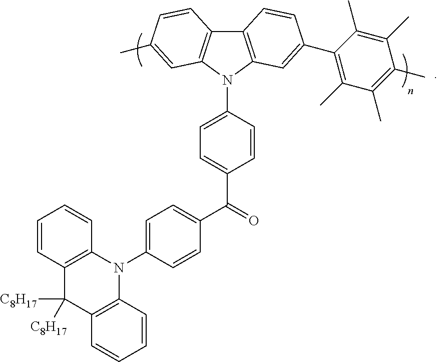

As used in Table 3, the term “poly(TMTPA-DCB)” refers to the TADF polymer represented by the following chemical structure:

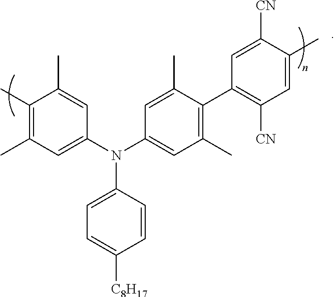

As used in Table 3, the term “P12,” where x=0.12, refers to the TADF polymer represented by the following chemical structure:

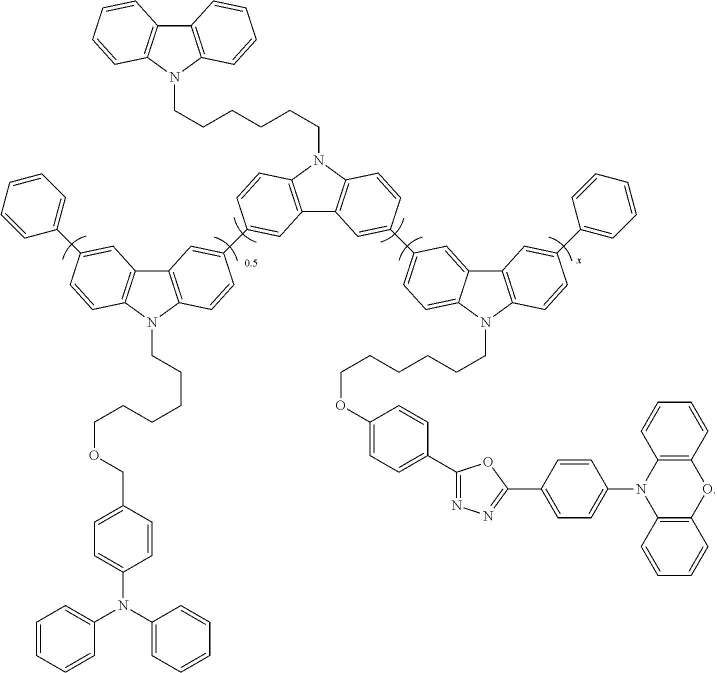

As used in Table 3, the term “PABPC5,” where x=5, refers to the TADF polymer represented by the following chemical structure:

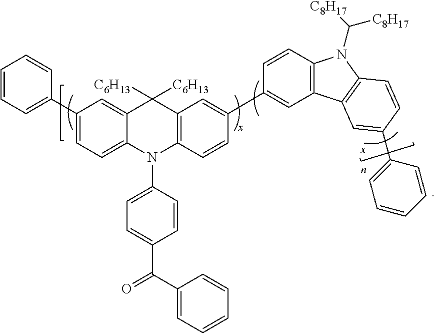

As used herein, the term “PCzATD5,” where x=5, refers to the TADF polymer represented by the following chemical structure:

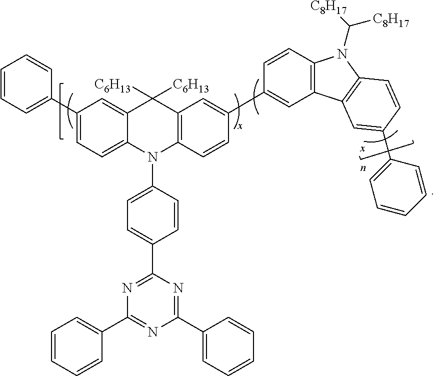

As used in Table 3, the terms “PAPTC,” where x=50, and “PCzAPT10,” where x=10, refer to the TADF polymers represented by the following chemical structure:

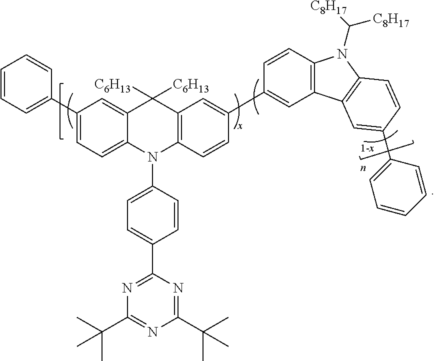

As used in Table 3, the term “PBD-10,” where x=0.10, refers to the TADF polymer represented by the following chemical structure:

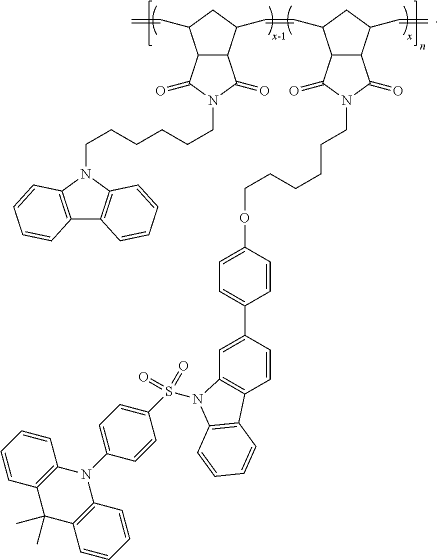

As used in Table 3, the term “PAPCC” refers to the TADF polymer represented by the following chemical structure:

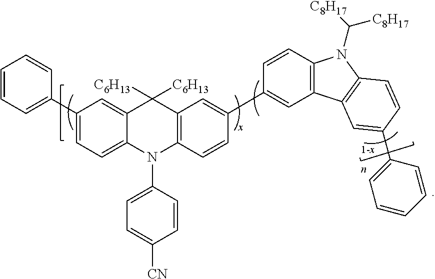

As used in Table 3, the term “P-Ac95-TRZO5,” where x=0.05, refers to the TADF polymer represented by the following chemical structure:

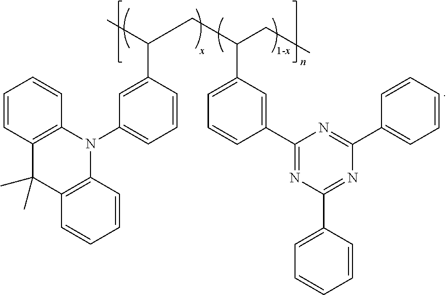

As used in Table 3, the term “PNB-TAc-TRZ-5,” where x is 0.05, refers to the TADF polymer represented by the following chemical structure:

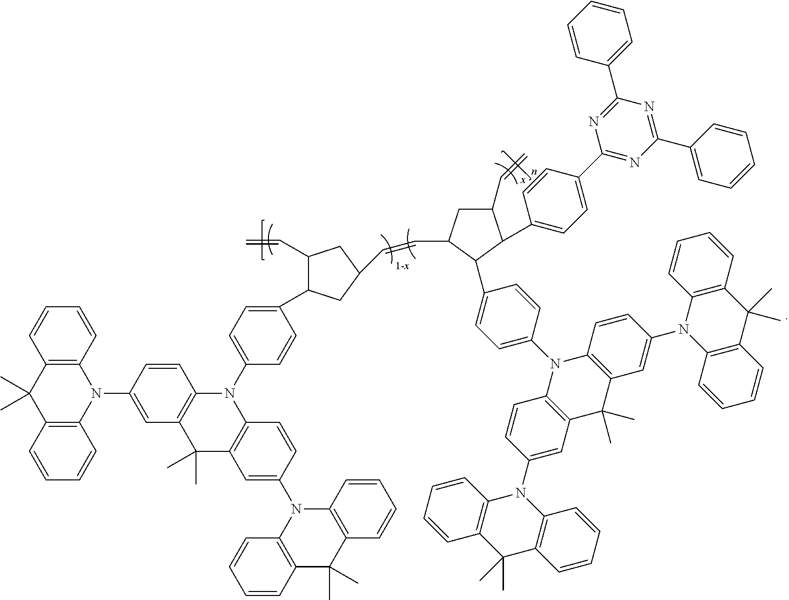

### H. Stretchability of Films of PDKCM, PDKCP, PDKCH, and PDKCD

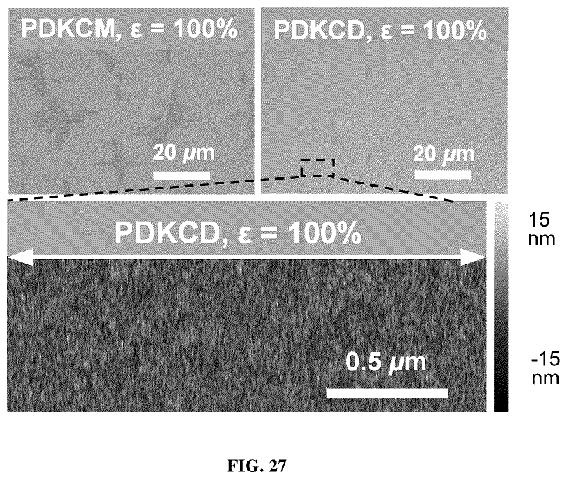

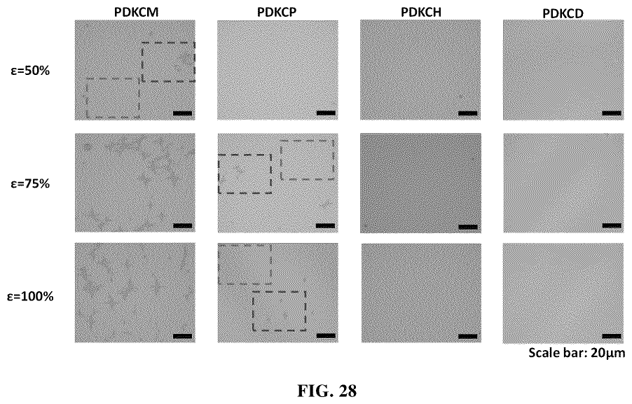

The stretchability of films of the four exemplary stretchable light-emitting polymers PDKCM, PDKCP, PDKCH, PDKCD was tested by measuring the stretching-induced evolution of luminescent performance up to 100% strain. Consistently with the trends for mechanical properties of the four exemplary stretchable light-emitting polymers illustrated by FIG. 16, the crack sizes and crack densities of films under large strains greatly reduced as the alkylene chain length of the exemplary stretchable light-emitting polymer increased, as illustrated by FIGS. 27 and 28. For example, a PDKCD film under 100% strain demonstrated intact morphology without any cracks, including nanoscale-sized cracks.

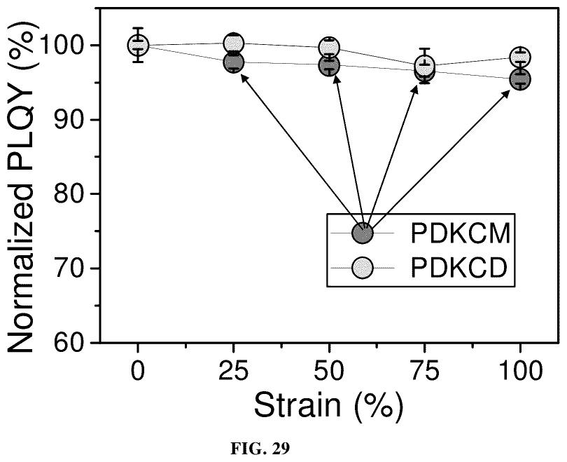

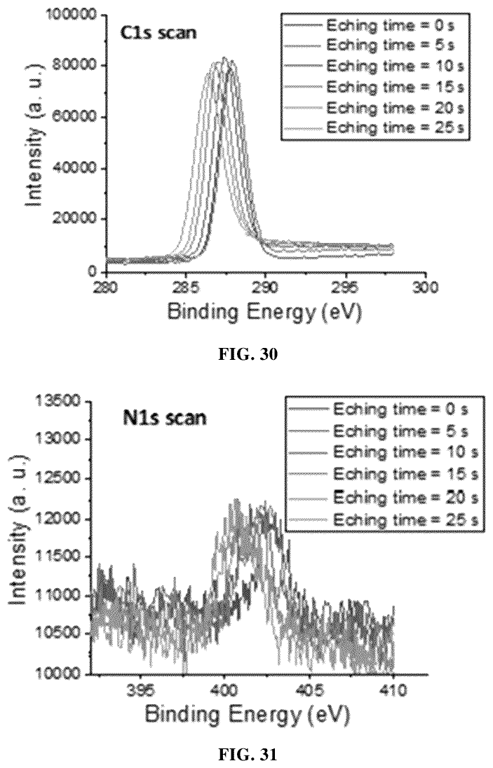

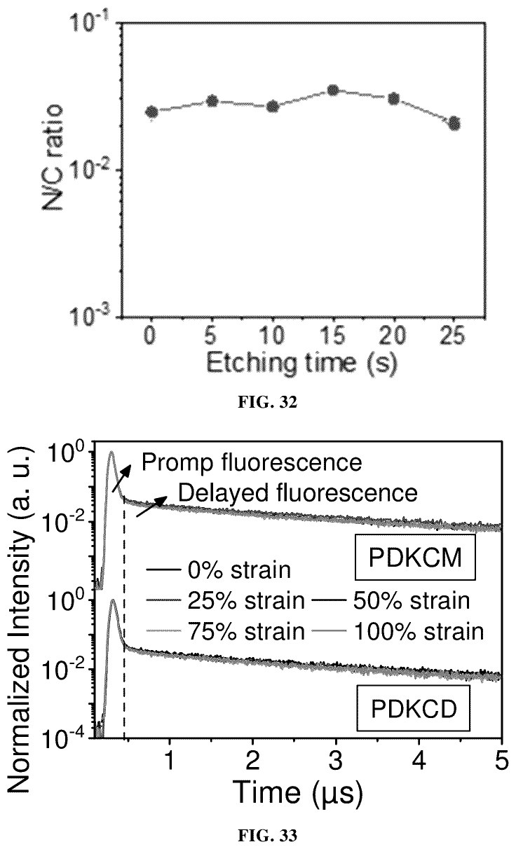

The effects of the strain and consequent crack formations on PL properties of the four exemplary stretchable light-emitting polymers were evaluated. However, PL processes are essentially localized to individual TADF units, so even in the case of crack formation, strain has demonstrated little influence on either PLQYs, as illustrated by FIGS. 29-32, or transient PL decay behaviors, as illustrated by FIGS. 21A-21E, 22A-22E, and 33 for all of the four exemplary stretchable light-emitting polymers.

The EL performance of the five exemplary stretchable polymers in OLED devices is also determined by the charge injection and by charge transport. Formation of cracks in the emitter layers of the OLEDs, where the emitter layer includes one of the five exemplary stretchable polymers, may have significant effects on charge injection and charge transport.

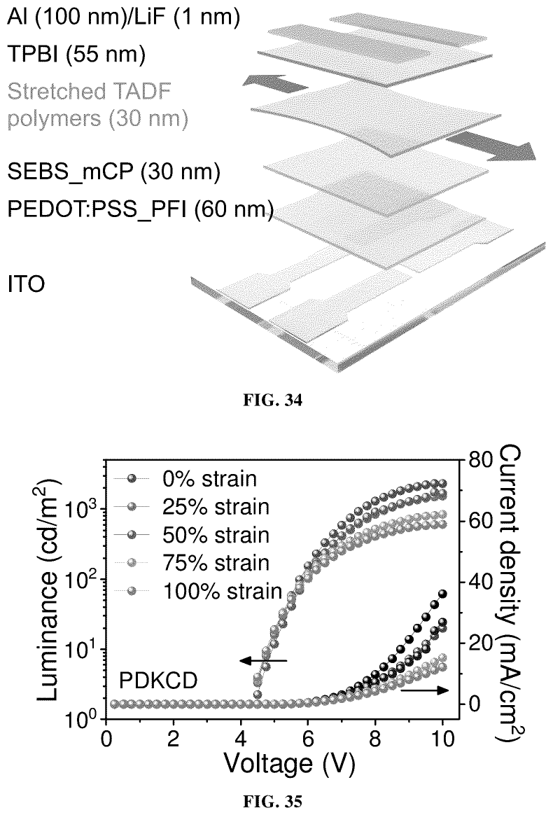

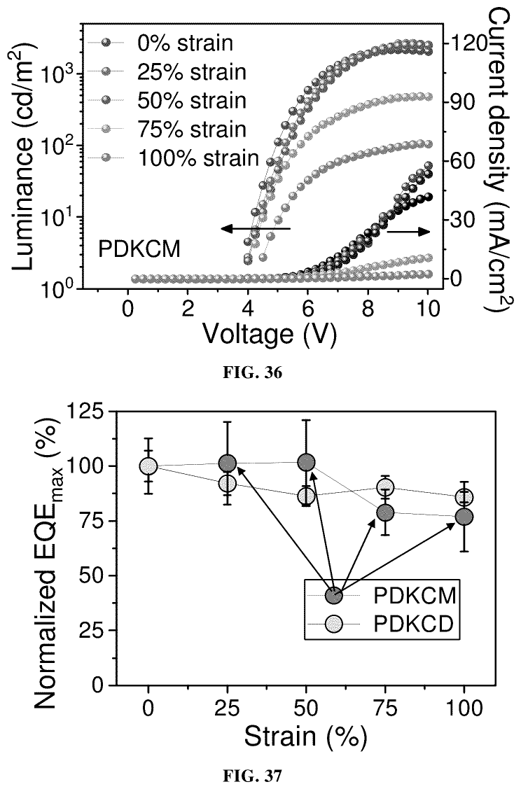

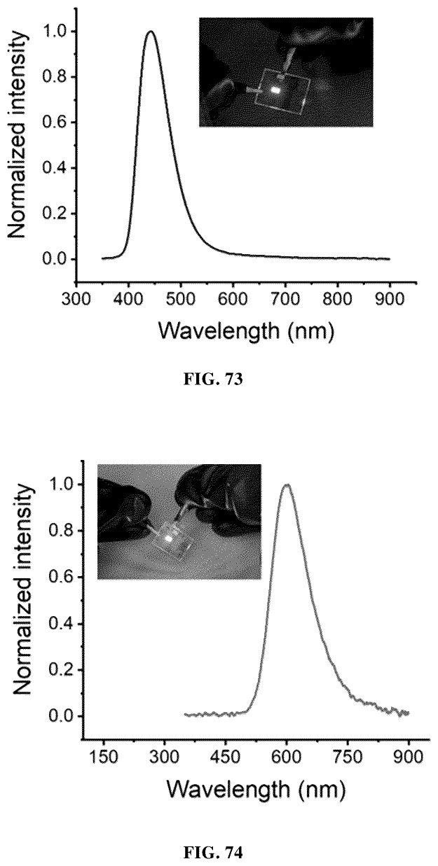

Each of the five exemplary stretchable polymer films was separately physically transferred onto a rigid device stack to study the effects of crack formation in emitter layers in a conventional OLED device structure, as illustrated by FIG. 34. The other layers of the OLED device were deposited by thermal evaporation. An additional layer of polystyrene-block-poly(ethylene-ranbutylene)-block-polystyrene (“SEBS”) and 1,3-bis(N-carbazolyl)benzene (“mCP”) blend in a weight ratio of 1:1 SEBS:mCP was inserted beneath the stretchable light-emitting polymer to increase surface adhesion and facilitate transfer. During stretching to 100% strain, the PDKCD film demonstrated much more stable luminance and current density (illustrated by FIG. 35) than the PDKCM film (illustrated by FIG. 36). Based on the decrease in current density and luminance with increase in strain observed for the PDKCM film, without being bound by theory, it is believed that negative effects of crack formations in the emitting layer of the OLED including PDKCM film result from the combination of contact deterioration between the cracked emitter and the adjacent electron/hole-transporting layers, and the increase of crack-induced charge tripping in the emitting layer. Representative EL spectrum of an OLED with PTrz-tBuCz as the emitting layer is illustrated in FIG. 73 (blue-light emission) and FIG. 74 (red-light emission).

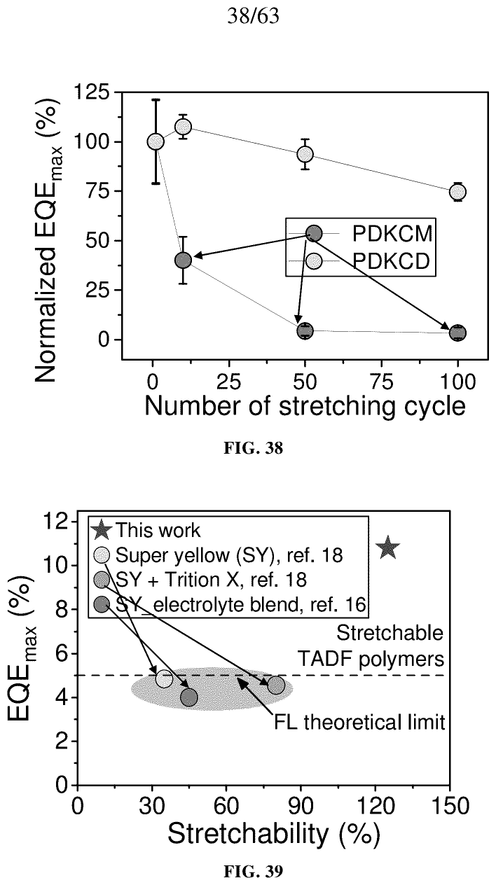

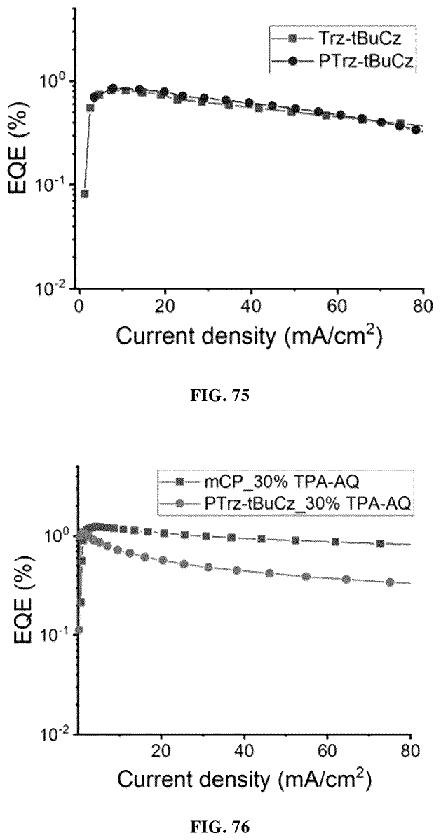

Further, the extracted EQEₘₐₓ values for the PDKCD film, illustrated by FIG. 37, decrease negligibly during stretching to 100% strain, and EQEₘₐₓ is maintained at approximately 10%. With repeated stretching to 100% strain for 100 cycles, PDKCD film also exhibits much more stable performance than PDKCM, as illustrated by FIG. 38. Compared to known stretchable light-emitting polymers, which have been based on a first-generation FL emitter, as illustrated in FIG. 39, the stretchable light-emitting polymers of the present disclosure achieved substantial increases both in EL efficiency, to twice of the theoretical limit of FL emitters, as represented by EQEₘₐₓ, and in stretchability, based on crack onset strain. An EQE-current density plot from the OLED with a PTrz-tBuCz emitting layer, in comparison to an EQE-current density plot from an OLED with a small molecule emitter Trz-tBUCz, is illustrated in FIG. 75. The OLED device structure is ITO/PEDOT:PSS_PFI (60 nm)/PTrz-tBuCz or Trz-tBuCz (30 nm)/TmPyPb (55 nm)LiF (1 nm)/Al. An EQE-current density plot from the OLED with a PTrz-tBuCz_30% TPA-AQ emitting layer, in comparison with that from mCP_30% TPA-AQ is illustrated in FIG. 76. The OLED device structure is ITO/PTrz-tBuCz_30% TPA-AQ or mCP_30% TPA-AQ (30 nm)/TmPyPb (55 nm)/LiF (1 nm)/Al. The structure of mCP is:

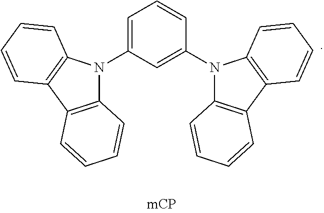 [SMILES: c1cc(-n2c3ccccc3c3ccccc32)cc(-n2c3ccccc3c3ccccc32)c1]

### I. Atomistic Molecular Dynamics (MD) Simulations

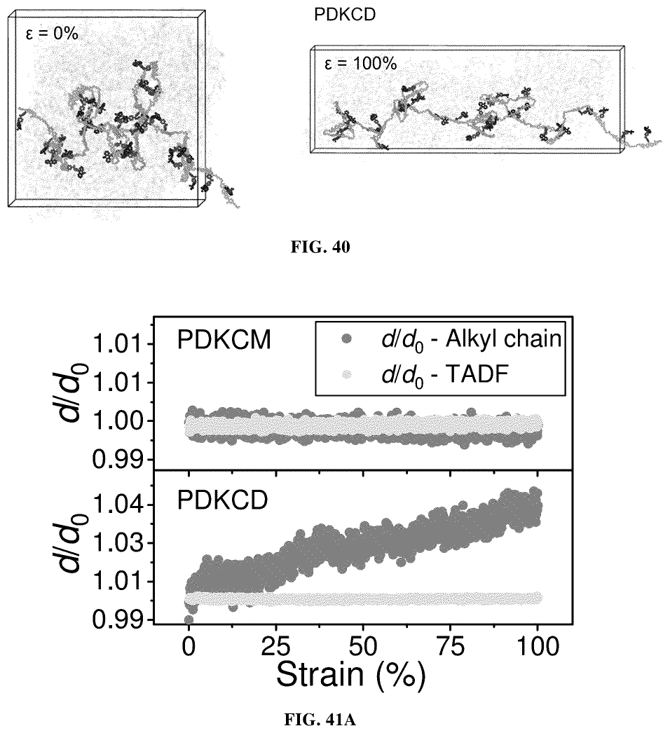

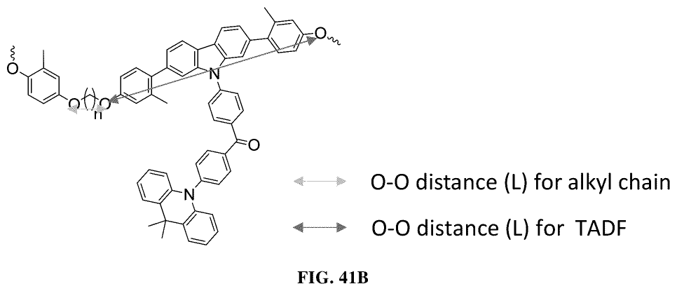

Atomistic MD simulations were performed to obtain molecular-level insight into the mechanism for strain energy dissipation and correlation of dissipation with the EL process. By tracking the conformation of a randomly selected polymer chain in a modeled PDKCD film, it was demonstrated in FIG. 40 that the applied stretching induces the polymer chain to gradually orient toward the stretching direction, which generally dissipates strain. At a detailed level, it was confirmed that the C₁₀alkylene units in the PDKCD backbone provide the most significant contribution to strain dissipation. The evolution of the straight-line distances between the terminal atoms for individual alkylene units, and for TADF segments, under stretching to 100% strain were separately evaluated, and it was demonstrated in FIGS. 41A and 41B that the C₁₀alkylene chains of stretchable sections of PDKCD are straightened effectively by the applied strain, while the TADF units and the C₁alkylene chain of stretchable sections in PDKCM have little conformational change to dissipate strain energy. The intramolecular-conformational structure and the intermolecular-packing structure of the TADF segments for PDKCM, PDKCP, PDKCH, and PDKCD were analyzed and compared, both in the pristine states and under stretching. The intramolecular-conformational structures and intermolecular-packing structures may indicate the influences of the alkylene chains of the stretchable sections and the stretching on the TADF process, the charge transport, and the EL performance.

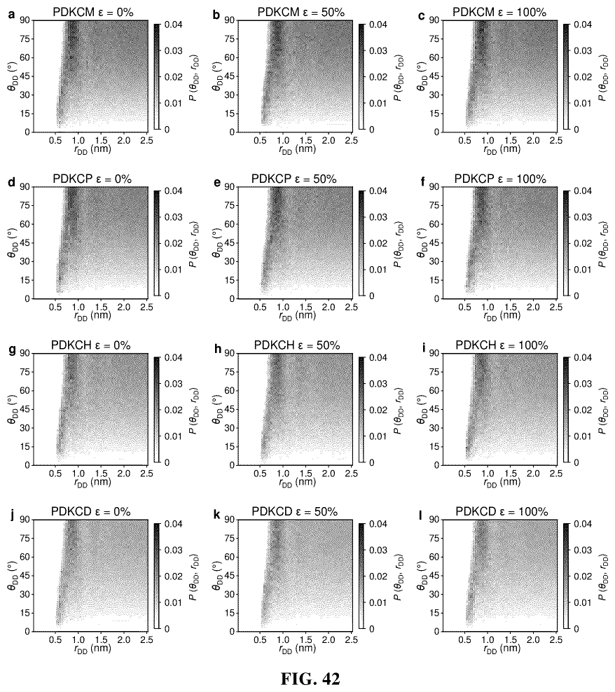

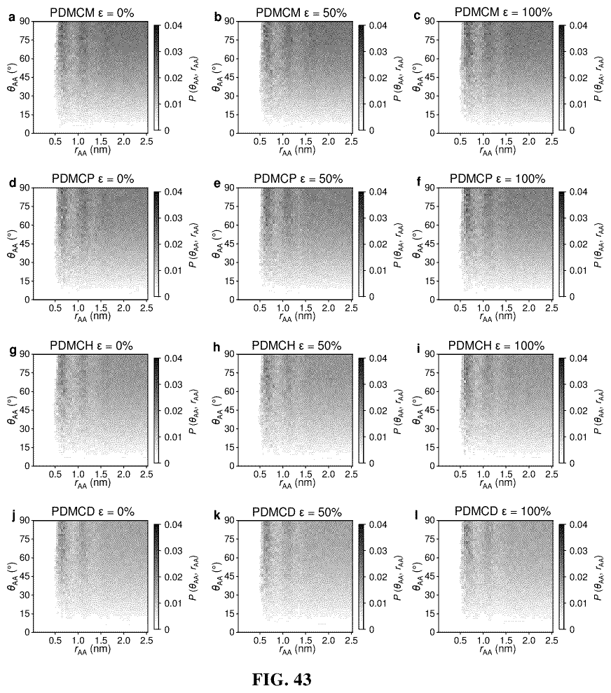

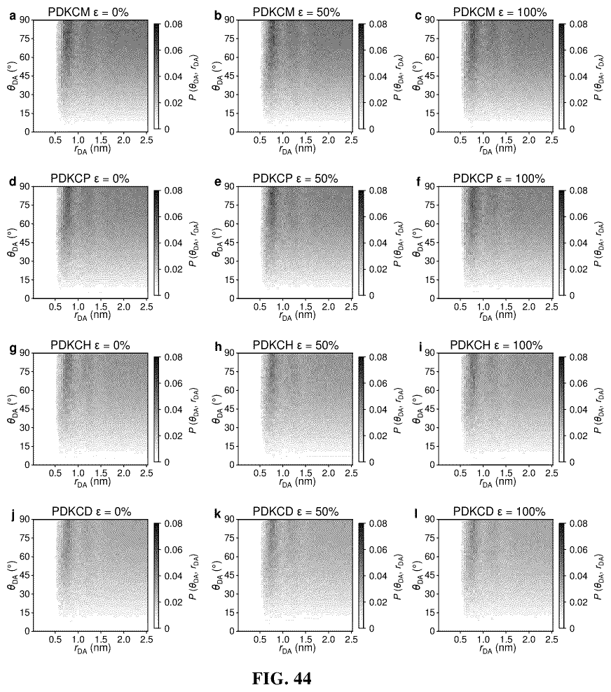

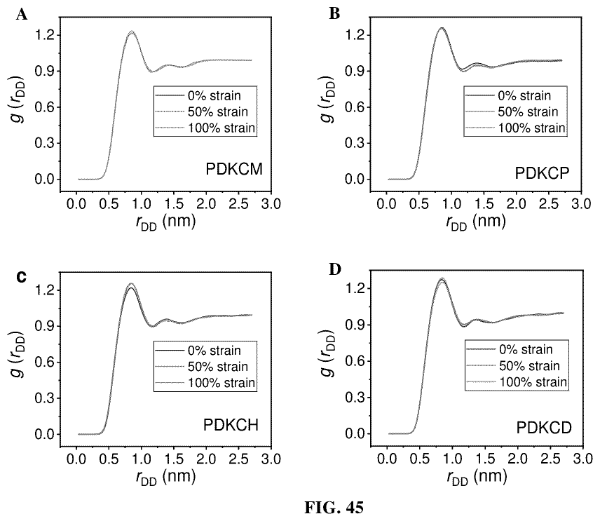

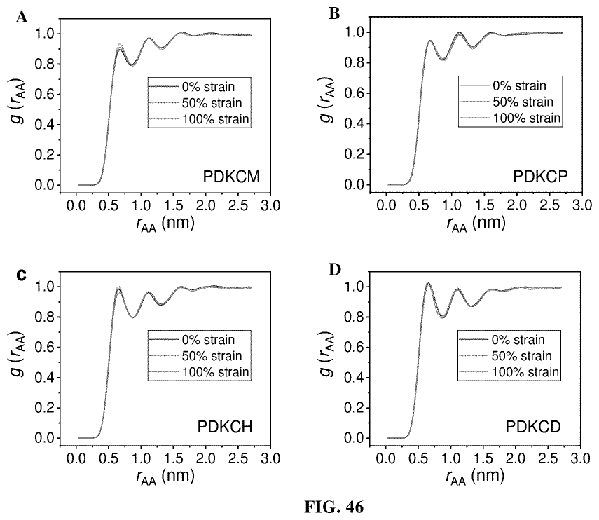

The distributions of the D-A dihedral angle in TADF units in all four of PDKCM, PDKCP, PDKCH, and PDKCD remained nearly unchanged under strain. The evaluation of the distances and the angles between the first nearest donor-donor (“D-D”) pairs, the first nearest acceptor-acceptor (“A-A”) pairs, and the second-nearest D-A pairs demonstrate very small changes during the stretching process, as illustrated by FIGS. 42 to 44. The consistency in the packing structure of PDKCM, PDKCP, PDKCH, and PDKCD is reflected in the radial distribution function of donor and acceptor results, as illustrated in FIGS. 45 and 46. The results indicate that both the inserted alkylene units of the stretchable section of PDKCM, PDKCP, PDKCH, and PDKCD and the applied strain before crack formation exert limited influences on long-range charge-carrier hopping, which provides insight into the experimental observations of the EL performances of PDKCM, PDKCP, PDKCH, and PDKCD.

### J. Fully Stretchable OLEDs

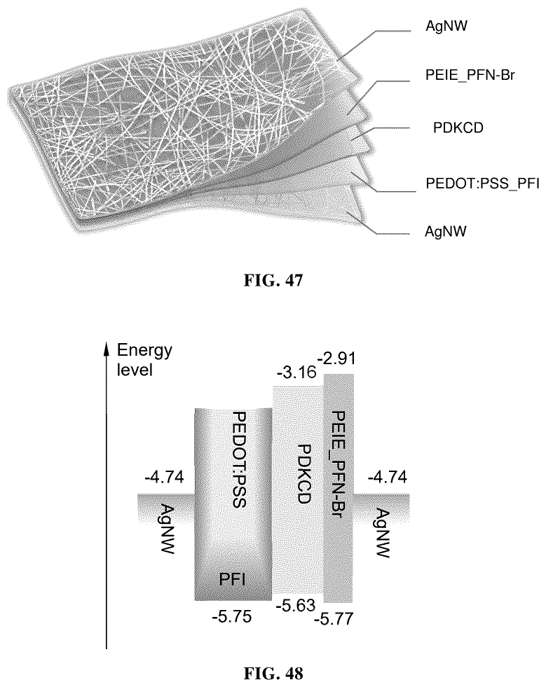

To demonstrate the applicability of the stretchable light-emitting polymers of the present disclosure in examples of fully stretchable OLEDs, a set of materials and a fabrication process for imparting stretchability onto all layers of the OLEDs so as to enable efficient charge injections were developed, as illustrated in FIGS. 47 and 48.

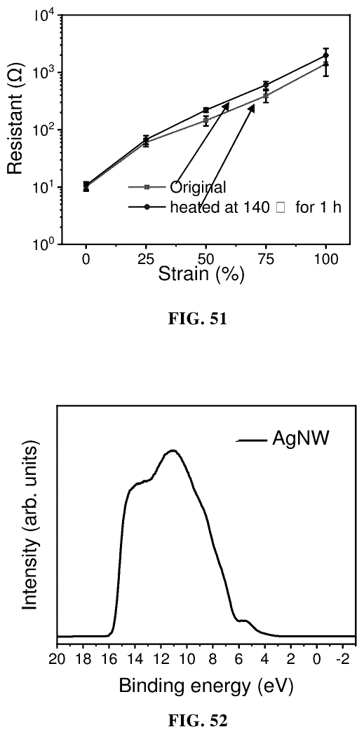

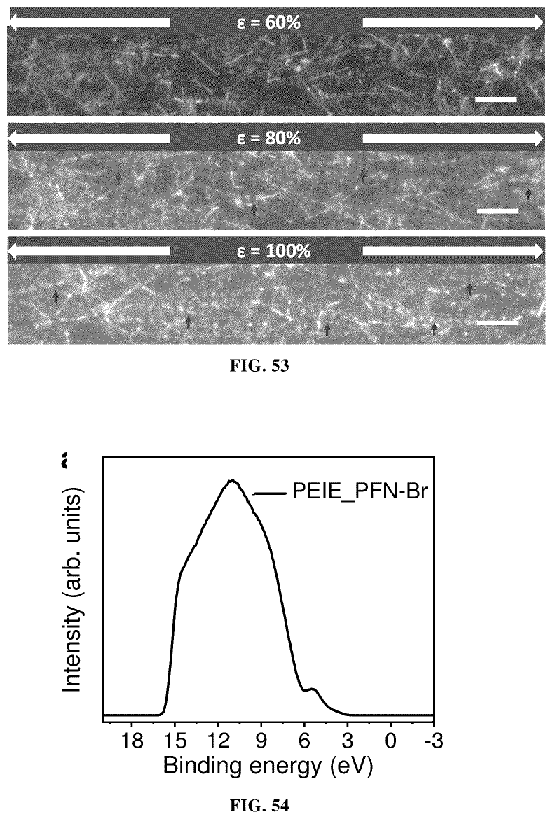

Both the cathode and anode are stretchable transparent silver nanowire (“AgNW”) assemblies embedded within a thin layer of thermoplastic polyurethane (“TPU”). The cathode and anode fabrication process is illustrated in FIG. 49. The electrodes were then released as stretchable, transparent AgNW/TPU/PDMS electrodes, which provide high conductivity, high stretchability, and moderate transparency, as illustrated in FIGS. 50-53.

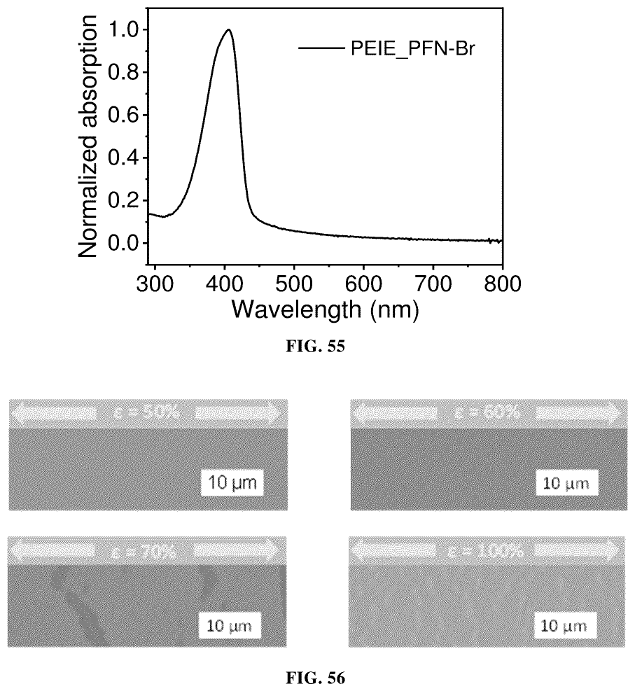

Between the cathode and the stretchable light-emitting polymer, so as to bridge the Fermi level of the AgNW and the lowest-unoccupied molecular orbital (“LUMO”) of the stretchable light-emitting polymer, a stretchable electron injection layer (“EIL”) was designed by blending poly[(9,9-bis(3′-((N,N-dimethyl)-N-ethylammonium)-propyl)-2,7-fluorene)-alt-2,7-(9,9-dioctylfluorene)](“PFN-Br”) with polyethyleneimine ethoxylated (“PEIE”) in a weight ratio of 1:1. Without being bound by theory, it is believed that the PEIE both reduces the work function of the AgNW cathode, as illustrated in FIGS. 54 and 55, and enables the stretchability of this EIL by taking advantage of the low T_{g} of the EIL. The EIL has the stretchability of 60% strain, as illustrated in FIG. 56.

Poly[(9,9-bis(3′-((N,N-dimethyl)-N-ethylammonium)-propyl)-2,7-fluorene)-alt-2,7-(9,9-dioctylfluorene)](PFN-Br) has the following structural formula:

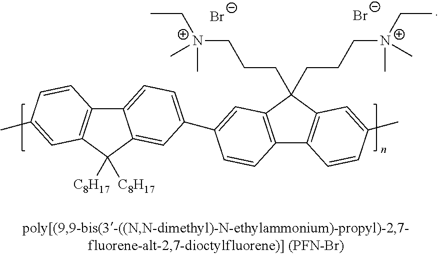

Polyethyleneimine ethoxylated (PEIE) has the following structural formula:

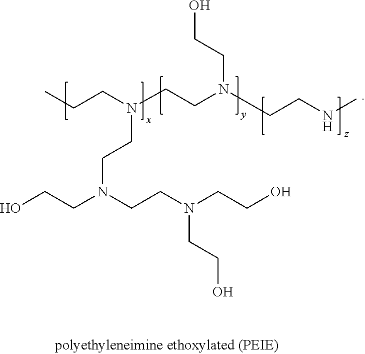

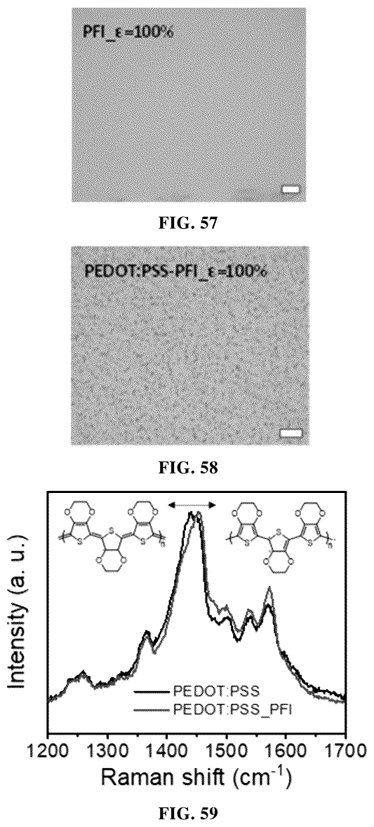

Between the anode and the stretchable light-emitting polymer is a stretchable hole transporting layer (“HTL”) formed by mixing poly(3,4-ethylenedioxythiophene) poly(styrenesulfonate) (“PEDOT:PSS”) with perfluorinated ionomers (“PFI”) in a weight ratio of 5:3. The PFI increases stretchability of the HTL to over 100% strain, as illustrated in FIGS. 57-59, and reduces the highest-occupied molecular orbital (“HOMO”) level for more efficient hole injection, as illustrated in FIG. 60.

Poly(3,4-ethylenedioxythiophene) (PEDOT) has the following structural formula:

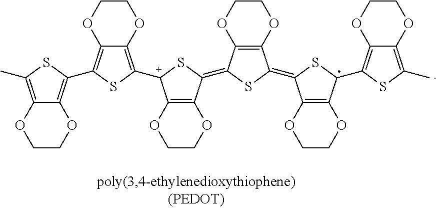

Poly(styrenesulfonate) (PSS) has the following structural formula:

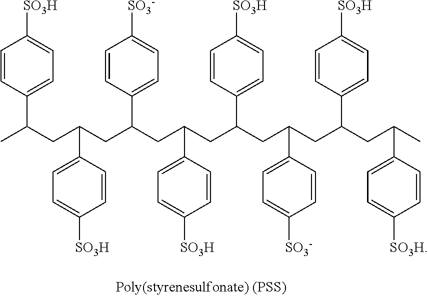

In an example, perfluorinated ionomers (PFI) may have the following structural formula:

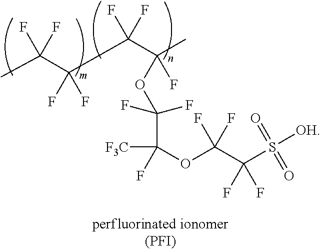

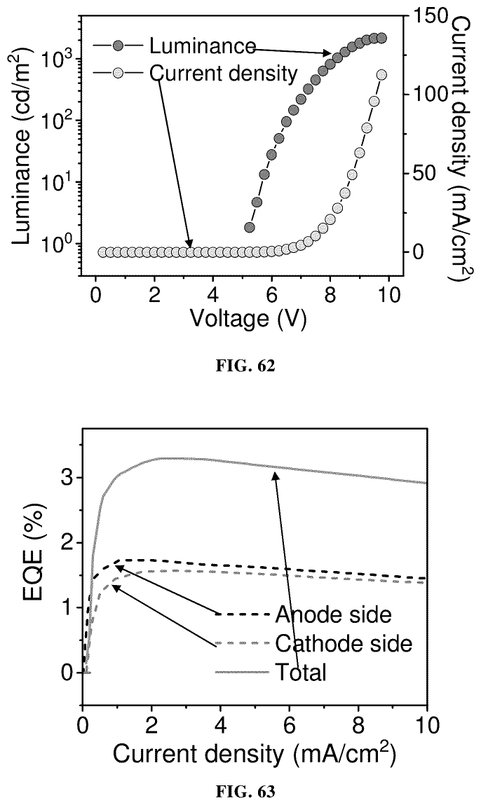

For fabrication of the fully stretchable OLED devices including stretchable light-emitting polymers of the present disclosure, the solution-processing compatibility between the layers enables the layer-on-layer direct depositions, enabling better interface adhesions in the device. The resulting stretchable OLED devices may be successfully powered by a commercial 9-volt battery, as illustrated in FIG. 61. The performance in the original states demonstrates a record-low turn-on voltage of 4.75 V, as illustrated in FIG. 62, and a record-high total EQEₘₐₓ of 3.3% compared to all of the reported stretchable OLEDs as shown in Table 4 (derived by adding together the emission from the cathode and anode sides, as illustrated in FIG. 63).

TABLE 4
Performance Comparison of Stretchable OLEDs Including Stretchable Light-Emitting
Polymers of the Present Disclosure Compared to Previously Reported Examples

| | | Turn-on | | | | |
|---|---|---|---|---|---|---|
| EL | Turn-on | voltage | CEₘₐₓ | EQEₘₐₓ | Stretchability | |
| Mechanism | time | (V) | (cd/A⁻¹) | (%) | (%) | Emitter |
| OLEDs | ~ns-ms | 4.75 | 5.3 + 4.9^{a} | 1.7 + 1.6^{a} | 60 | PDKCD |
| | | 8.0 | 1.6 | — | 80 | Super Yellow |
| | | | | | | (“SY”) |
| | | 7.0 | 2.0 | — | 130 | White Light- |
| | | | | | | Emitting |
| | | | | | | Polymers |
| | | | | | | (“WLEP”) |
| | | 13 | — | — | >50 | SY |
| LEECs | ~min | 4.8 | 1.24 | — | 45 | PF-B |
| | | 6.8 | 5.7 | 2.0 | 120 | SY |
| LECs | ~ms | 23, 1k Hz | — | — | — | Phosphor |
| | | | | | | microparticles |
| | | >1000 | — | — | ~500 | ZnS |

^{a}Measured from both anode and cathode sides.
^{b}Alternating current.
CEₘₐₓ = maximum current efficiency.
LEECs = light-emitting electrochemical cells.
LECs = light-emitting capacitors.

The following Table 5 further illustrates a performance comparison of the stretchable light-emitting polymer OLEDs with previously reported stretchable OLEDs and representative stretchable light-emitting electrochemical cells (“LEECs”) and light-emitting capacitors (“LECs”).

TABLE 5

| | | Stretch- | | Voltage | | | | | |
|---|---|---|---|---|---|---|---|---|---|
| | Light | ability | Turn-on | at 1000 | | | | Stretch- | |
| EL | emitting | design | voltage | cd/m² | Brightnessₘₐₓ | CEₘₐₓ | EQEₘₐₓ | ability | Turn-on |
| Mechanism | materials | strategy | (V) | (V) | (cd/m²) | (cd/A⁻¹) | (%) | (%) | speed |
| TADF- | PDKCD | Chemically | 4.75 | 8.1 | 2175 @ 10 | 5.3 + 4.9^{b} | 1.7 + 1.6^{a} | 60 | ~ms |
| OLEDs | | inserting | | | V | | | | |
| | | soft alkyl | | | | | | | |
| | | chains | | | | | | | |
| FL- | SY | Blending | 8.0 | 10.5 | 4400 @ 11 | 1.6 | — | 80 | |
| OLEDs | | with | | | V | | | | |
| | | plasticizer | | | | | | | |
| | | Triton-X | | | | | | | |
| | WLEP^{a} | Blending | 7.0 | 10.5 | 1100 @ 21 | 2.0 + 2.0^{b} | — | 130 | |
| | | with OXD-7 | | | V | | | | |
| | SY | Blending | 13.0 | — | ~300 @ 21 | — | — | 50 | |
| | | with PEO | | | V | | | | |
| | | elastomer | | | | | | | |
| | SY | Blending | 5.0 | 10.5 | 7450 @ 15 | 5.3 + 5.2^{b} | — | 100 | |
| | | with PU | | | V | | | | |
| | | elastomer | | | | | | | |
| | SY | Blending | 5.3 | 11.0 | 2175 @ 15 | ~20.3^{c} | — | 20 | |
| | | with | | | V | | | | |
| | | Triton-X | | | | | | | |
| | | plasticizer | | | | | | | |
| | SY | Blending | 3.7 | 7.0 | 1754 @ 11 | 3.14^{c} | — | 30 | |
| | | with PEO | | | V | | | | |
| | | elastomer | | | | | | | |
| LEECs | PF-B | Blending | 4.8 | — | ~300 @ 12 | 1.24 | — | 45 | ~min |
| | | w/PEO | | | V | | | | |
| | | elastomer | | | | | | | |
| | SY | Blending | 6.8 | 18.0 | 2200 @ 21 | 5.7 + 5.7^{a} | 2.0 + 2.0^{a} | 120 | |
| | | w/PEO | | | V | | | | |
| | | elastomer | | | | | | | |
| LECs | ZnS:Cu + | Blending | 23, 1k | — | 1460 @ | — | — | — | ~ms |
| | ZnS:Cu, | w/PVDF | Hz^{d} | | 3750 V, | | | | |
| | Mn | elastomer | | | 800 Hz^{c} | | | | |
| | ZnS | Blending | >1000^{c} | — | — | — | — | ~500 | |
| | | w/Ecoflex | | | | | | | |
| | | 00-30 | | | | | | | |
| | | elastomer | | | | | | | |

^{a}WLEP, white-light-emitting polymer, which was provided by Cambridge Display Company but without specific name offered from the literature.
^{b}Measured from both anode and cathode sides.
^{c}Total value from both anode and cathode sides.
^{d}Alternating current model.
Brightnessₘₐₓ, maximum luminance value.
CEₘₐₓ, maximum current efficiency.
TADF-OLEDs, TADF emitter-based OLEDS.
FL-OLEDs, fluorescent emitter-based OLEDs.

Compared to the EL performance of the stretchable light-emitting polymers of formula (I), (II), (III), (IV), (V), or (VI) in rigid OLED devices, the lower EQEₘₐₓ of fully stretchable OLEDs including a stretchable light-emitting polymer of formula (I), (II), (III), (IV), (V), or (VI) may result from the lower conductance, non-ideal interface band alignment, and limited transparency and increased resistance of the AgNW electrodes.

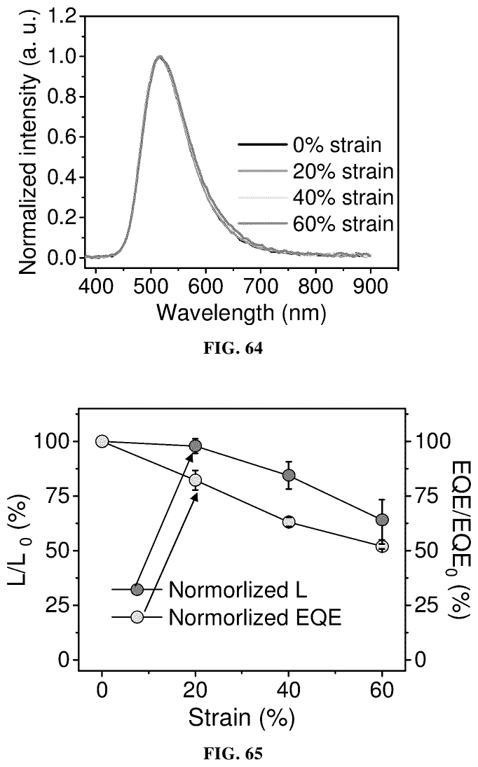

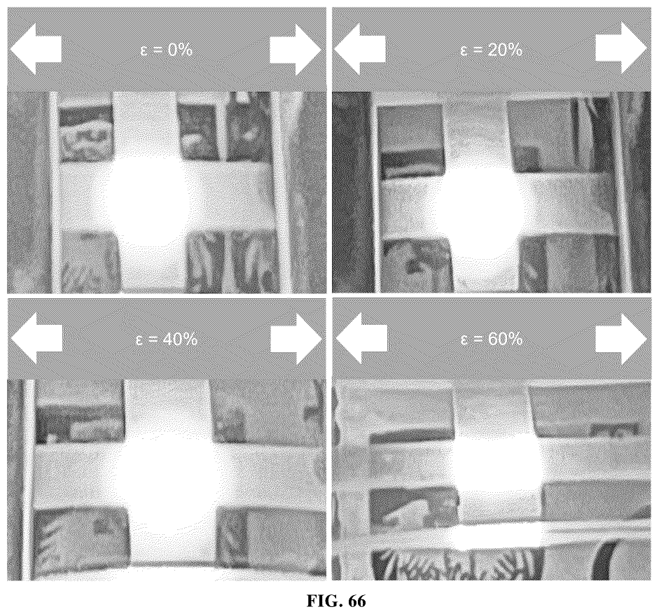

The example of the fully stretchable OLED of FIG. 47 may be stretched to 60% while keeping the unshifted luminescent wavelength with the CIE chromaticity coordinates of (0.31, 0.53), as illustrated in FIG. 64. The luminance of the OLED of FIG. 47 maintains at over 60% of its original value, as illustrated in FIG. 65, and the EQEₘₐₓ maintains at over 50% of its original value, as illustrated in FIG. 66. When stretched to over 60% strain, any incidental failures may be attributable to shorting between the AgNW electrodes across the thickness-decreased middle layers.

Although the present disclosure has been described with reference to examples and the accompanying drawings, the present disclosure is not limited thereto, but may be variously modified and altered by those skilled in the art to which the present disclosure pertains without departing from the spirit and scope of the present disclosure.

The subject-matter of the disclosure may also relate, among others, to the following aspects:

A first aspect relates to a stretchable light-emitting polymer of formula (I), (II), (III), (IV), or (V):

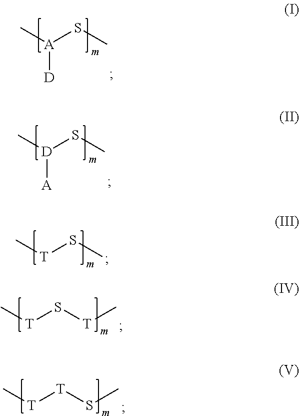

wherein D is a donor chemical moiety capable of donating electrons; A is an acceptor chemical moiety capable of accepting electrons; T is a chemical moiety comprising D bonded to A; S is a stretchable section, comprising a stretchable chemical moiety selected from the group consisting of

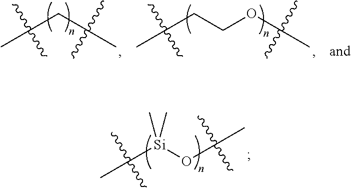

m is an integer from 1 to 100; n is an integer from 1 to 50; and a dihedral angle of a bond between D and A is from about 75.0° to about 90.00.

A second aspect relates to the polymer of aspect 1, wherein the stretchable section comprises a stretchable chemical moiety selected from the group consisting of

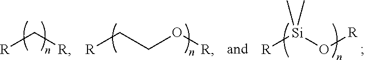

and wherein R is a linker moiety, bonded in either direction, selected from the group consisting of

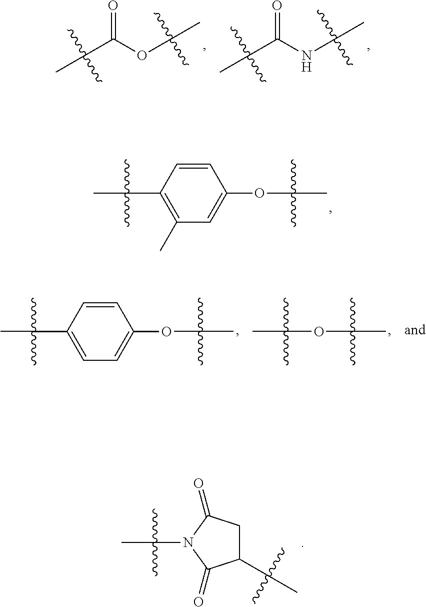

A third aspect relates to the polymer of any preceding aspect, wherein the donor chemical moiety is selected from the group consisting of:

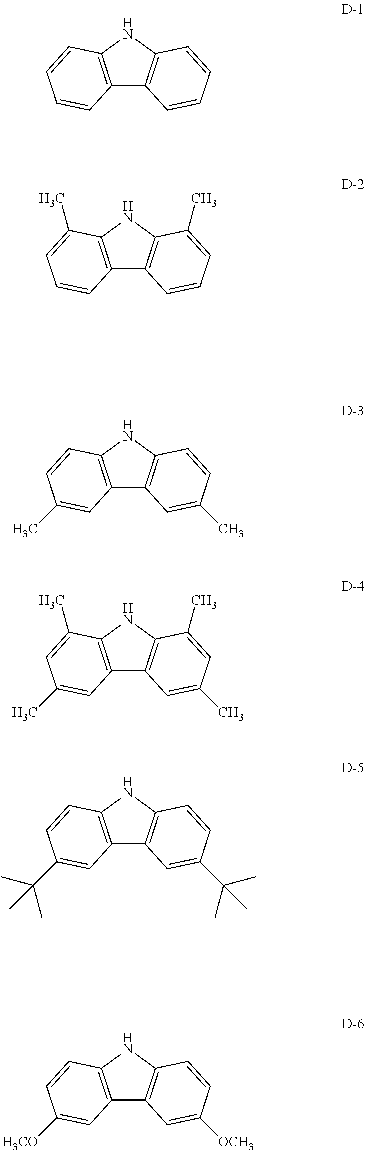

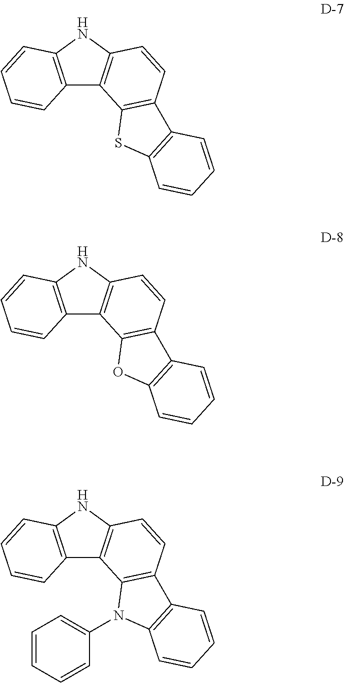 [SMILES: c1ccc2c(c1)[nH]c1ccc3c4ccccc4sc3c12 ; c1ccc2c(c1)[nH]c1ccc3c4ccccc4oc3c12 ; c1ccc(-n2c3ccccc3c3ccc4[nH]c5ccccc5c4c32)cc1]

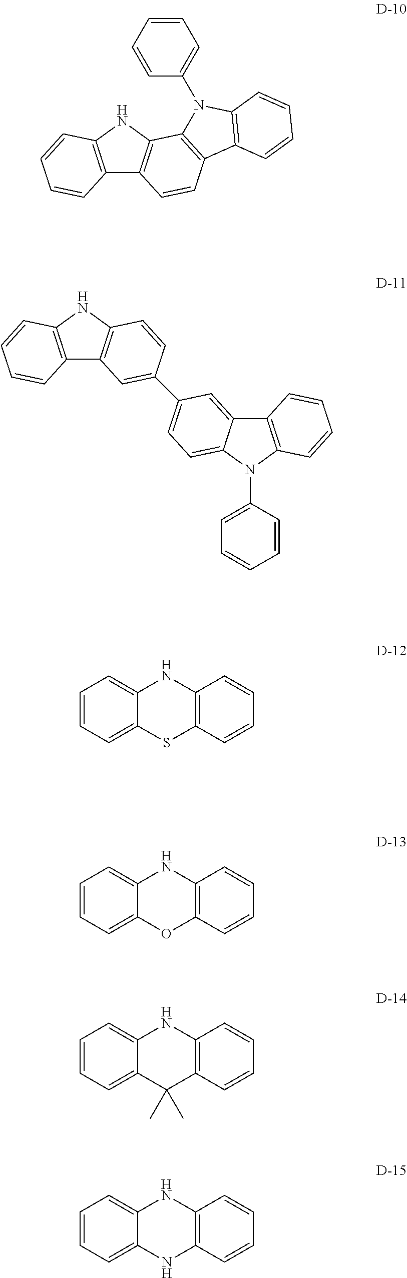 [SMILES: c1ccc(-n2c3ccccc3c3ccc4c5ccccc5[nH]c4c32)cc1 ; c1ccc(-n2c3ccccc3c3cc(-c4ccc5[nH]c6ccccc6c5c4)ccc32)cc1 ; c1ccc2c(c1)Nc1ccccc1S2 ; c1ccc2c(c1)Nc1ccccc1O2 ; CC1(C)c2ccccc2Nc2ccccc21 ; c1ccc2c(c1)Nc1ccccc1N2]

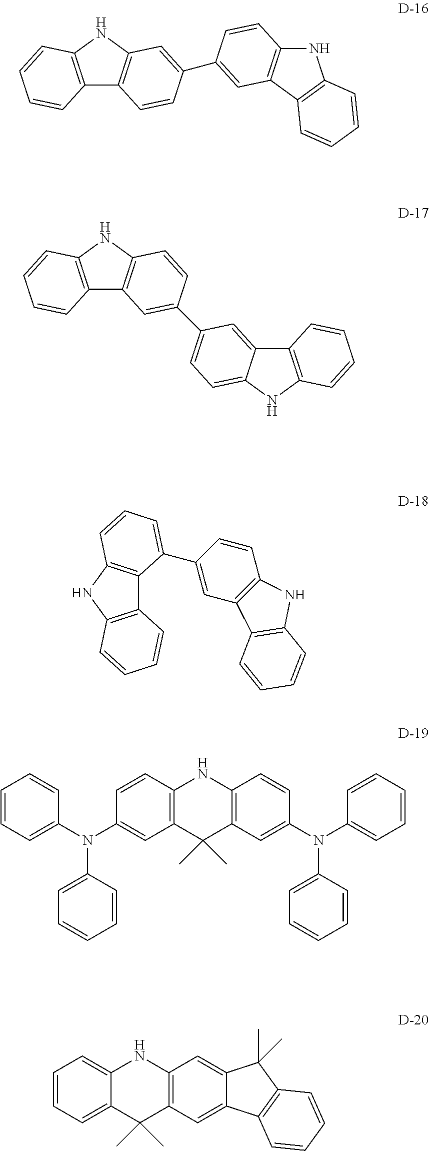 [SMILES: c1ccc2c(c1)[nH]c1cc(-c3ccc4[nH]c5ccccc5c4c3)ccc12 ; c1ccc2c(c1)[nH]c1ccc(-c3ccc4[nH]c5ccccc5c4c3)cc12 ; c1ccc2c(c1)[nH]c1ccc(-c3cccc4[nH]c5ccccc5c34)cc12 ; CC1(C)c2cc(N(c3ccccc3)c3ccccc3)ccc2Nc2ccc(N(c3ccccc3)c3ccccc3)cc21 ; CC1(C)c2ccccc2Nc2cc3c(cc21)-c1ccccc1C3(C)C]

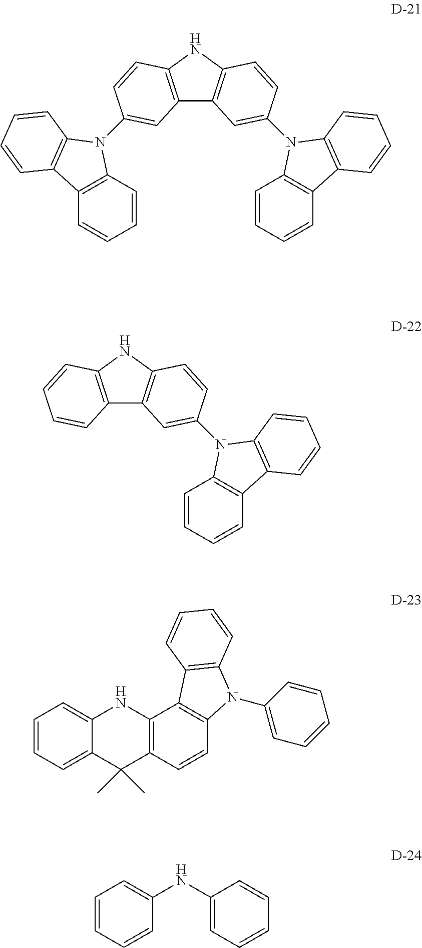 [SMILES: c1ccc2c(c1)c1ccccc1n2-c1ccc2[nH]c3ccc(-n4c5ccccc5c5ccccc54)cc3c2c1 ; c1ccc2c(c1)[nH]c1ccc(-n3c4ccccc4c4ccccc43)cc12 ; CC1(C)c2ccccc2Nc2c1ccc1c2c2ccccc2n1-c1ccccc1 ; c1ccc(Nc2ccccc2)cc1]

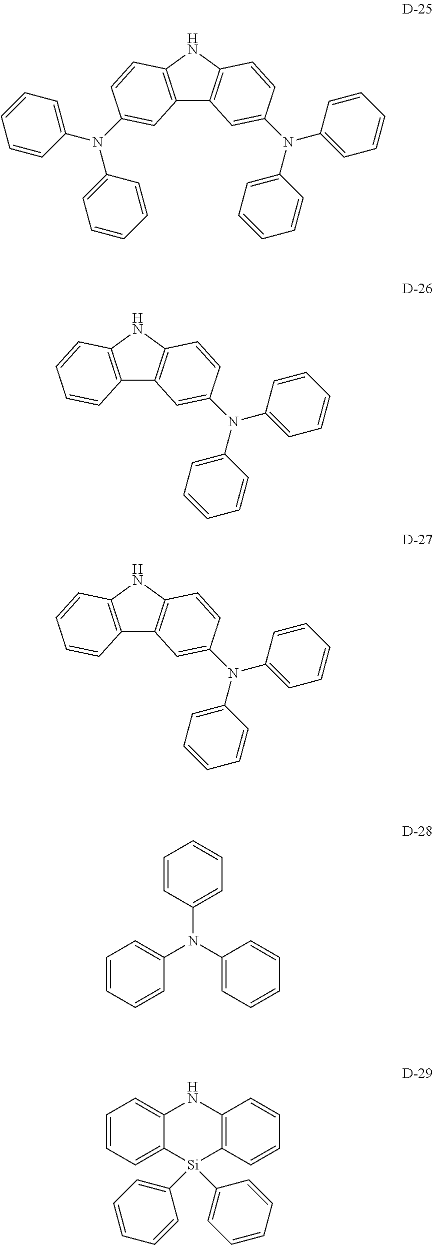 [SMILES: c1ccc(N(c2ccccc2)c2ccc3[nH]c4ccc(N(c5ccccc5)c5ccccc5)cc4c3c2)cc1 ; c1ccc(N(c2ccccc2)c2ccc3[nH]c4ccccc4c3c2)cc1 ; c1ccc(N(c2ccccc2)c2ccc3[nH]c4ccccc4c3c2)cc1 ; c1ccc(N(c2ccccc2)c2ccccc2)cc1 ; c1ccc([Si]2(c3ccccc3)c3ccccc3Nc3ccccc32)cc1]

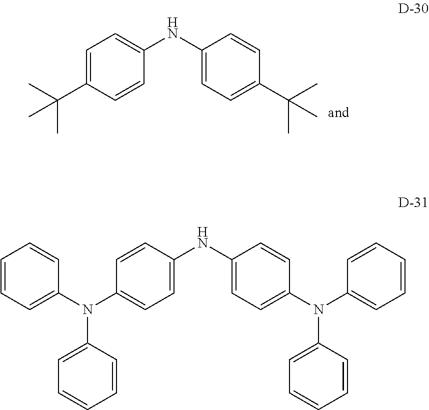 [SMILES: CC(C)(C)c1ccc(Nc2ccc(C(C)(C)C)cc2)cc1 ; c1ccc(N(c2ccccc2)c2ccc(Nc3ccc(N(c4ccccc4)c4ccccc4)cc3)cc2)cc1]

and wherein the donor chemical moiety is bonded to the acceptor chemical moiety at a carbon or nitrogen atom of the donor chemical moiety.

A fourth aspect relates to the polymer of any preceding aspect, wherein the acceptor chemical moiety is selected from the group consisting of:

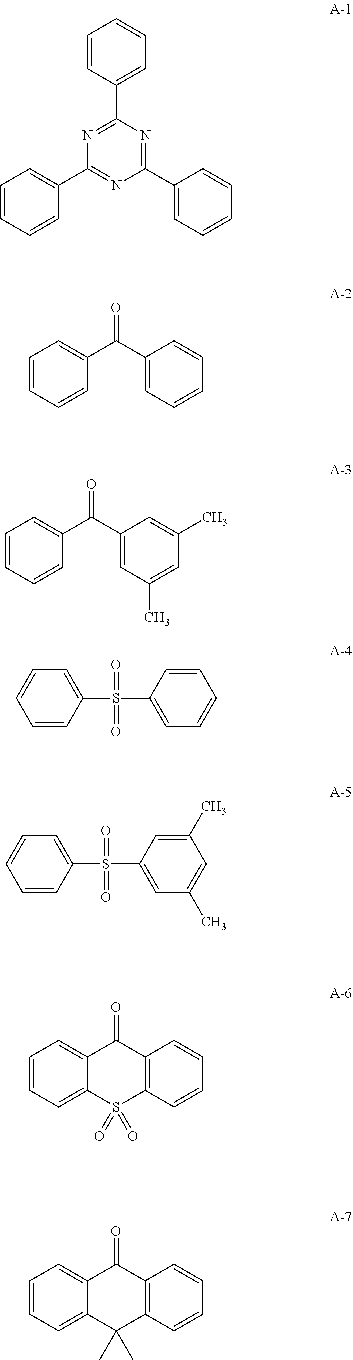

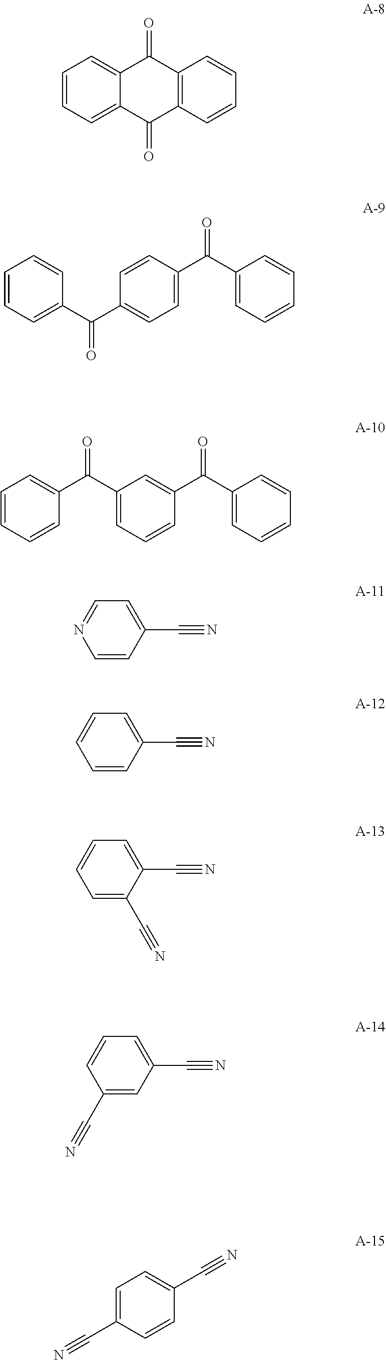

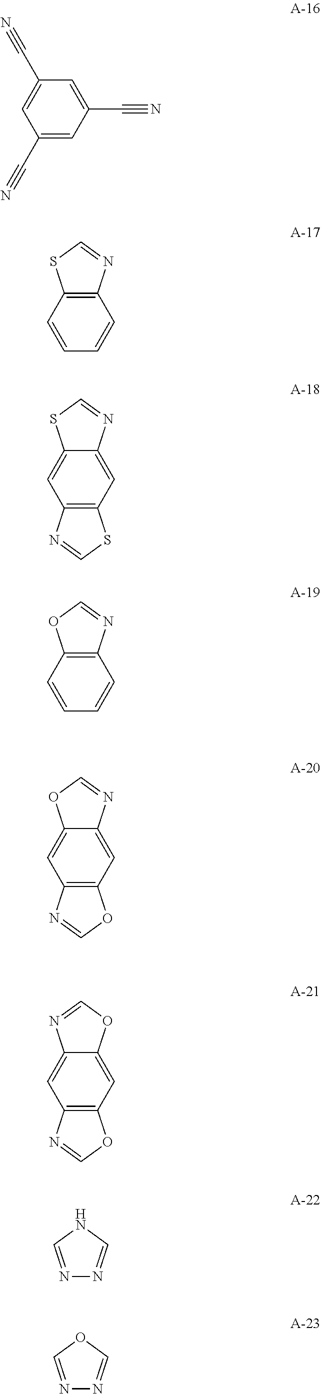

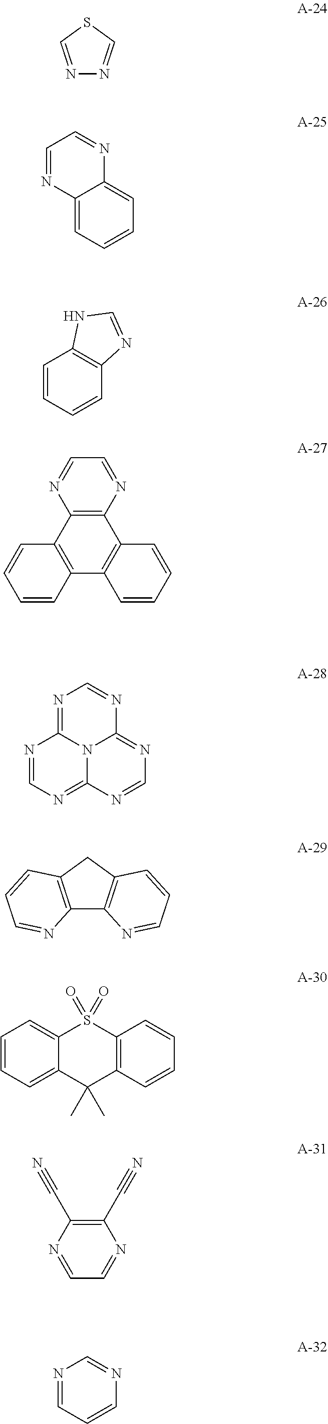

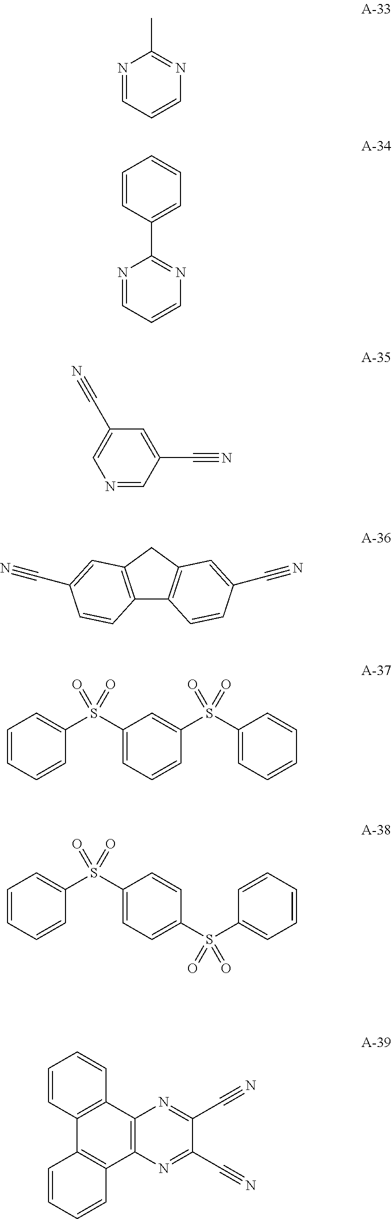

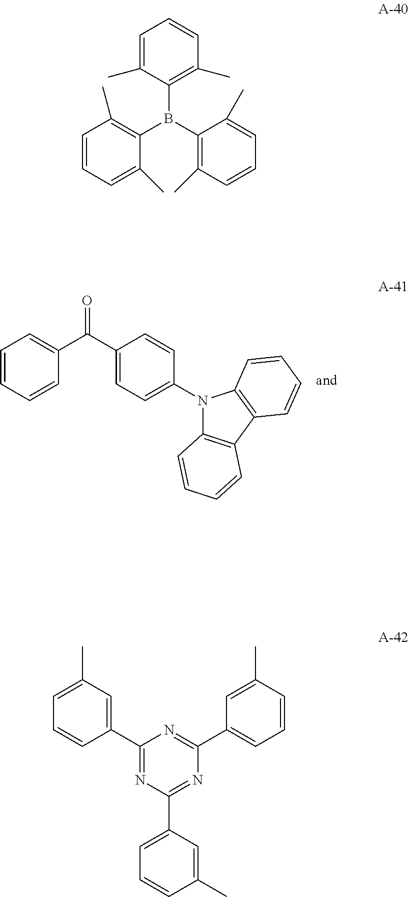 [SMILES: Cc1cccc(C)c1B(c1c(C)cccc1C)c1c(C)cccc1C ; O=C(c1ccccc1)c1ccc(-n2c3ccccc3c3ccccc32)cc1 ; Cc1cccc(-c2nc(-c3cccc(C)c3)nc(-c3cccc(C)c3)n2)c1]

wherein the acceptor chemical moiety is bonded to the donor chemical moiety at a carbon, nitrogen, boron, or sulfur atom, and the acceptor chemical moiety is bonded to each of two stretchable sections at each of a second and a third carbon, nitrogen, boron, or sulfur atom.

A fifth aspect relates to the polymer of any preceding aspect, wherein the polymer is a polymer of formula (VI):

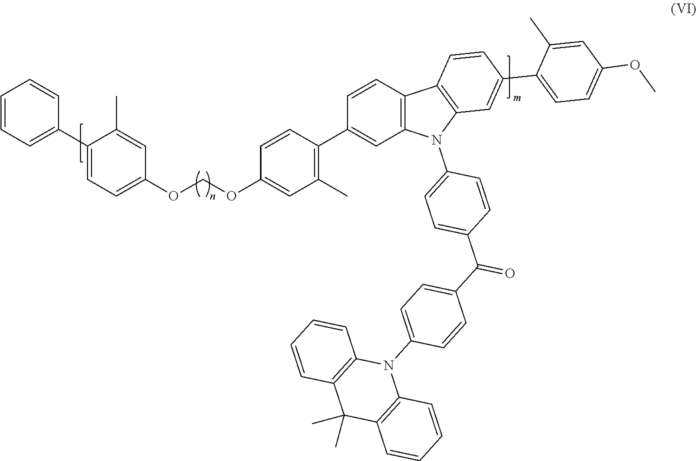

wherein m is an integer from 1 to 100; and n is an integer from 1 to 50.

A sixth aspect relates to the polymer of any preceding aspect, wherein the polymer is selected from the group consisting of:

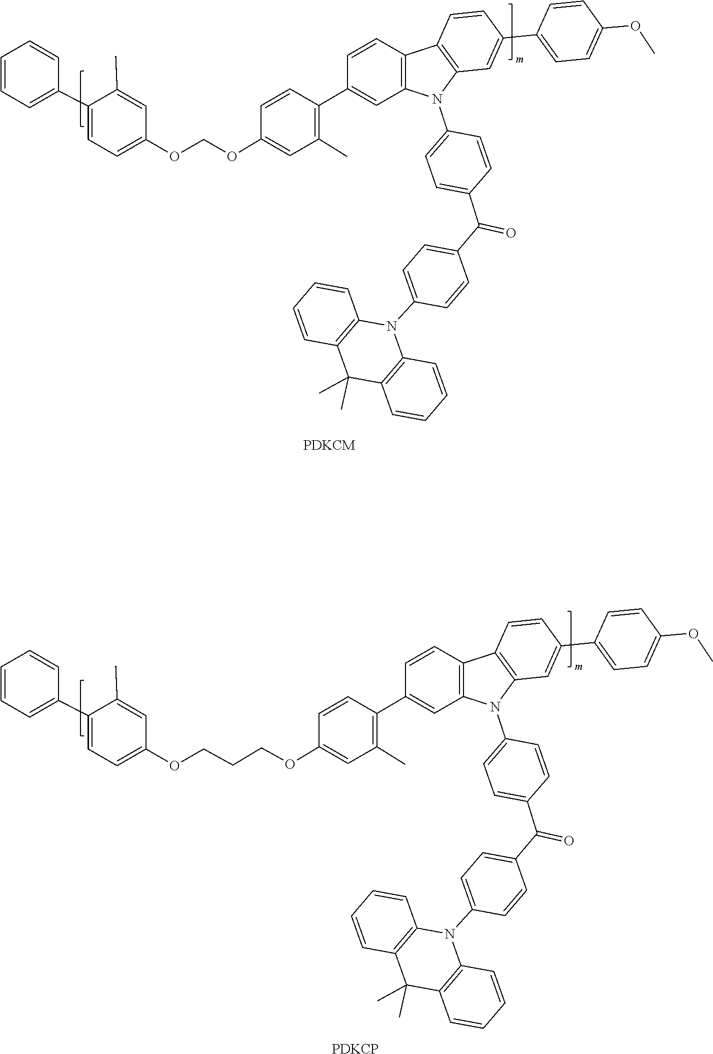

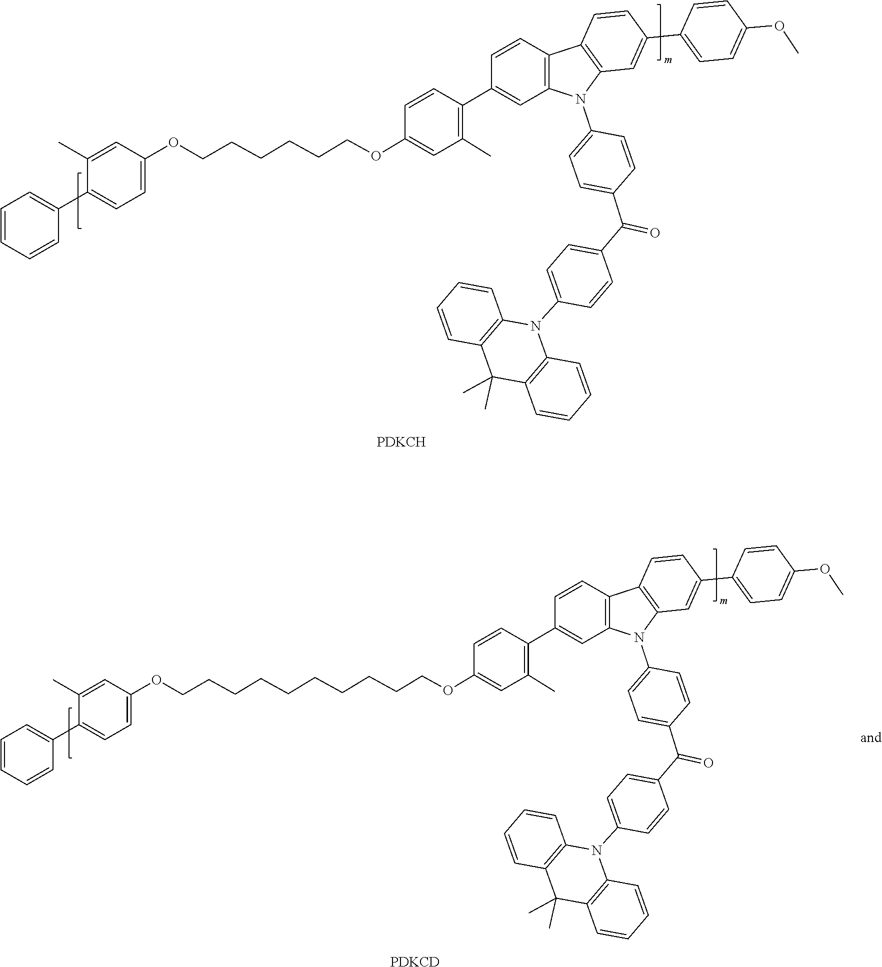

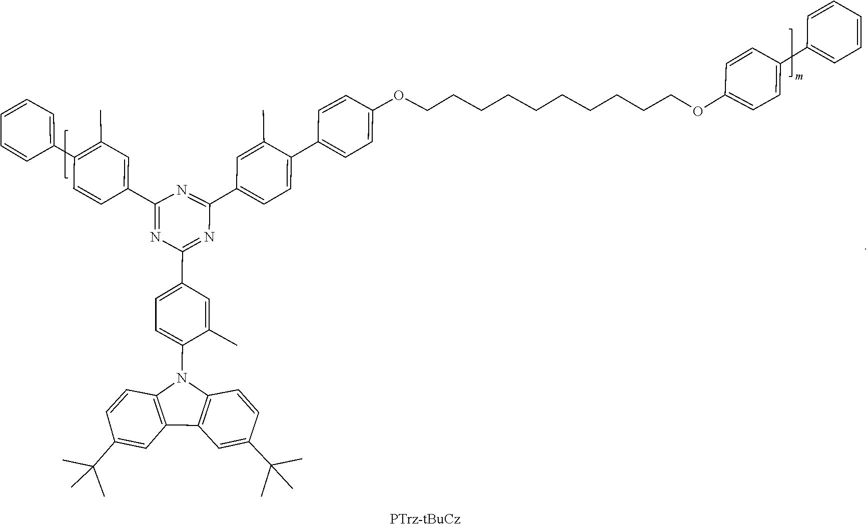

A seventh aspect relates to the polymer of any preceding aspect, wherein the polymer exhibits a charge transfer absorption at a wavelength of from 350 to 400 nanometers, and a second charge transfer absorption at a wavelength of from 400 to 450 nanometers.

An eighth aspect relates to the polymer of any preceding aspect, wherein the polymer exhibits a prompt decay of about 10 nanoseconds and a delayed decay of about 3 microseconds.

A ninth aspect relates to the polymer of any preceding aspect, wherein the polymer exhibits a crack on-set strain of greater than 100%.

A tenth aspect relates to a stretchable organic light-emitting diode, comprising: a cathode layer; an anode layer; a film comprising a polymer of any preceding aspect; a stretchable electron injection layer between the cathode layer and the film; and a stretchable hole transporting layer between the anode layer and the film.

An eleventh aspect relates to the diode of aspect 10, wherein the cathode layer and the anode layer comprise thermoplastic polyurethane comprising transparent silver nanowire.

A twelfth aspect relates to the diode of aspects 10 and 11, wherein the electron injection layer comprises poly[(9,9-bis(3′-((N,N-dimethyl)-N-ethylammonium)-propyl)-2,7-fluorene)-alt-2,7-(9,9-dioctylfluorene)](PFN-Br) and polyethylene ethoxylated (PEIE) in a weight ratio of from about 2:1 to about 1:4.

A thirteenth aspect relates to the diode of aspects 10 to 12, wherein the hole transporting layer comprises poly(3,4-ethylenedioxythiophene) poly(styrenesulfonate) (PEDOT:PSS) with perfluorinated ionomers (PFI) in a weight ratio of from about 3:1 to about 1:50.

A fourteenth aspect relates to the diode of aspects 10 to 13, wherein the diode is configured to exhibit a maximum external quantum efficiency of about 10% during stretching to 100% strain.

A fifteenth aspect relates to the diode of aspects 10 to 14, wherein the diode is configured to exhibit a maximum external quantum efficiency of about 3.3% during stretching to 60% strain.

In addition to the features mentioned in each of the independent aspects enumerated above, some examples may show, alone or in combination, the optional features mentioned in the dependent aspects and/or as disclosed in the description above and shown in the figures.

1. A stretchable light-emitting polymer of formula (I), (II), (III), (IV), or (V): 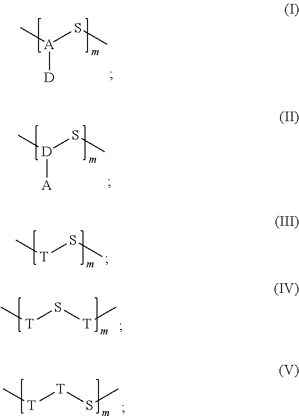
wherein D is a donor chemical moiety capable of donating electrons;
A is an acceptor chemical moiety capable of accepting electrons;
T is a chemical moiety comprising D bonded to A;
S is a stretchable section, comprising a stretchable chemical moiety selected from the group consisting of 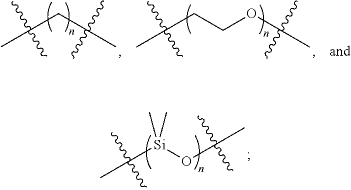
m is an integer from 1 to 100;
n is an integer from 1 to 50; and
a dihedral angle of a bond between D and A is from about 75.0° to about 90.0°.

2. The polymer of claim 1, wherein the stretchable section comprises a stretchable chemical moiety selected from the group consisting of 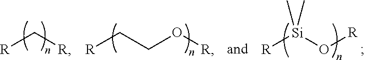
and
wherein R is a linker moiety, bonded in either direction, selected from the group consisting of

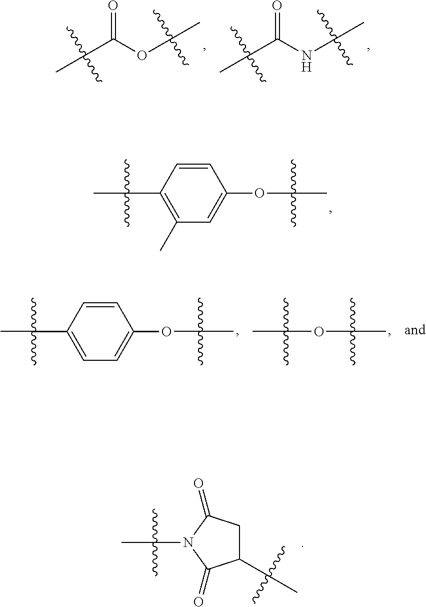

3. The polymer of claim 1, wherein the donor chemical moiety is selected from the group consisting of: 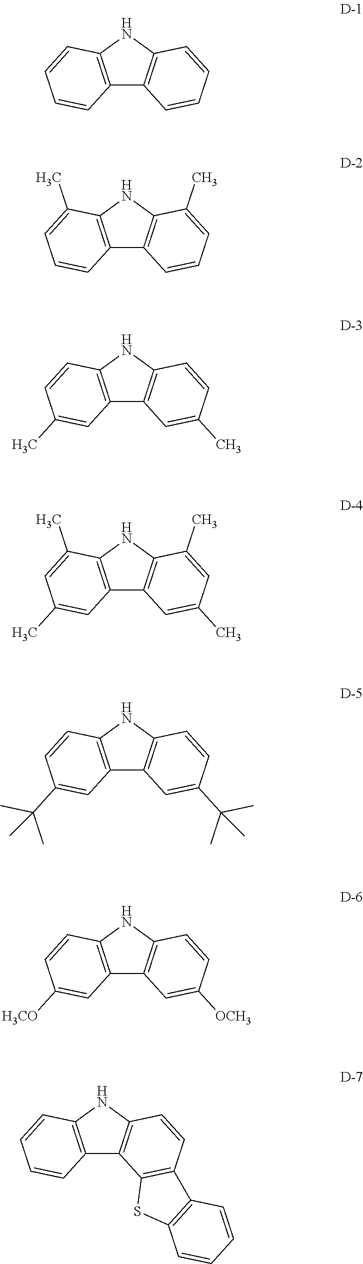 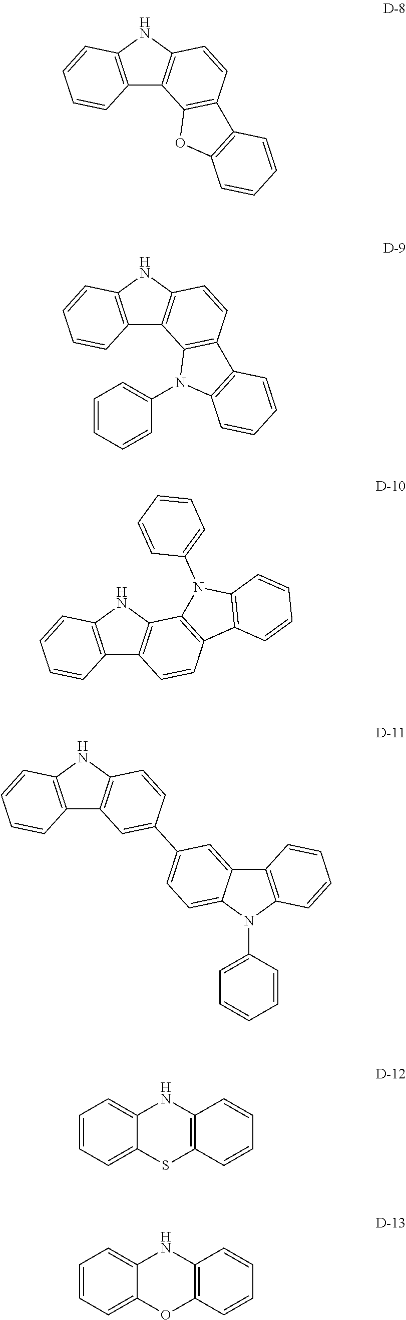 [SMILES: c1ccc2c(c1)[nH]c1ccc3c4ccccc4oc3c12 ; c1ccc(-n2c3ccccc3c3ccc4[nH]c5ccccc5c4c32)cc1 ; c1ccc(-n2c3ccccc3c3ccc4c5ccccc5[nH]c4c32)cc1 ; c1ccc(-n2c3ccccc3c3cc(-c4ccc5[nH]c6ccccc6c5c4)ccc32)cc1 ; c1ccc2c(c1)Nc1ccccc1S2 ; c1ccc2c(c1)Nc1ccccc1O2] 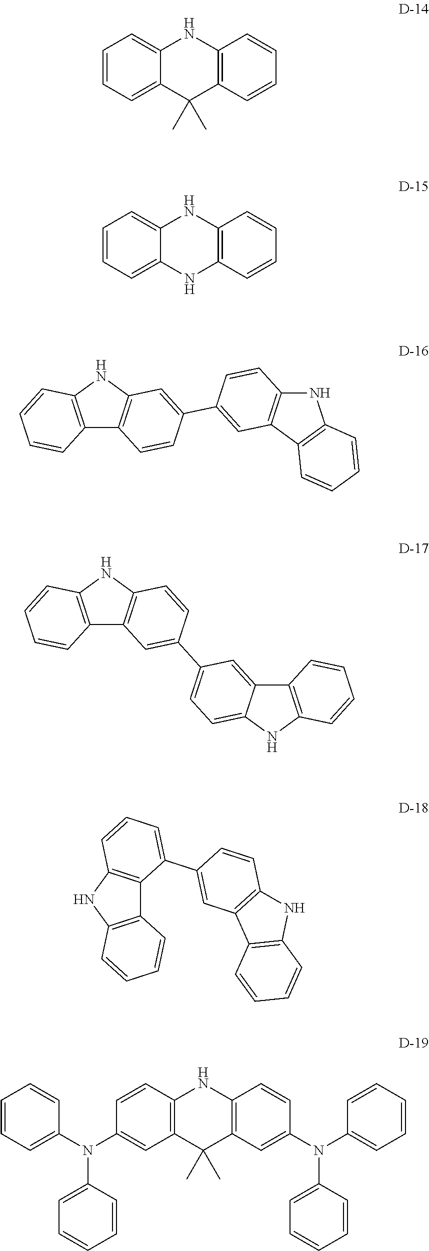 [SMILES: CC1(C)c2ccccc2Nc2ccccc21 ; c1ccc2c(c1)Nc1ccccc1N2 ; c1ccc2c(c1)[nH]c1cc(-c3ccc4[nH]c5ccccc5c4c3)ccc12 ; c1ccc2c(c1)[nH]c1ccc(-c3ccc4[nH]c5ccccc5c4c3)cc12 ; c1ccc2c(c1)[nH]c1ccc(-c3cccc4[nH]c5ccccc5c34)cc12 ; CC1(C)c2cc(N(c3ccccc3)c3ccccc3)ccc2Nc2ccc(N(c3ccccc3)c3ccccc3)cc21] 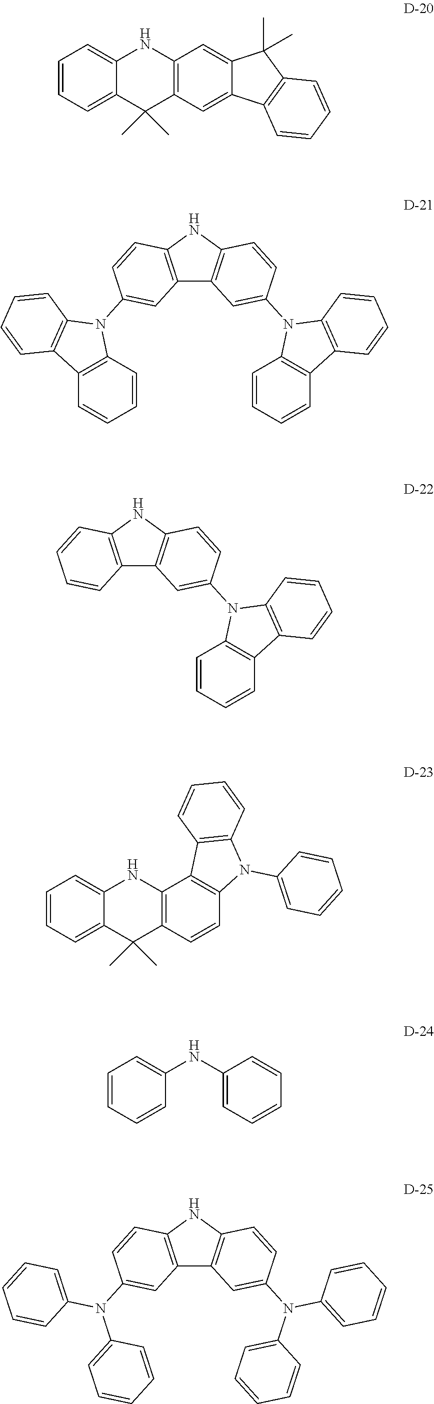 [SMILES: CC1(C)c2ccccc2Nc2cc3c(cc21)-c1ccccc1C3(C)C ; c1ccc2c(c1)c1ccccc1n2-c1ccc2[nH]c3ccc(-n4c5ccccc5c5ccccc54)cc3c2c1 ; c1ccc2c(c1)[nH]c1ccc(-n3c4ccccc4c4ccccc43)cc12 ; CC1(C)c2ccccc2Nc2c1ccc1c2c2ccccc2n1-c1ccccc1 ; c1ccc(Nc2ccccc2)cc1 ; c1ccc(N(c2ccccc2)c2ccc3[nH]c4ccc(N(c5ccccc5)c5ccccc5)cc4c3c2)cc1] 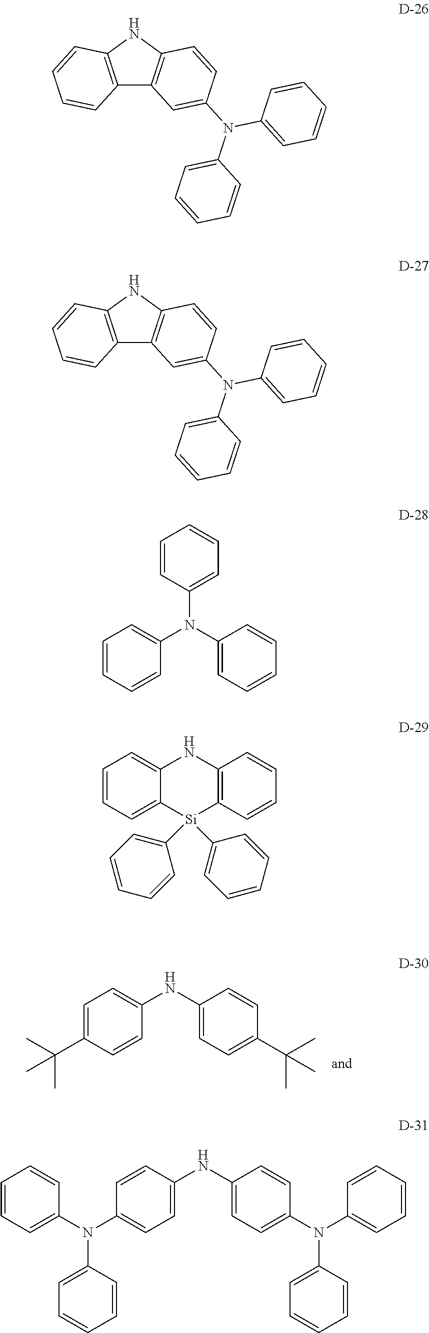
and wherein the donor chemical moiety is bonded to the acceptor chemical moiety at a carbon or nitrogen atom of the donor chemical moiety.

4. The polymer of claim 1, wherein the acceptor chemical moiety is selected from the group consisting of: 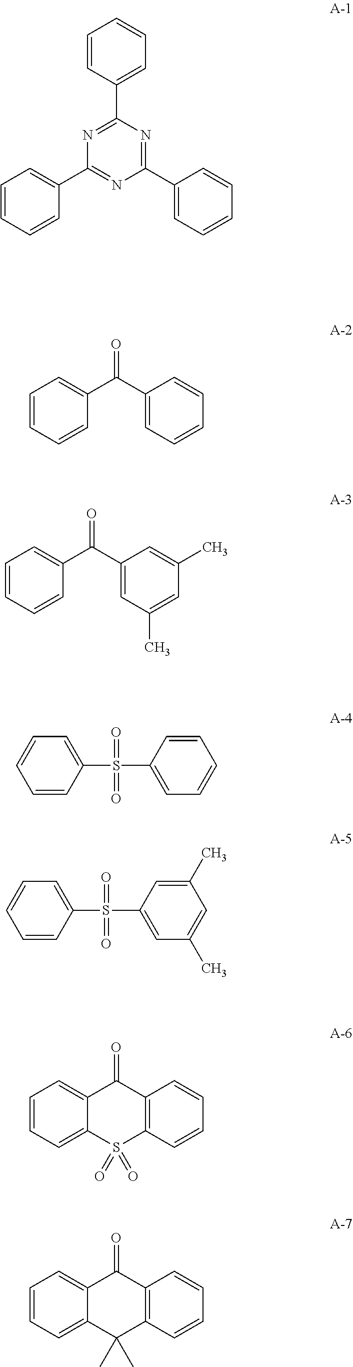 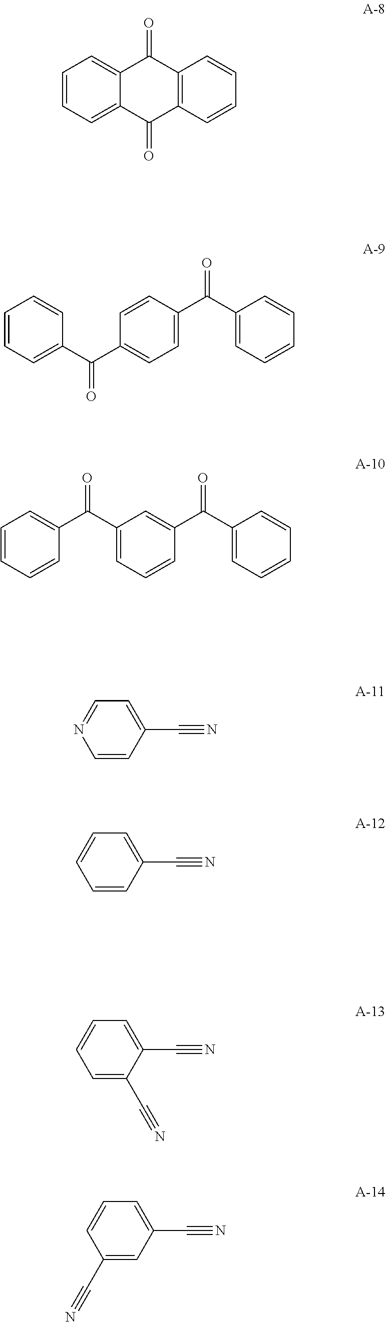 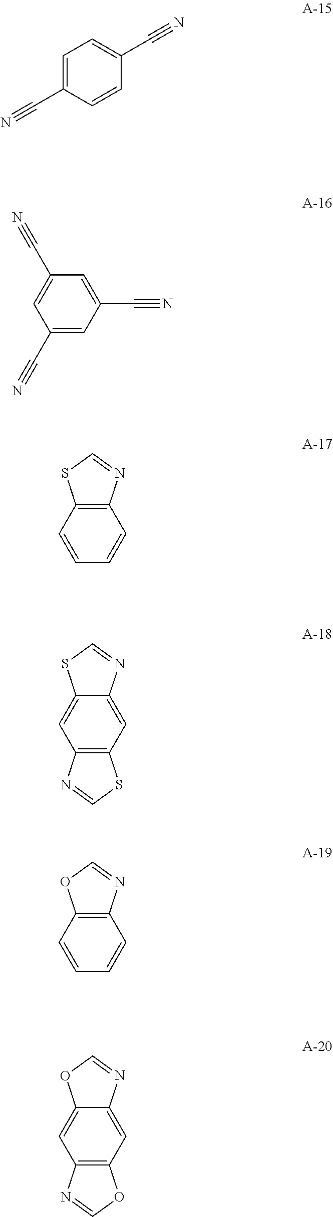 [SMILES: N#Cc1ccc(C#N)cc1 ; N#Cc1cc(C#N)cc(C#N)c1 ; c1ccc2scnc2c1 ; c1nc2cc3scnc3cc2s1 ; c1ccc2ocnc2c1 ; c1nc2cc3ocnc3cc2o1] 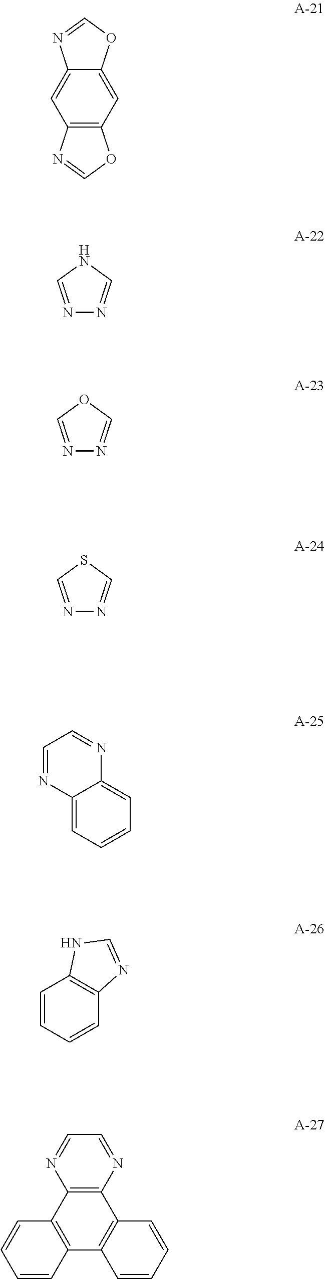 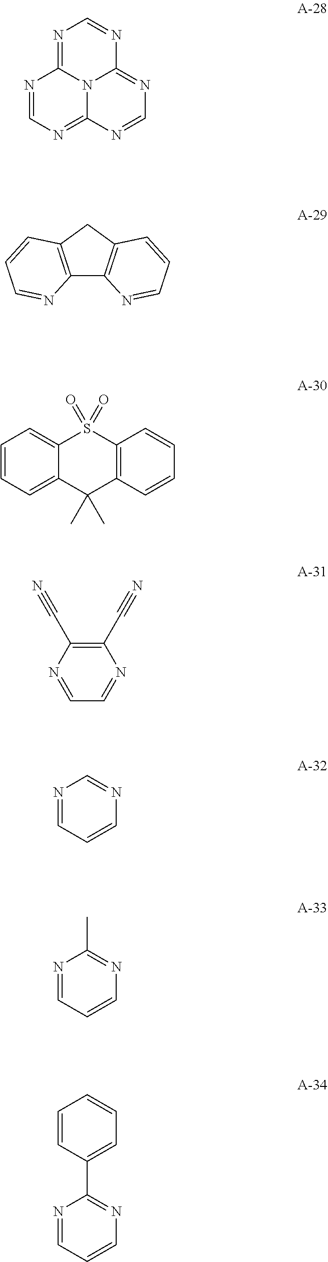 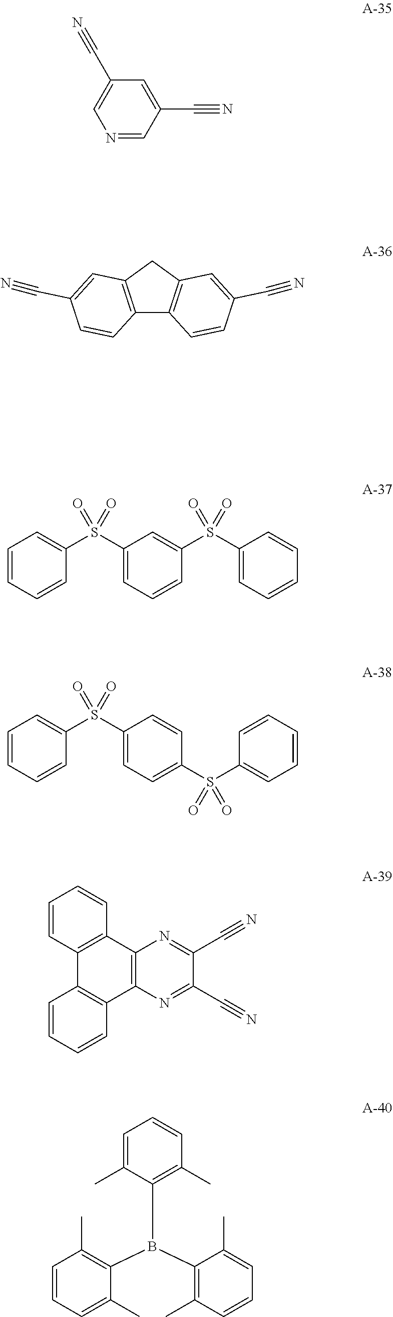 [SMILES: N#Cc1cncc(C#N)c1 ; N#Cc1ccc2c(c1)Cc1cc(C#N)ccc1-2 ; O=S(=O)(c1ccccc1)c1cccc(S(=O)(=O)c2ccccc2)c1 ; O=S(=O)(c1ccccc1)c1ccc(S(=O)(=O)c2ccccc2)cc1 ; N#Cc1nc2c3ccccc3c3ccccc3c2nc1C#N ; Cc1cccc(C)c1B(c1c(C)cccc1C)c1c(C)cccc1C] 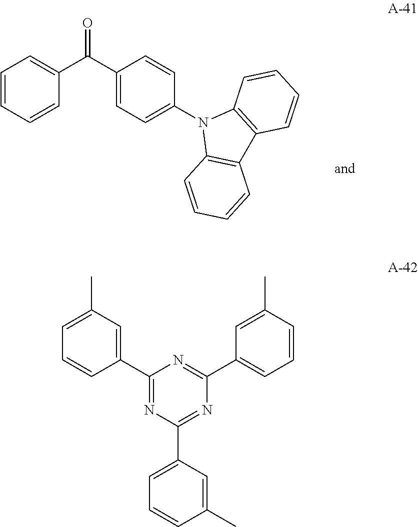 [SMILES: O=C(c1ccccc1)c1ccc(-n2c3ccccc3c3ccccc32)cc1 ; Cc1cccc(-c2nc(-c3cccc(C)c3)nc(-c3cccc(C)c3)n2)c1]
wherein the acceptor chemical moiety is bonded to the donor chemical moiety at a carbon, nitrogen, boron, or sulfur atom, and the acceptor chemical moiety is bonded to each of two stretchable sections at each of a second and a third carbon, nitrogen, boron, or sulfur atom.

5. The polymer of claim 1, wherein the polymer is selected from the group consisting of:

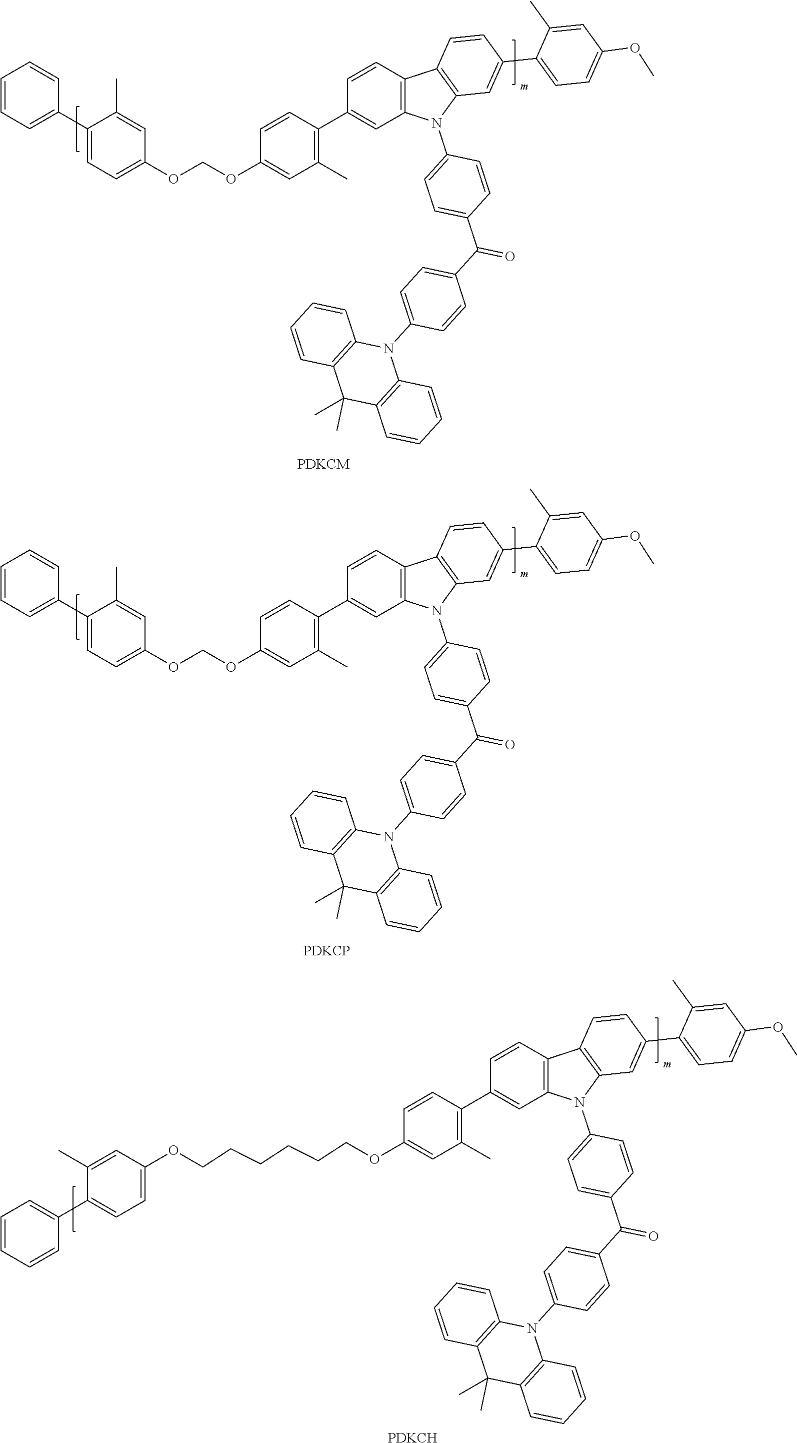

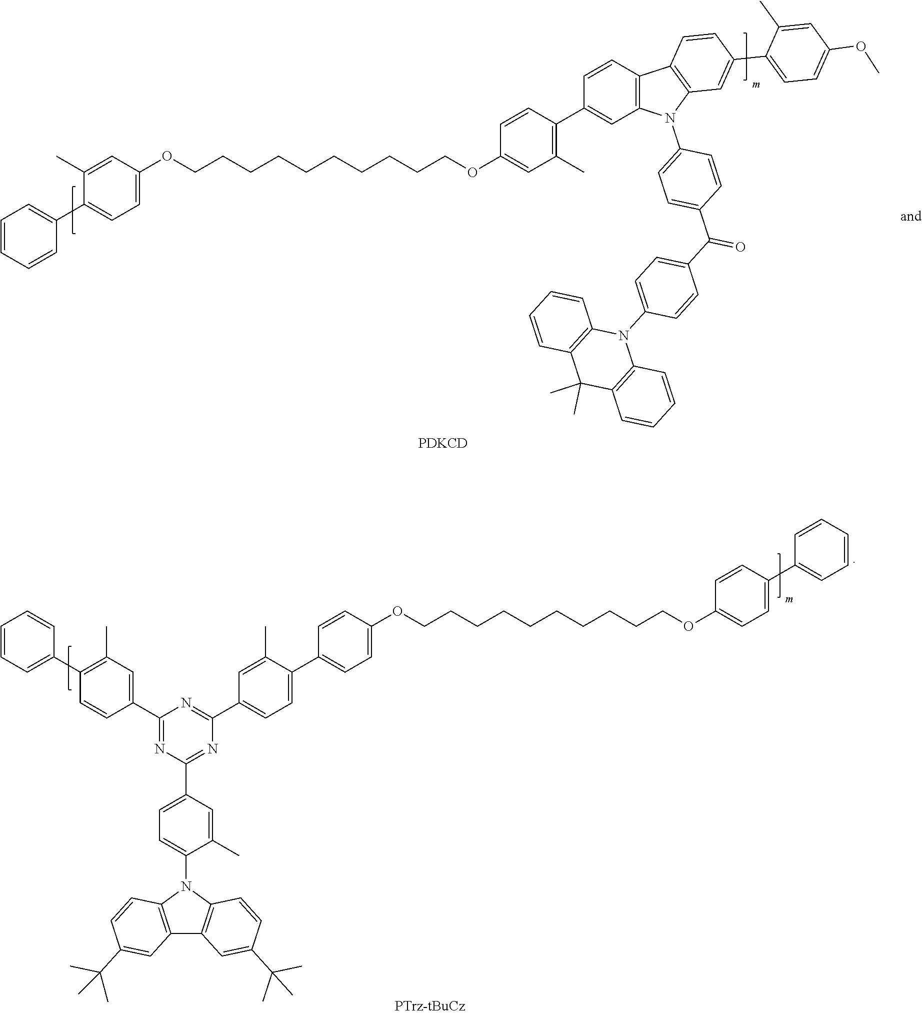

6. The polymer of claim 1, wherein the polymer exhibits a charge transfer absorption at a wavelength of from 350 to 400 nanometers, and a second charge transfer absorption at a wavelength of from 400 to 450 nanometers.

7. The polymer of claim 1, wherein the polymer exhibits a prompt decay of about 10 nanoseconds and a delayed decay of about 3 microseconds.

8. The polymer of claim 1, wherein the polymer exhibits a crack on-set strain of greater than 100%.

9. A stretchable organic light-emitting diode, comprising:
a cathode layer;
an anode layer;
a film comprising a stretchable light-emitting polymer of formula (I), (II), (III), (IV), or (V): 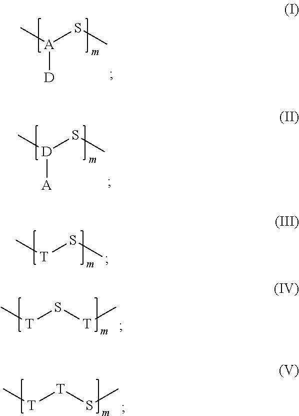
a stretchable electron injection layer between the cathode layer and the film; and
a stretchable hole transporting layer between the anode layer and the film;
wherein D is a donor chemical moiety capable of donating electrons;
A is an acceptor chemical moiety capable of accepting electrons;
T is a chemical moiety comprising D bonded to A;
S is a stretchable section, comprising a stretchable chemical moiety selected from the group consisting of 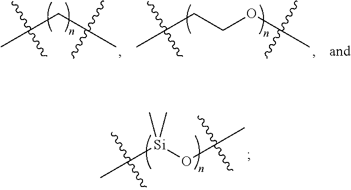
m is an integer from 1 to 100;
n is an integer from 1 to 50; and
a dihedral angle of a bond between D and A is from about 75.0° to about 90.0°.

10. The diode of claim 9, wherein the stretchable section comprises a stretchable chemical moiety selected from the group consisting of 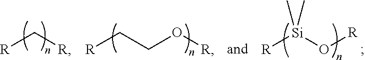
and
wherein R is a linker moiety, bonded in either direction, selected from the group consisting of

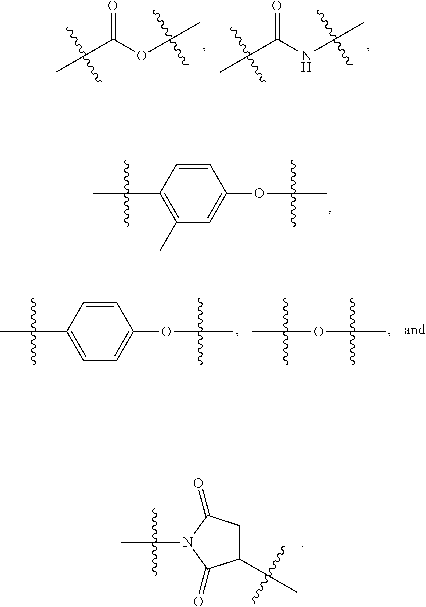

11. The diode of claim 9, wherein the donor chemical moiety is selected from the group consisting of: 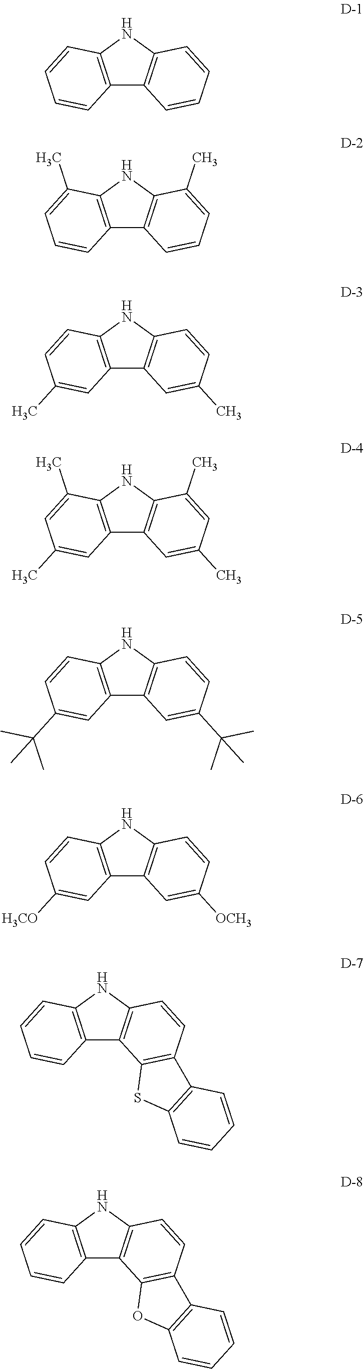 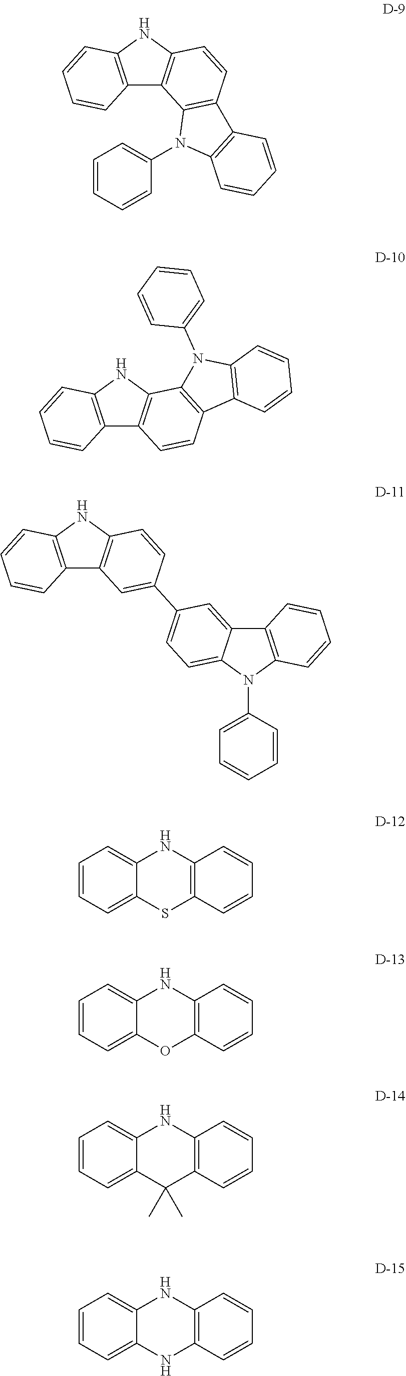 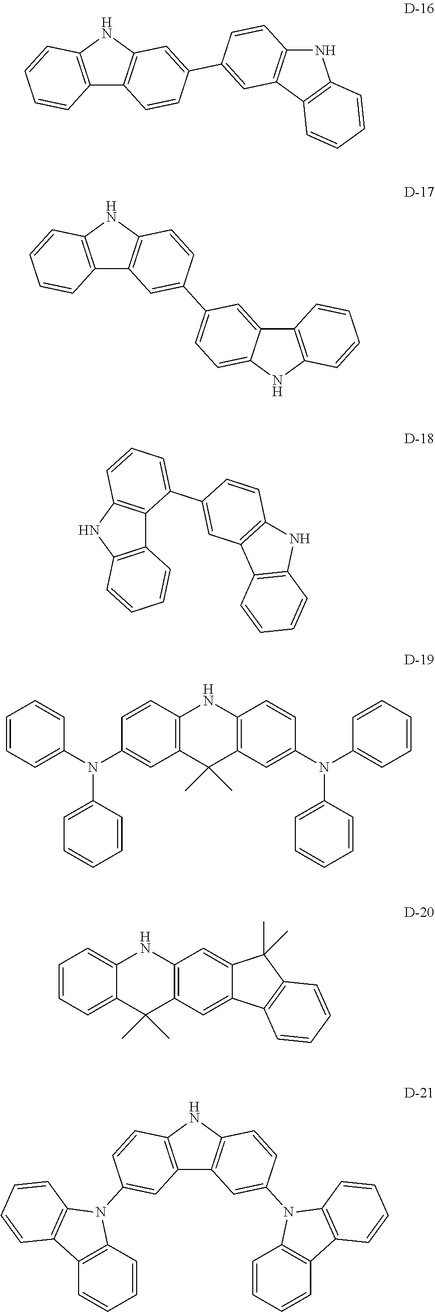 [SMILES: c1ccc2c(c1)[nH]c1cc(-c3ccc4[nH]c5ccccc5c4c3)ccc12 ; c1ccc2c(c1)[nH]c1ccc(-c3ccc4[nH]c5ccccc5c4c3)cc12 ; c1ccc2c(c1)[nH]c1ccc(-c3cccc4[nH]c5ccccc5c34)cc12 ; CC1(C)c2cc(N(c3ccccc3)c3ccccc3)ccc2Nc2ccc(N(c3ccccc3)c3ccccc3)cc21 ; CC1(C)c2ccccc2Nc2cc3c(cc21)-c1ccccc1C3(C)C ; c1ccc2c(c1)c1ccccc1n2-c1ccc2[nH]c3ccc(-n4c5ccccc5c5ccccc54)cc3c2c1] 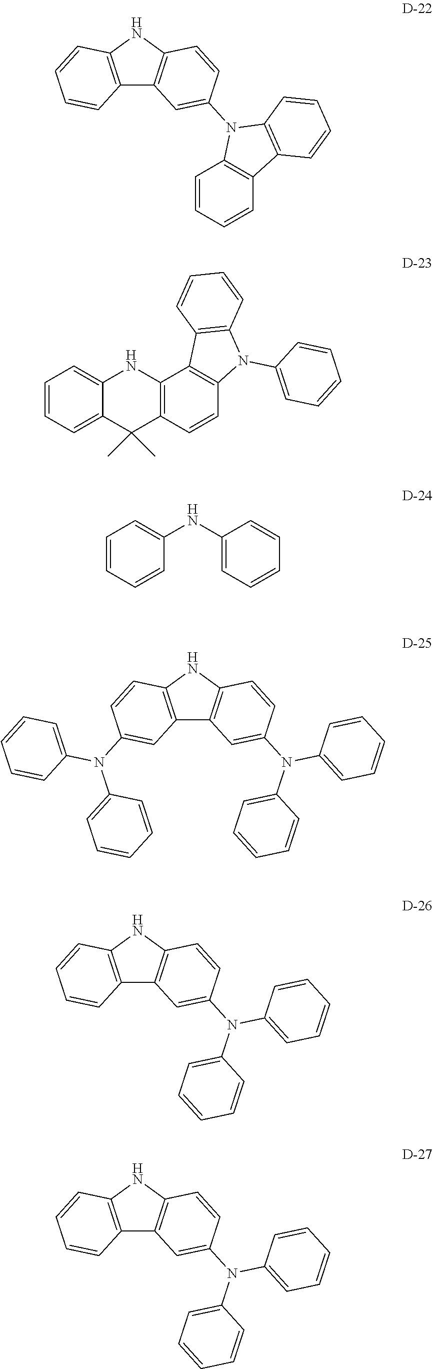 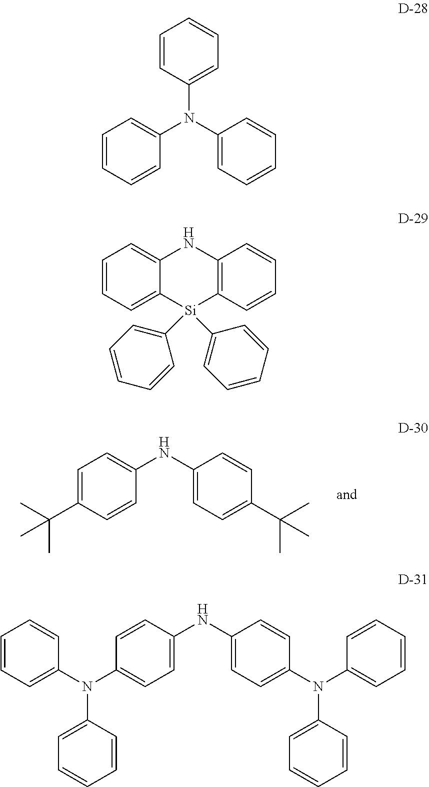 [SMILES: c1ccc(N(c2ccccc2)c2ccccc2)cc1 ; c1ccc([Si]2(c3ccccc3)c3ccccc3Nc3ccccc32)cc1 ; CC(C)(C)c1ccc(Nc2ccc(C(C)(C)C)cc2)cc1 ; c1ccc(N(c2ccccc2)c2ccc(Nc3ccc(N(c4ccccc4)c4ccccc4)cc3)cc2)cc1]
and wherein the donor chemical moiety is bonded to an acceptor chemical moiety at a carbon or nitrogen atom of the donor chemical moiety.

12. The diode of claim 9, wherein the acceptor chemical moiety is selected from the group consisting of: 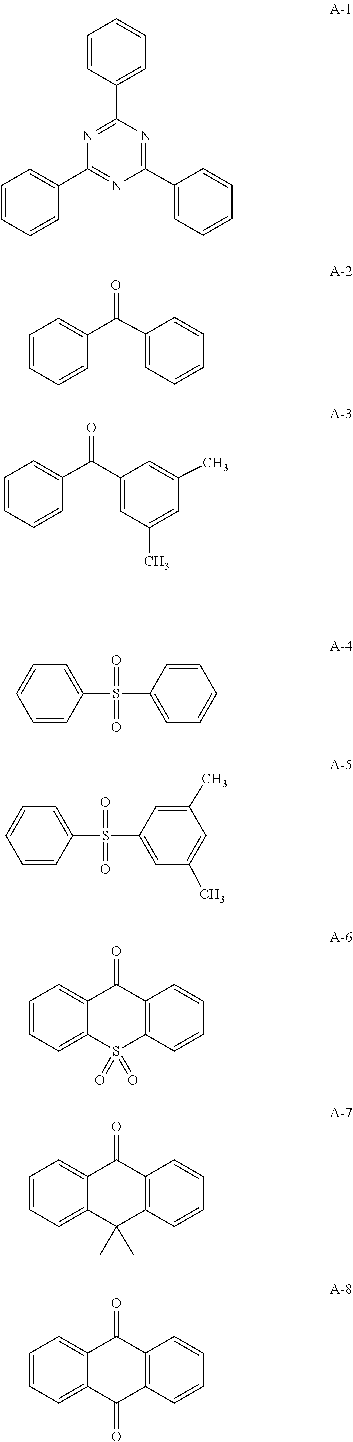 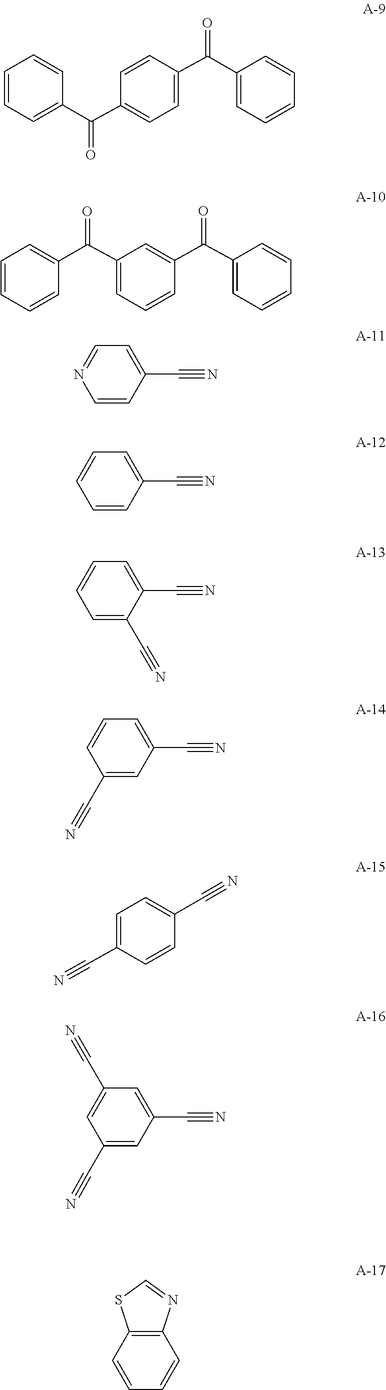 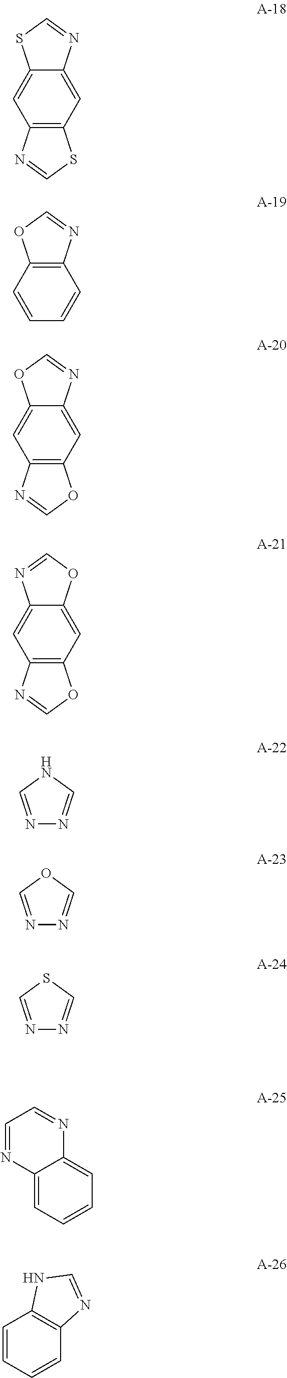 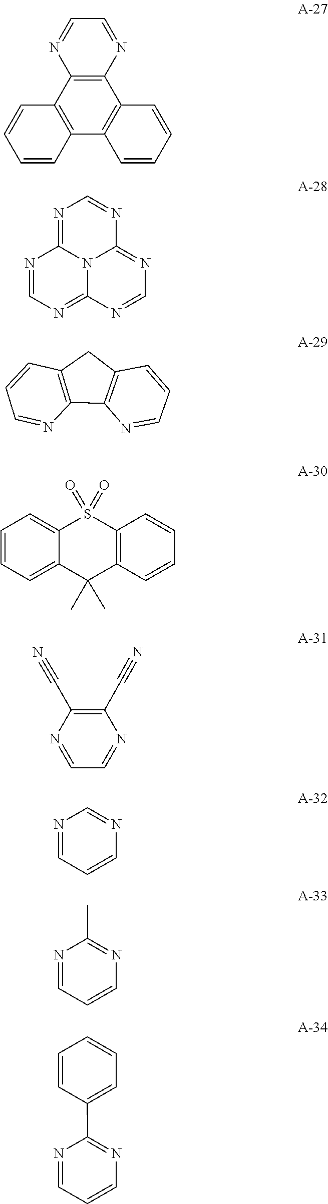 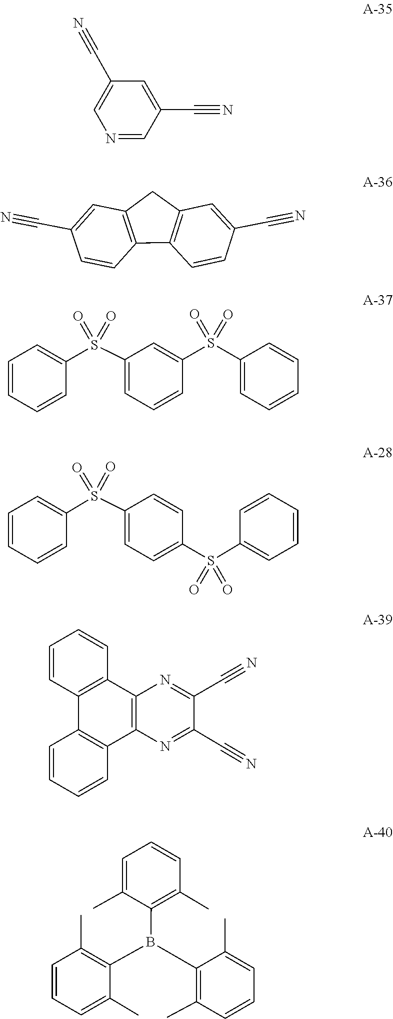 [SMILES: N#Cc1cncc(C#N)c1 ; N#Cc1ccc2c(c1)Cc1cc(C#N)ccc1-2 ; O=S(=O)(c1ccccc1)c1cccc(S(=O)(=O)c2ccccc2)c1 ; O=S(=O)(c1ccccc1)c1ccc(S(=O)(=O)c2ccccc2)cc1 ; N#Cc1nc2c3ccccc3c3ccccc3c2nc1C#N ; Cc1cccc(C)c1B(c1c(C)cccc1C)c1c(C)cccc1C] 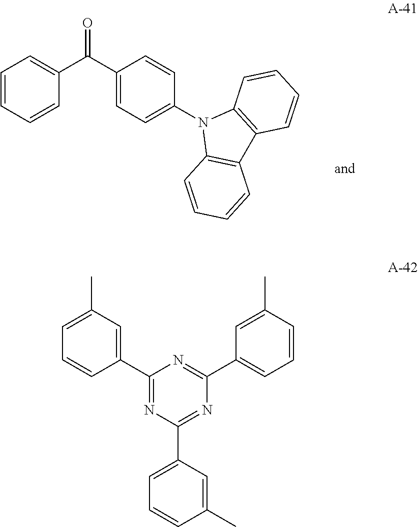 [SMILES: O=C(c1ccccc1)c1ccc(-n2c3ccccc3c3ccccc32)cc1 ; Cc1cccc(-c2nc(-c3cccc(C)c3)nc(-c3cccc(C)c3)n2)c1]
wherein the acceptor chemical moiety is bonded to the donor chemical moiety at a carbon, nitrogen, boron, or sulfur atom, and the acceptor chemical moiety is bonded to each of two stretchable sections at each of a second and a third carbon, nitrogen, boron, or sulfur atom.

13. The diode of claim 9, wherein the polymer is selected from the group consisting of:

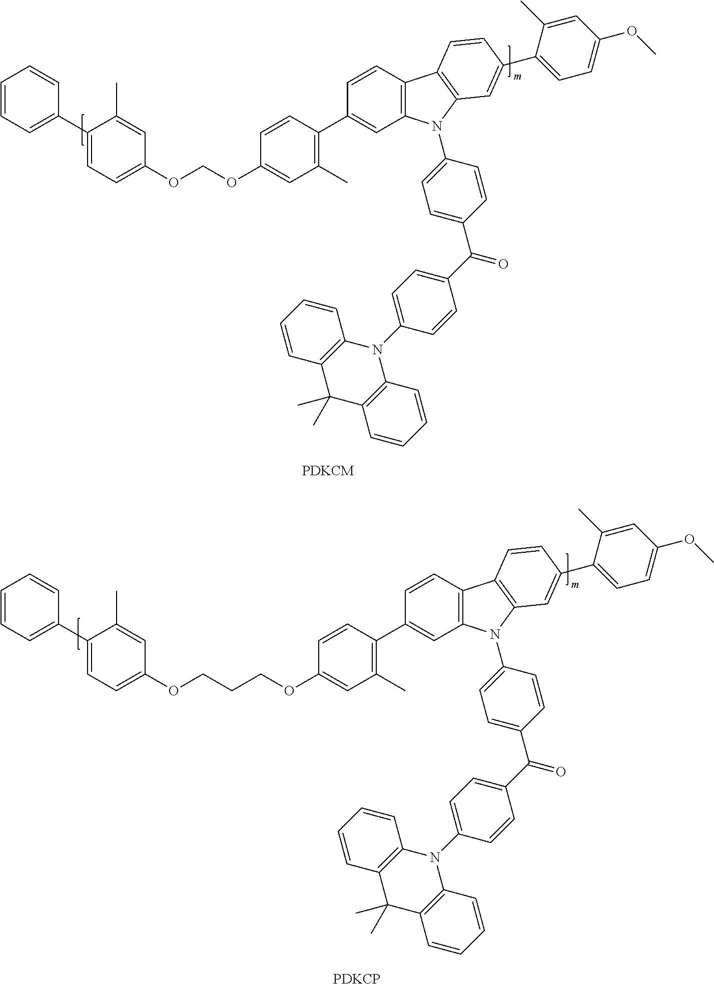

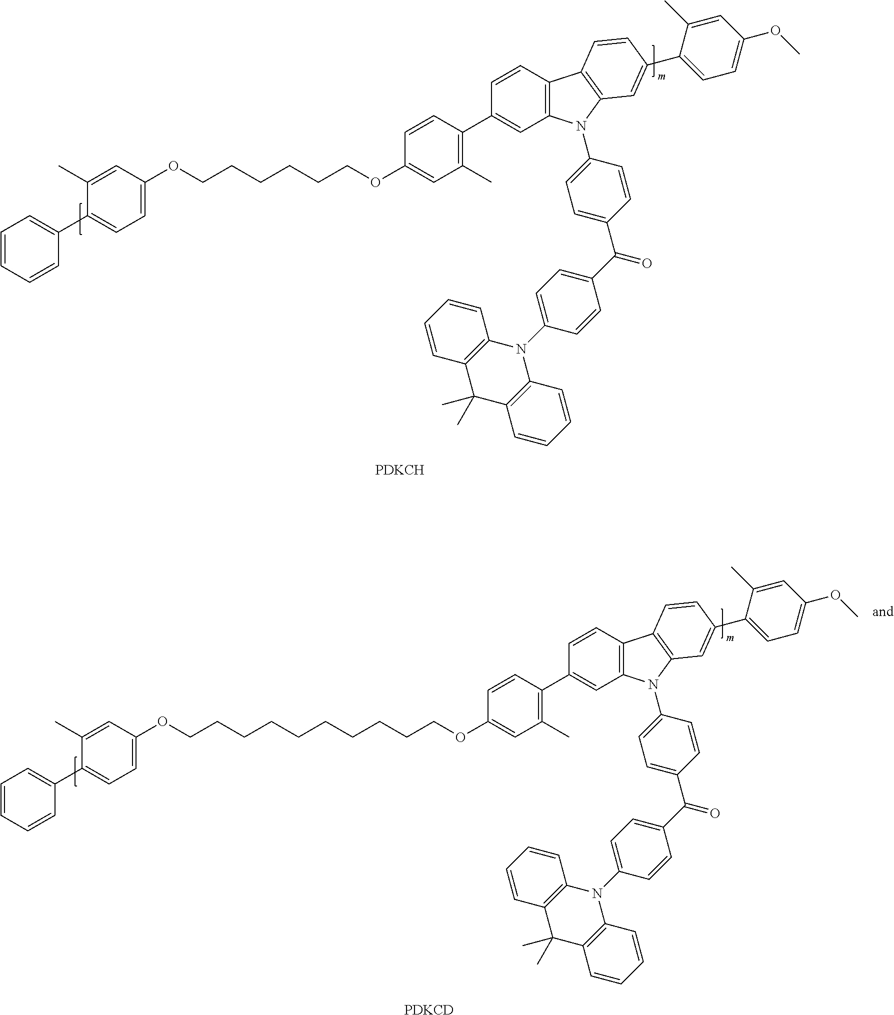

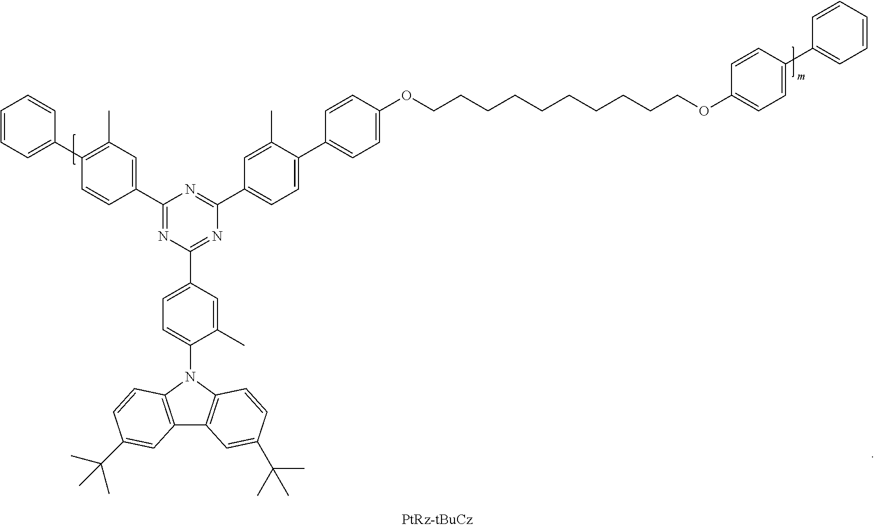

14. The diode of claim 9, wherein the cathode layer and the anode layer comprise thermoplastic polyurethane comprising transparent silver nanowire.

15. The diode of claim 9, wherein the electron injection layer comprises poly[(9,9-bis(3′-((N,N-dimethyl)-N-ethylammonium)-propyl)-2,7-fluorene)-alt-2,7-(9,9-dioctylfluorene)](PFN-Br) and polyethyleneimine ethoxylated (PEIE) in a weight ratio of from about 2:1 to about 1:4; and/or
wherein the hole transporting layer comprises poly(3,4-ethylenedioxythiophene) poly(styrenesulfonate) (PEDOT:PSS) with perfluorinated ionomers (PFI) in a weight ratio of from about 3:1 to about 1:50.

16. (canceled)

17. The diode of claim 9, wherein the diode is configured to exhibit a maximum external quantum efficiency of about 10% during stretching to 100% strain.

18. (canceled)

19. A stretchable light-emitting polymer of formula (VI): 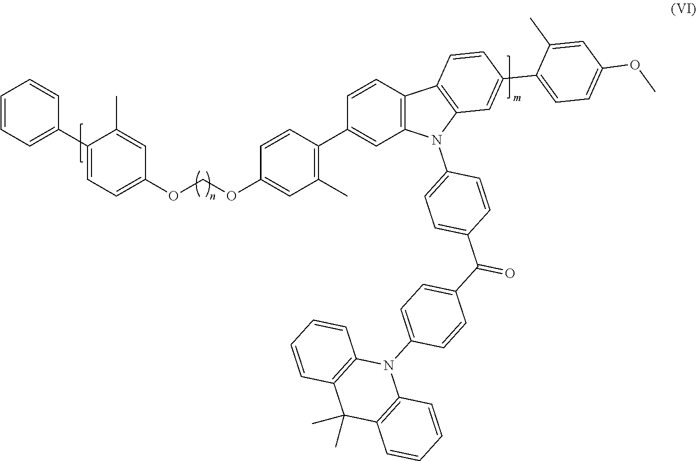
wherein m is an integer from 1 to 100; and
n is an integer from 1 to 50.

20. The polymer of claim 19, wherein the polymer exhibits a charge transfer absorption at a wavelength of from 350 to 400 nanometers, and a second charge transfer absorption at a wavelength of from 400 to 450 nanometers.

21. The polymer of claim 19, wherein the polymer exhibits a prompt decay of about 10 nanoseconds and a delayed decay of about 3 microseconds.

22. The polymer of claim 19, wherein the polymer exhibits a crack on-set strain of greater than 100%.
